(19) United States
(12) Patent Application Publication
(10) Pub. No.: US 2014/0030643 A1
(43) Pub. Date: Jan. 30, 2014

(54) ACTINIC-RAY-OR RADIATION-SENSITIVE RESIN COMPOSITION, ACTINIC-RAY- OR RADIATION-SENSITIVE RESIN FILM THEREFROM AND METHOD OF FORMING PATTERN USING THE COMPOSITION

(71) Applicant: FUJIFILM Corporation, Tokyo (JP)

(72) Inventors: Toshiya TAKAHASHI, Shizuoka (JP); Hiroo TAKIZAWA, Shizuoka (JP); Hideaki TSUBAKI, Shizuoka (JP); Shuji HIRANO, Shizuoka (JP); Tomotaka TSUCHIMURA, Shizuoka (JP)

(73) Assignee: FUJIFILM Corporation, Tokyo (JP)

(21) Appl. No.: 14/039,435

(22) Filed: Sep. 27, 2013

Related U.S. Application Data
(63) Continuation of application No. PCT/JP2012/059300, filed on Mar. 29, 2012.

(30) Foreign Application Priority Data
Mar. 30, 2011 (JP) 2011-076093

(51) Int. Cl. G03F 7/004

(52) U.S. Cl. CPC G03F 7/0045
USPC 430/18; 430/270.1; 430/296

(57) ABSTRACT

Provided is an actinic-ray- or radiation-sensitive resin composition including a resin (P) containing an acid-decomposable repeating unit (A), which resin when acted on by an acid, increases its solubility in an alkali developer, a compound (Q) that when exposed to actinic rays or radiation, generates an acid, and a compound (R) expressed by general formula (1) or (2) below.

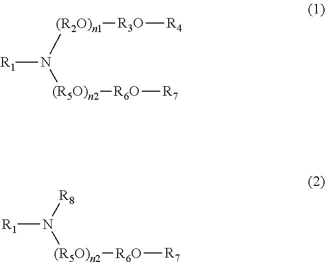

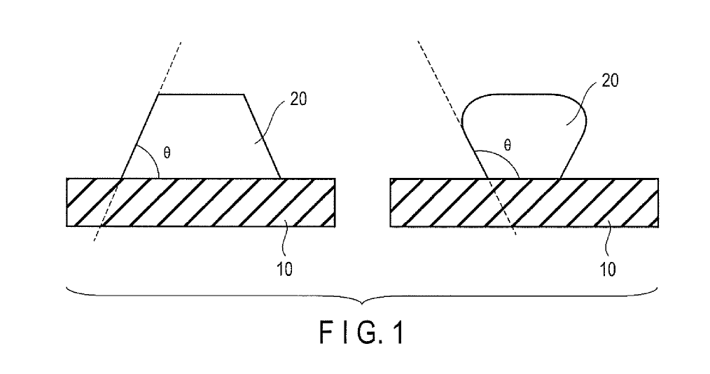

### CROSS-REFERENCE TO RELATED APPLICATION

This application is a Continuation Application of PCT Application No. PCT/JP2012/059300, filed Mar. 29, 2012 and based upon and claiming the benefit of priority from prior Japanese Patent Applications No. 2011-076093, filed Mar. 30, 2011, the entire contents of all of which are incorporated herein by reference.

### BACKGROUND OF THE INVENTION

1. Field of the Invention

The present invention relates to an actinic-ray- or radiation-sensitive resin composition, an actinic-ray- or radiation-sensitive resin film therefrom and a method of forming a pattern using the composition. More particularly, the present invention relates to a composition that is suitable for use in, for example, an ultramicrolithography process applicable to a process for manufacturing a super-LSI or a high-capacity microchip, a process for fabricating a nanoimprint mold, a process for producing a high-density information recording medium, etc., and other photofabrication processes, and relates to a relevant film and method of forming a pattern. Further more particularly, the present invention relates to a composition, film and method of forming a pattern that can find appropriate application in, for example, the microfabrication of semiconductor devices by electron beams or soft X-rays such as EUV light.

2. Background Art

Description of the Related Art

In the microfabrication by lithography, in recent years, the formation of an ultrafine pattern on the order of tens of nanometers is increasingly required in accordance with the realization of high integration for integrated circuits. In accordance with this requirement, the trend of exposure wavelength toward a short wavelength, for example, from g-rays to i-rays and further to a KrF excimer laser light is seen. Moreover, now, the development of lithography using electron beams, X-rays or EUV light besides the excimer laser light is progressing.

Further, the microfabrication using a resist composition is not only directly used in the manufacturing of integrated circuits but also, in recent years, finds application in the fabrication of so-called imprint mold structures, etc. (see, for example, patent reference 1 and non-patent reference 1).

Basic compounds may be added to the resist compositions (see, for example, patent references 2 to 10). Basic compounds fulfill the role of, for example, quenching any deprotection reaction by an acid generated upon exposure.

In recent years, the lithography using X-rays, soft X-rays or electron beams is positioned as the next-generation or next-next-generation pattern forming technology. When this lithography technology is applied, it is especially an important task to simultaneously attain high sensitivity and favorable performance in pattern shape, roughness characteristic and reduction of residue defects.

### PRIOR ART LITERATURE

### Patent Reference

Patent reference 1: Jpn. Pat. Appln. KOKAI Publication No. (hereinafter referred to as JP-A-) 2008-162101,
Patent reference 2: U.S. Pat. No. 5,916,728,
Patent reference 3: JP-A-H10-177250,
Patent reference 4: JP-A-H5-232706,
Patent reference 5: JP-A-H10-326015,
Patent reference 6: European Patent No. 881539,
Patent reference 7: JP-A-2004-046157,
Patent reference 8: U.S. Pat. No. 6,274,286,
Patent reference 9: JP-A-H11-084639, and
Patent reference 10: JP-A-2008-065296.

### Non-Patent Literature

Non-patent reference 1: “Fundamentals of nanoimprint and its technology development/application deployment—technology of nanoimprint substrate and its latest technology deployment” edited by Yoshihiko Hirai, published by Frontier Publishing (issued in June, 2006).

### BRIEF SUMMARY OF THE INVENTION

It is an object of the present invention to provide an actinic-ray- or radiation-sensitive resin composition that can attain high sensitivity, favorable pattern shape, favorable roughness characteristic and reduction of residue defects. It is further objects of the present invention to provide an actinic-ray- or radiation-sensitive resin film therefrom and a method of forming a pattern using the composition.

The inventors have conducted extensive and intensive studies with a view toward attaining the above object. As a result, the following inventions have been completed.

[1] An actinic-ray- or radiation-sensitive resin composition comprising:

a resin (P) containing an acid-decomposable repeating unit (A), which resin when acted on by an acid, increases its solubility in an alkali developer,

a compound (Q) that when exposed to actinic rays or radiation, generates an acid, and

a compound (R) expressed by general formula (1) or (2) below,

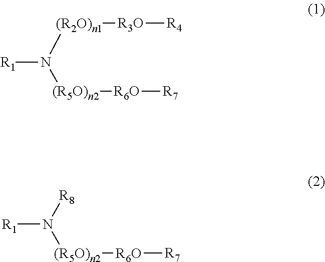

in the formulae,

each of R₁ and R₈ independently represents an organic group containing no heteroatom,

each of R₂, R₃, R₅ and R₆ independently represents an alkylene group having 1 to 3 carbon atoms,

each of R₄ and R₇ independently represents a hydrogen atom or an alkyl group, and

each of n₁ and n₂ independently is an integer of 1 to 6.

[2] The composition according to the above item [1], wherein the organic group is an alkyl group or an aryl group.

[3] The composition according to the above item [1] or [2], wherein the compound (R) is expressed by general formula (1), and wherein at least one of R₄ and R₇ is a hydrogen atom.

[4] The composition according to the above item [3], wherein both of R₄ and R₇ are hydrogen atoms.

[5] The composition according to the above item [1] or [2], wherein the compound (R) is expressed by general formula (2), and wherein R₇ is a hydrogen atom.

[6] The composition according to any of the above items [1] to [5], wherein the repeating unit (A) is expressed by general formula (V) or (VI) below.

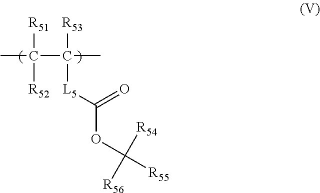

In general formula (V), each of R₅₁, R₅₂ and R₅₃ independently represents a hydrogen atom, an alkyl group, a cycloalkyl group, a halogen atom, a cyano group or an alkoxycarbonyl group, provided that R₅₂ may be bonded to L₅ to thereby form a ring, which R₅₂ represents an alkylene group,

L₅ represents a single bond or a bivalent connecting group, provided that when a ring is formed in cooperation with R₅₂, L₅ represents a trivalent connecting group, and

R₅₄ represents an alkyl group, and each of R₅₅ and R₅₆ independently represents a hydrogen atom, an alkyl group, a cycloalkyl group or a monovalent aromatic ring group, provided that R₅₅ and R₅₆ may be bonded to each other to thereby form a ring, and provided that R₅₅ and R₅₆ are not simultaneously hydrogen atoms.

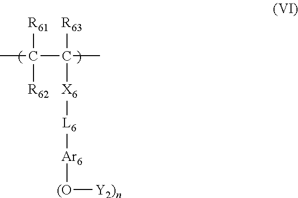

In general formula (VI), each of R₆₁, R₆₂ and R₆₃ independently represents a hydrogen atom, an alkyl group, a cycloalkyl group, a halogen atom, a cyano group or an alkoxycarbonyl group, provided that R₆₂ may be bonded to Ar₆ to thereby form a ring, which R₆₂ represents an alkylene group,

X₆ represents a single bond, —COO— or —CONR₆₄— in which R₆₄ represents a hydrogen atom or an alkyl group,

L₆ represents a single bond or an alkylene group,

Ar₆ represents a bivalent aromatic ring group,

Y₂, when n≧2 each independently, represents a hydrogen atom or a group that when acted on by an acid, is cleaved, provided that at least one of Y₂s is a group that when acted on by an acid, is cleaved, and

n is an integer of 1 to 4.

[7] The composition according to any of the above items [1] to [6], wherein the resin (P) further contains any of repeating units (B) expressed by general formula (I) below.

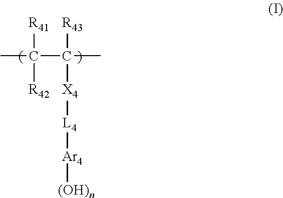

In general formula (I), each of R₄₁, R₄₂ and R₄₃ independently represents a hydrogen atom, an alkyl group, a halogen atom, a cyano group or an alkoxycarbonyl group,

X₄ represents a single bond, —COO— or —CONR₆₄— in which R₆₄ represents a hydrogen atom or an alkyl group,

L₄ represents a single bond or an alkylene group,

Ar₄ represents a (n+1)-valent aromatic ring group, and

n is an integer of 1 to 4.

[8] The composition according to the above item [7], wherein the repeating unit (B) has a hydroxystyrene structure.

[9] The composition according to any of the above items [1] to [8], further comprising a basic compound other than the compound (R).

[10] The composition according to the above item [9], wherein the basic compound contains no hydroxyl group.

[11] The composition according to any of the above items [1] to [10] for use in a pattern formation including exposure by EUV.

[12] An actinic-ray- or radiation-sensitive resin film formed from the composition according to any of the above items [1] to [11].

[13] A method of forming a pattern, comprising:

exposing the film according to the above item [12] to light, and

developing the exposed film.

[14] The method according to item [13], wherein the exposure is carried out by EUV light.

[15] A process for manufacturing an electronic device, comprising the pattern forming method according to the above item [13] or [14].

[16] An electronic device manufactured by the process according to the above item [15].

The present invention has made it feasible to provide an actinic-ray- or radiation-sensitive resin composition that can attain high sensitivity, favorable pattern shape, favorable roughness characteristic and reduction of residue defects and to provide an actinic-ray- or radiation-sensitive resin film therefrom and a method of forming a pattern using the composition.

### BRIEF DESCRIPTION OF DRAWINGS

The single FIGURE is a section view schematically showing the definition of taper angle mentioned in Examples.

### DETAILED DESCRIPTION OF THE INVENTION

The present invention will be described below.

Note that, with respect to the expression of a group (or an atomic group) used in this specification, the expression without explicitly referring to whether the group is substituted or unsubstituted encompasses not only groups with no substituents but also groups having one or more substituents. For example, the expression “alkyl group” encompasses not only alkyl groups having no substituents (viz. unsubstituted alkyl groups) but also alkyl groups having one or more substituents (viz. substituted alkyl groups).

In the present invention, the terms “actinic rays” and “radiation” mean, for example, a mercury lamp bright line spectrum, far ultraviolet rays represented by an excimer laser, extreme ultraviolet rays, X-rays, electron beams and the like. In the present invention, the term “light” means actinic rays or radiation. The expression “exposure” used herein, unless otherwise noted, means not only light irradiation using a mercury lamp, far ultraviolet, X-rays, EUV light, etc. but also lithography using particle beams, such as an electron beam and an ion beam.

The actinic-ray- or radiation-sensitive resin composition of the present invention comprises [1] a resin that when acted on by an acid, increases its solubility in an alkali developer (hereinafter also referred to as an acid-decomposable resin or resin (P)), [2] a compound that when exposed to actinic rays or radiation, generates an acid (hereinafter also referred to as an acid generator or compound (Q)), and [3] a basic compound (R) with a structure to be specified below.

The inventors have found that high sensitivity, favorable pattern shape, favorable roughness characteristic and reduction of residue defects can be attained by employing a composition comprising a basic compound (R) with a specified structure. Further, the inventors have found that this effect is especially striking when a pattern is formed on an acid substrate.

The above-mentioned components of the composition will be sequentially described below.

[1] Acid-decomposable resin The composition of the present invention contains an acid-decomposable resin (P).

<Repeating Unit (A)>

The acid-decomposable resin comprises an acid-decomposable repeating unit (A). The repeating unit (A) is a repeating unit that when acted on by an acid, is decomposed to thereby generate an alkali-soluble group.

As the alkali-soluble group, there can be mentioned a phenolic hydroxyl group, a carboxyl group, a fluoroalcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

As preferred alkali-soluble groups, there can be mentioned a phenolic hydroxyl group, a carboxyl group, a fluoroalcohol group (preferably hexafluoroisopropanol) and a sulfonic acid group.

The acid-decomposable group is preferably a group as obtained by substituting the hydrogen atom of any of these alkali-soluble groups with an acid-cleavable group.

As the acid eliminable group, there can be mentioned, for example, —C(R₃₆)(R₃₇)(R₃₈), —C(R₃₆) (R₃₇)(OR₃₉), —C(R₀₁)(R₀₂)(OR₃₉) or the like.

In the formulae, each of R₃₆ to R₃₉ independently represents an alkyl group, a cycroalkyl group, a monovalent aromatic ring group, a combination of an alkylene group and a monovalent aromatic ring group or an alkenyl group. R₃₆ and R₃₇ may be bonded with each other to thereby form a ring structure.

Each of R₀₁ to R₀₂ independently represents a hydrogen atom, an alkyl group, a cycroalkyl group, a monovalent aromatic ring group, a combination of an alkylene group and a monovalent aromatic ring group or an alkenyl group.

Preferably, the acid-decomposable group is a cumyl ester group, an enol ester group, an acetal ester group, a tertiary alkyl ester group or the like. A tertiary alkyl ester group is more preferred.

The repeating unit (A) is preferably any of those of general formula (V) below.

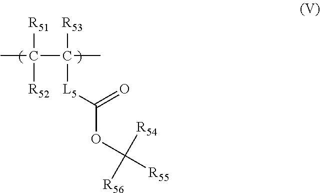

In general formula (V),

each of R₅₁, R₅₂ and R₅₃ independently represents a hydrogen atom, an alkyl group, a cycloalkyl group, a halogen atom, a cyano group or an alkoxycarbonyl group, provided that R₅₂ may be bonded to L₅ to thereby form a ring, which R₅₂ represents an alkylene group.

L₅ represents a single bond or a bivalent connecting group, provided that when a ring is formed in cooperation with R₅₂, L₅ represents a trivalent connecting group.

R₅₄ represents an alkyl group, and each of R₅₅ and R₅₆ independently represents a hydrogen atom, an alkyl group, a cycloalkyl group or a monovalent aromatic ring group, provided that R₅₅ and R₅₆ may be bonded to each other to thereby form a ring, and provided that R₅₅ and R₅₆ are not simultaneously hydrogen atoms.

General formula (V) will be described in greater detail below.

As a preferred alkyl group represented by each of R₅₁ to R₅₃ in general formula (V), there can be mentioned an optionally substituted alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having up to 8 carbon atoms is more preferred, and an alkyl group having up to 3 carbon atoms is most preferred.

The alkyl group contained in the alkoxycarbonyl group is preferably the same as that represented by each of R₅₁ to R₅₃ above.

The cycloalkyl group may be monocyclic or polycyclic. The cycloalkyl group is preferably an optionally substituted monocycloalkyl group having 3 to 8 carbon atoms, such as a cyclopropyl group, a cyclopentyl group or a cyclohexyl group.

As the halogen atom, there can be mentioned a fluorine atom, a chlorine atom, a bromine atom or an iodine atom. A fluorine atom is most preferred.

As preferred substituents that can be introduced in these groups, there can be mentioned, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, a nitro group and the like. Preferably, the number of carbon atoms of each of the substituents is up to 8.

When R₅₂ is an alkylene group and forms a ring in cooperation with L₅, the alkylene group is preferably an alkylene group having 1 to 8 carbon atoms, such as a methylene group, an ethylene group, a propylene group, a butylene group, a hexylene group or an octylene group. An alkylene group having 1 to 4 carbon atoms is more preferred, and an alkylene group having 1 or 2 carbon atoms is most preferred. The ring formed by the mutual bonding of R₅₂ and L₅ is most preferably a 5- or 6-membered ring.

In formula (V), each of R₅₁ and R₅₃ is more preferably a hydrogen atom, an alkyl group or a halogen atom, most preferably a hydrogen atom, a methyl group, an ethyl group, a trifluoromethyl group (—CF₃), a hydroxymethyl group (—CH₂—OH), a chloromethyl group (—CH₂—Cl) or a fluorine atom (—F). R₅₂ is more preferably a hydrogen atom, an alkyl group, a halogen atom or an alkylene group (forming a ring in cooperation with L₅), most preferably a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (forming a ring in cooperation with L₅) or an ethylene group (forming a ring in cooperation with L₅).

As the bivalent connecting group represented by L₅, there can be mentioned an alkylene group, a bivalent aromatic ring group, —COO—L₁-, —O-L₁-, a group consisting of a combination of two or more thereof or the like. In the formulae, L₁ represents an alkylene group, a cycloalkylene group, a bivalent aromatic ring group or a group consisting of an alkylene group combined with a bivalent aromatic ring group.

L₅ is preferably a single bond, any of the groups of the formula —COO-L₁- or a bivalent aromatic ring group. When the exposure is conducted using an ArF excimer laser, a single bond or —COO-L₁- is preferred from the viewpoint that the absorption in the region of 193 nm can be reduced. L₁ is preferably an alkylene group having 1 to 5 carbon atoms, more preferably a methylene group or a propylene group.

The alkyl group represented by each of R₅₄ to R₅₆ is preferably one having 1 to 20 carbon atoms, more preferably one having 1 to 10 carbon atoms and most preferably one having 1 to 4 carbon atoms, such as a methyl group, an ethyl group, an n-propyl group, an isopropyl group, an n-butyl group, an isobutyl group or a t-butyl group.

The cycloalkyl group represented by each of R₅₅ and R₅₆ is preferably one having 3 to 20 carbon atoms. It may be a monocyclic one, such as a cyclopentyl group or a cyclohexyl group, or a polycyclic one, such as a norbonyl group, an adamantyl group, a tetracyclodecanyl group or a tetracyclododecanyl group.

The ring formed by the mutual bonding of R₅₅ and R₅₆ preferably has 3 to 20 carbon atoms. It may be a monocyclic one, such as a cyclopentyl group or a cyclohexyl group, or a polycyclic one, such as a norbonyl group, an adamantyl group, a tetracyclodecanyl group or a tetracyclododecanyl group. When R₅₅ and R₅₆ are bonded to each other to thereby form a ring, R₅₄ is preferably an alkyl group having 1 to 3 carbon atoms, more preferably a methyl group or an ethyl group.

The monovalent aromatic ring group represented by each of R₅₅ and R₅₆ is preferably one having 6 to 20 carbon atoms. As such, there can be mentioned, for example, a phenyl group, a naphthyl group or the like. When either R₅₅ or R₅₆ is a hydrogen atom, it is preferred for the other to be a monovalent aromatic ring group.

When the exposure is conducted using an ArF excimer laser, it is preferred for each of R₅₅ and R₅₆ to independently represent a hydrogen atom, an alkyl group or a cycloalkyl group from the viewpoint that the absorption in the region of 193 nm can be reduced.

As the method of synthesizing the monomers corresponding to the repeating units of general formula (V), use can be made of a routine process for synthesizing esters containing a polymerizable group. The method is not particularly limited.

Particular examples of the repeating units (A) of general formula (V) are shown below, which however in no way limit the scope of the present invention.

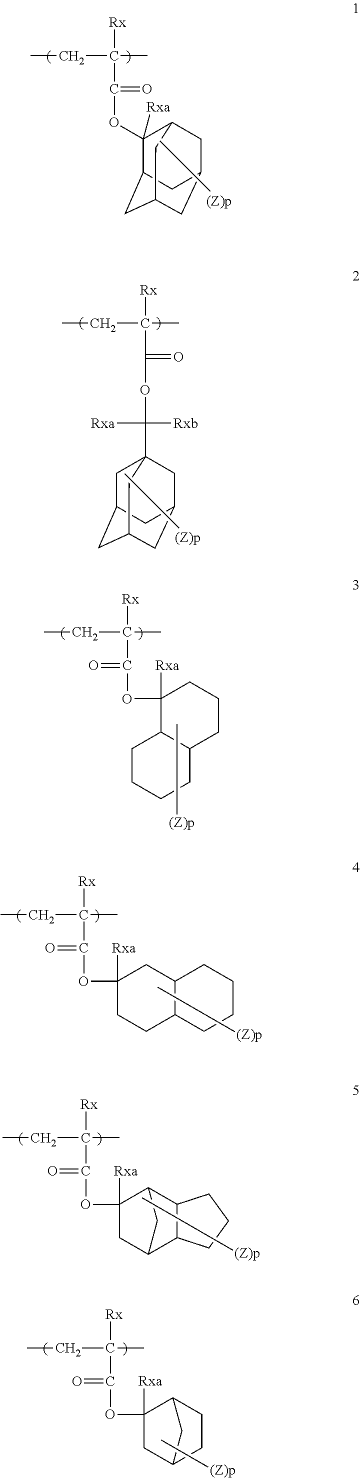

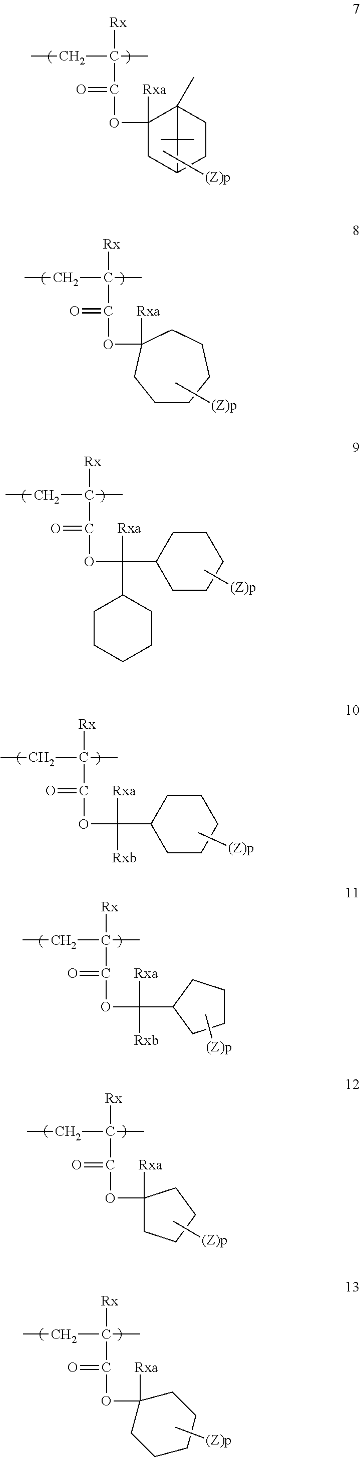

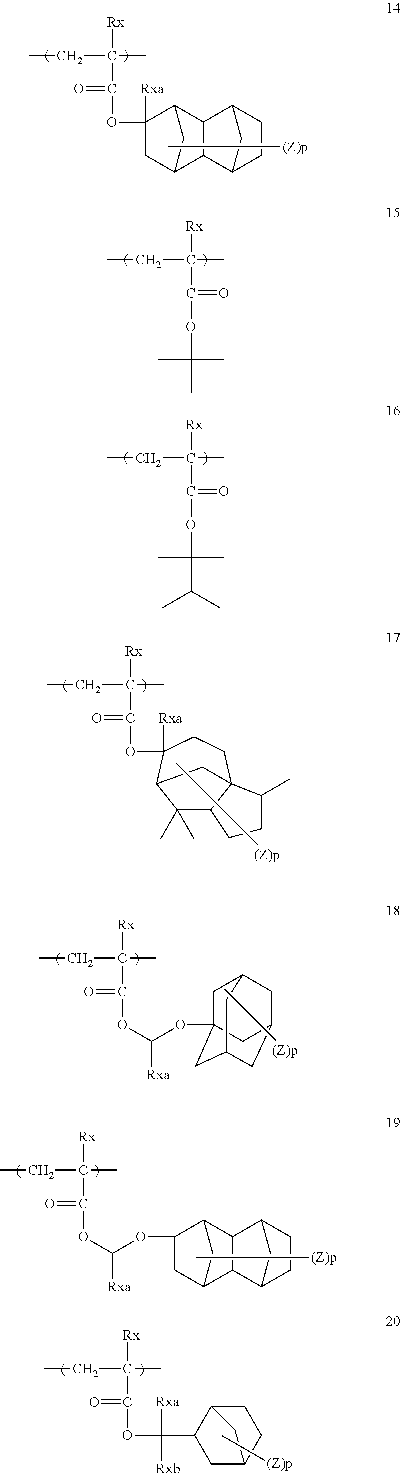

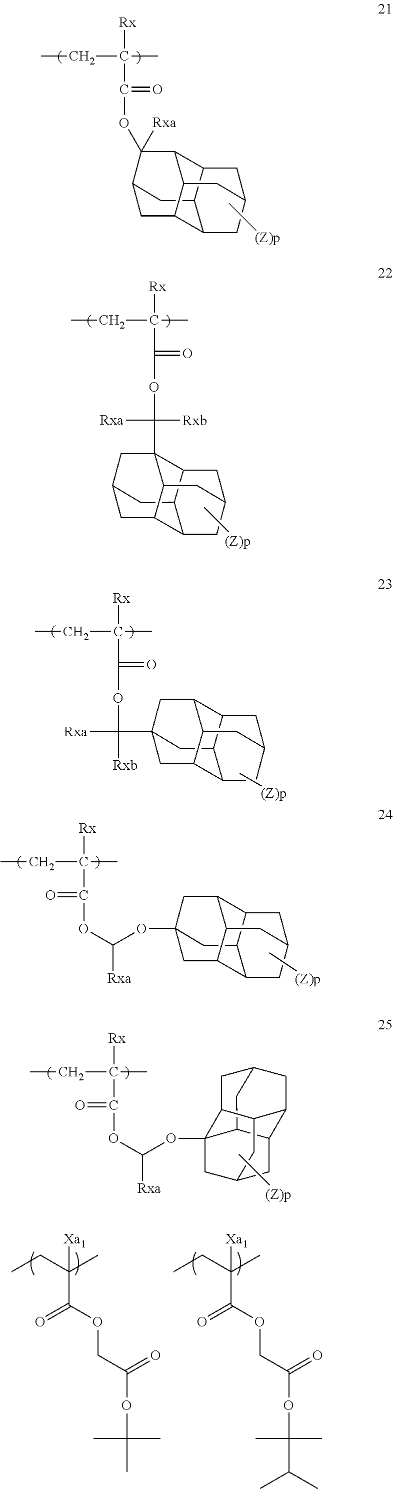

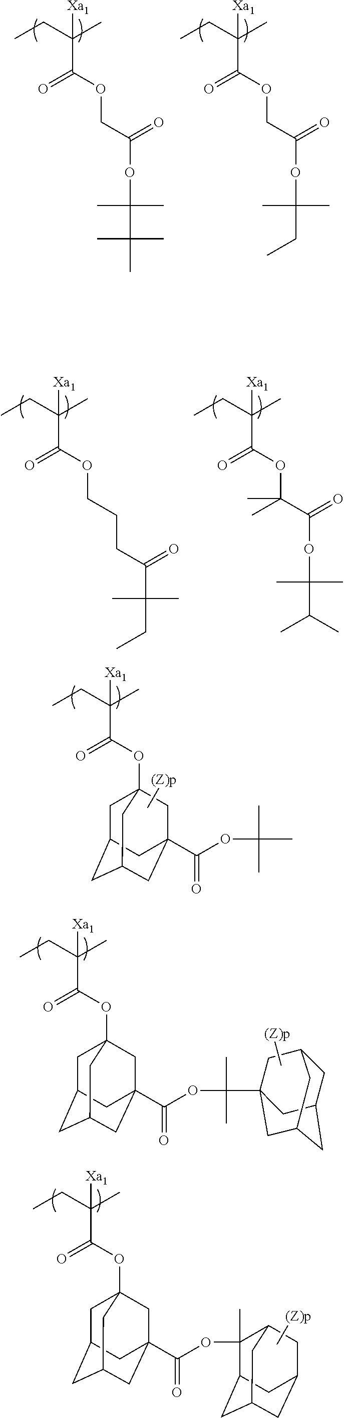

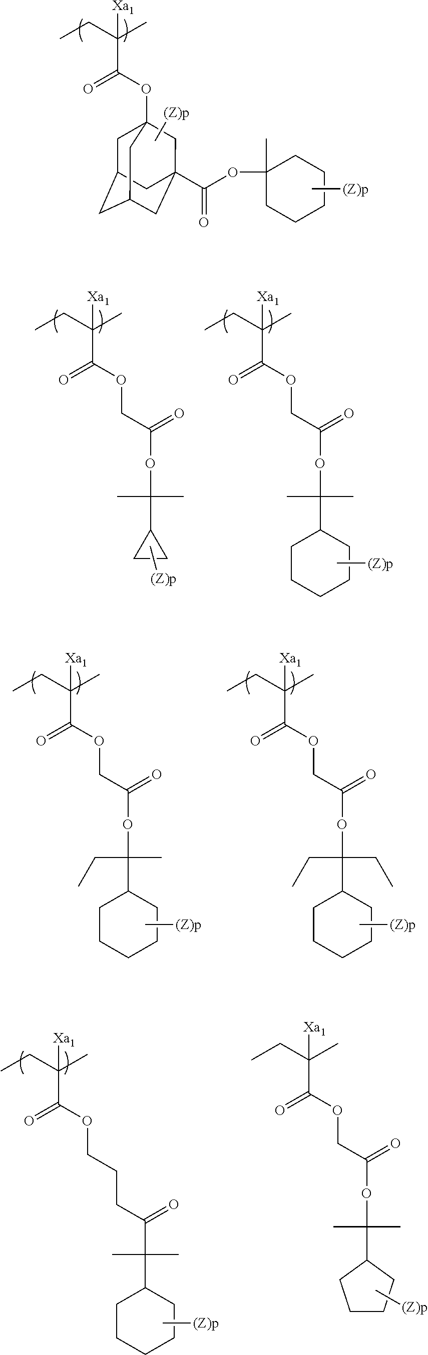

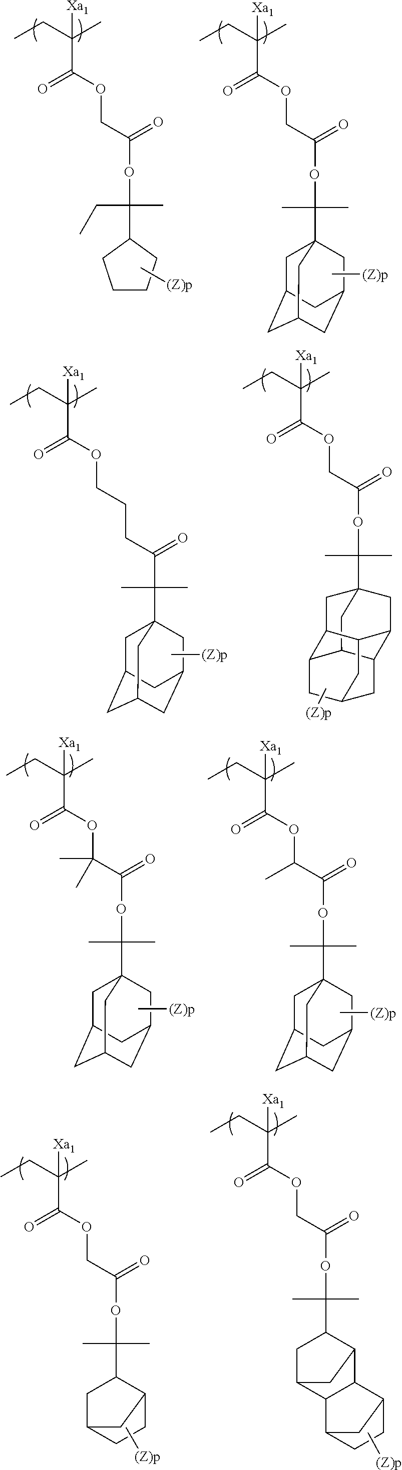

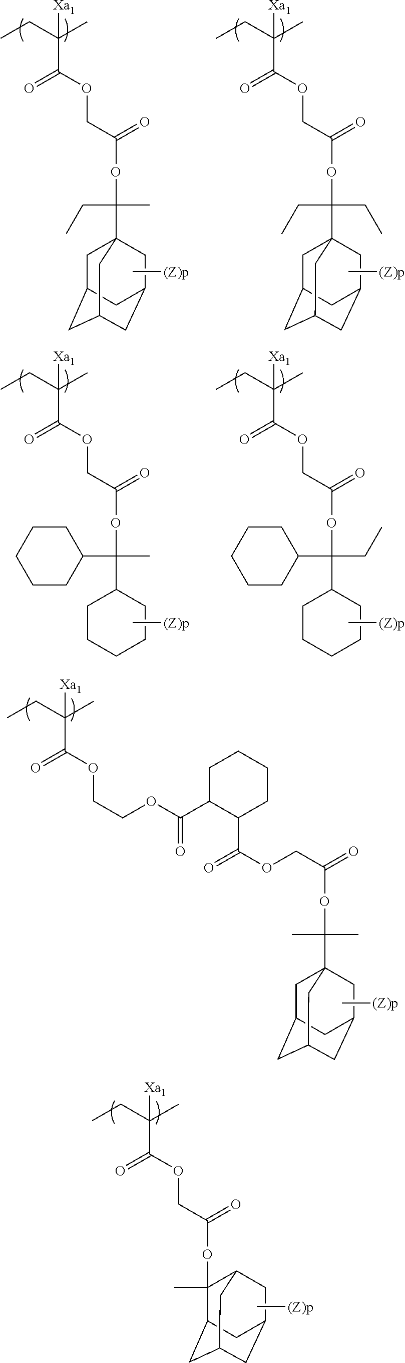

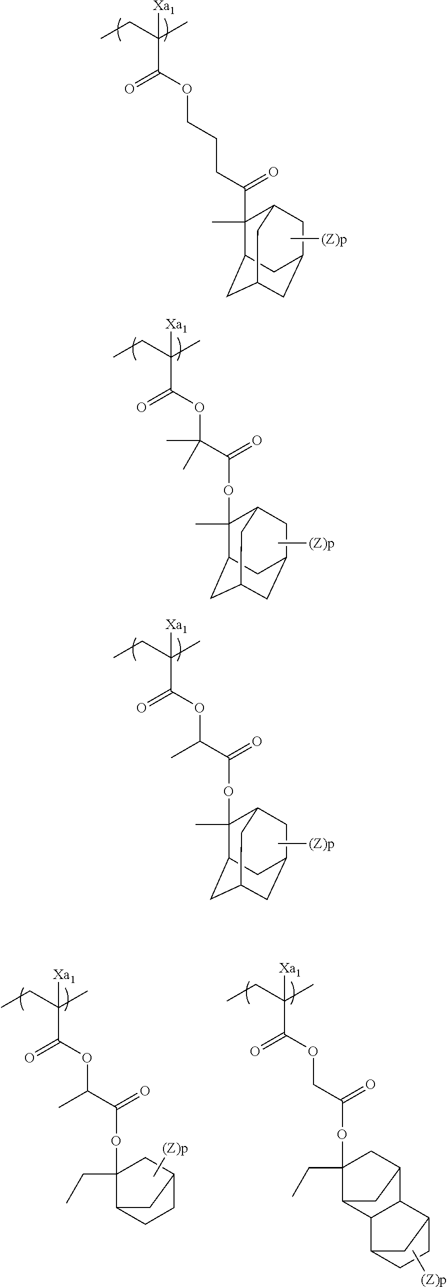

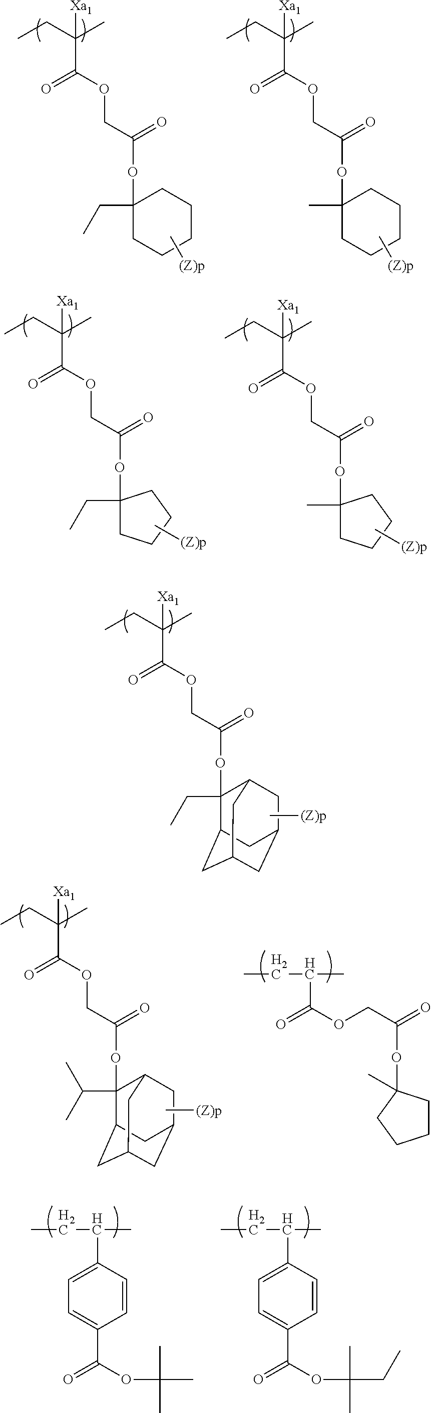

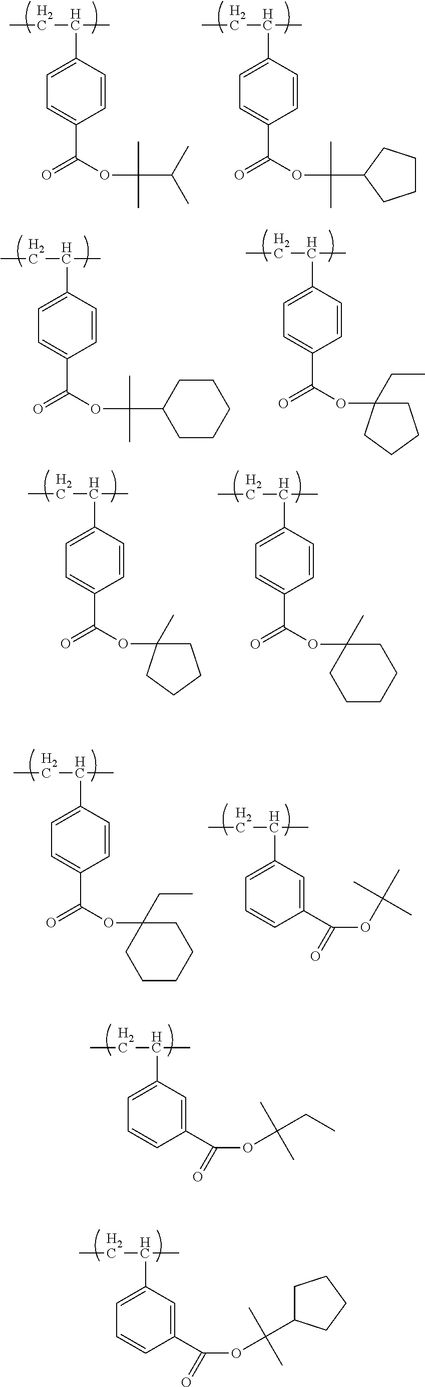

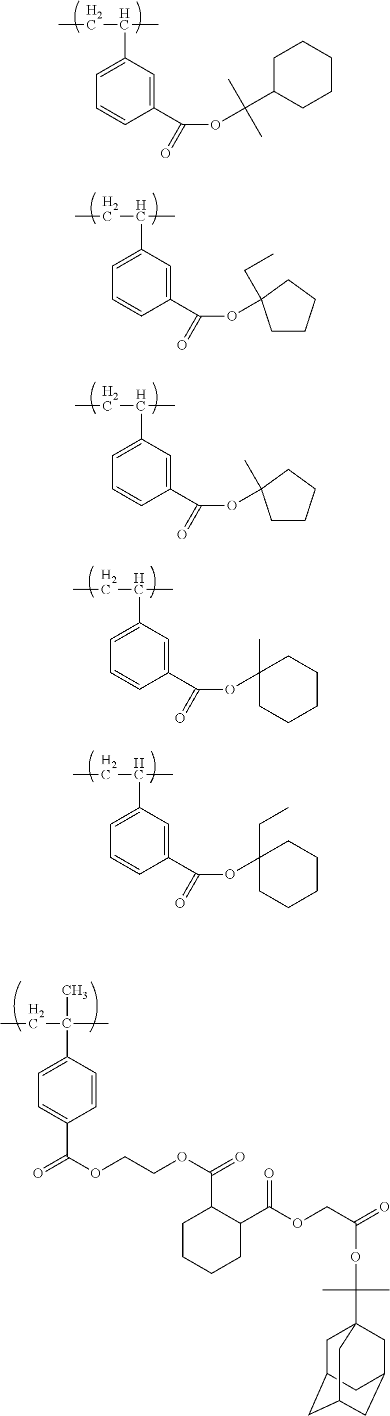

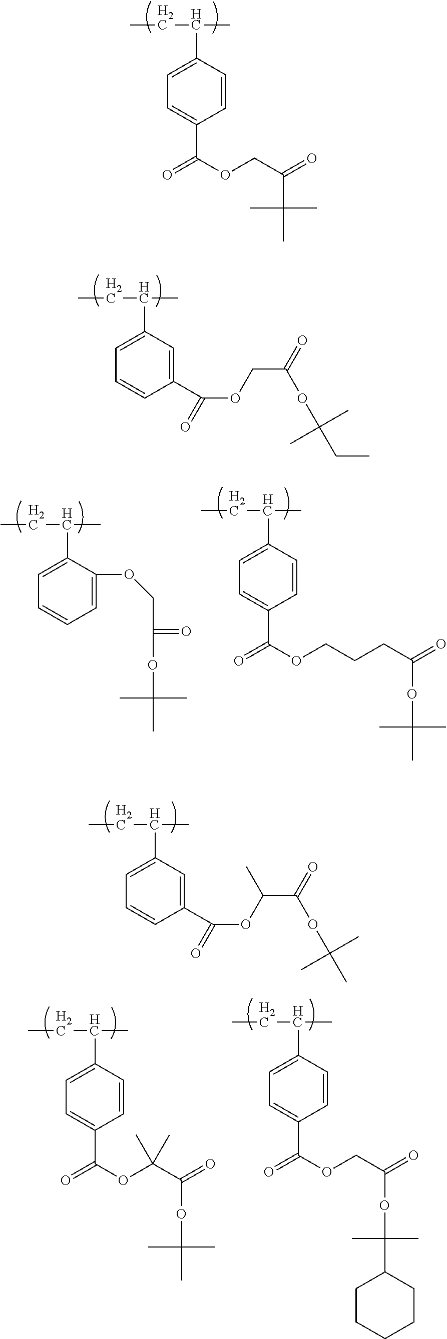

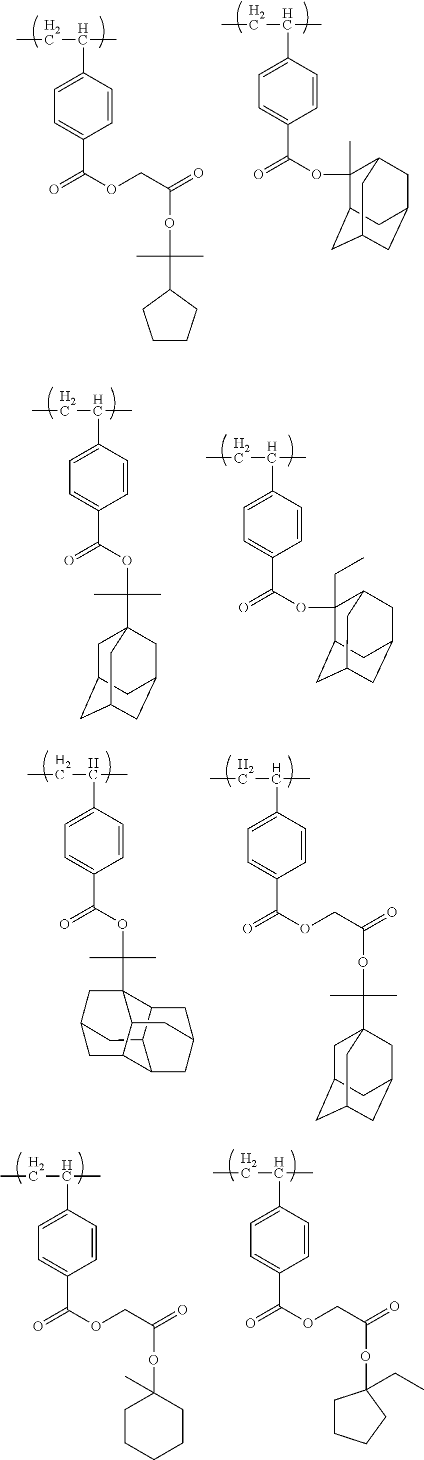

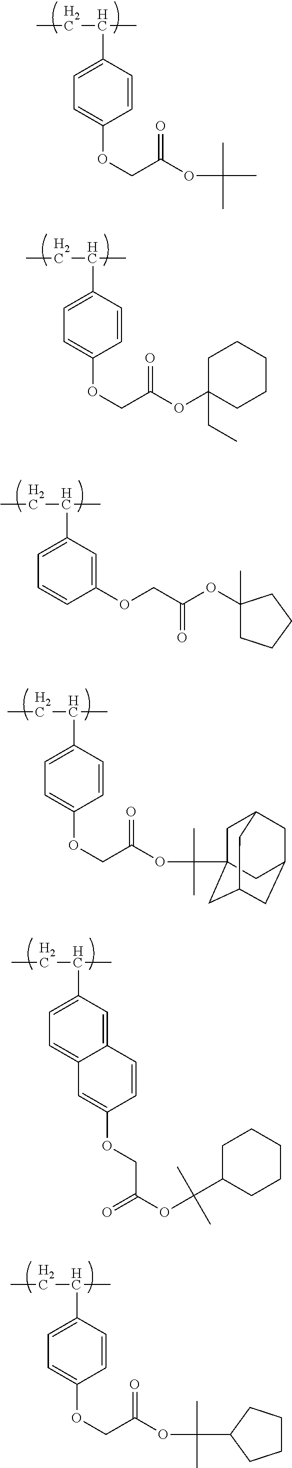

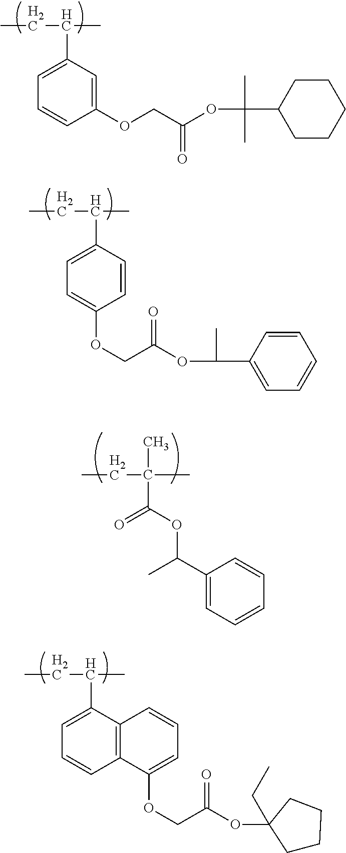

Moreover, the resin (P) may contain any of the repeating units of general formula (VI) below as the repeating unit (A). This is especially preferred when the exposure is performed using electron beams or EUV light.

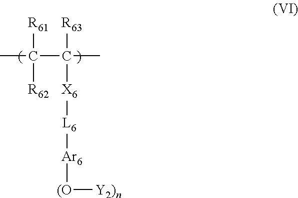

In general formula (VI), each of R₆₁, R₆₂ and R₆₃ independently represents a hydrogen atom, an alkyl group, a cycloalkyl group, a halogen atom, a cyano group or an alkoxycarbonyl group. R₆₂ may be bonded to Ar₆ to thereby form a ring. If so, R₆₂ represents an alkylene group.

X₆ represents a single bond, —COO— or —CONR₆₄— in which R₆₄ represents a hydrogen atom or an alkyl group,

L₆ represents a single bond or an alkylene group,

Ar₆ represents a bivalent aromatic ring group,

Y₂, when each independently, represents a hydrogen atom or a group that when acted on by an acid, is cleaved, provided that at least one of Y₂s is a group that when acted on by an acid, is cleaved, and

n is an integer of 1 to 4.

General formula (VI) will be described in greater detail below.

As a preferred alkyl group represented by each of R₆₁ to R₆₃ in general formula (VI), there can be mentioned an optionally substituted alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having up to 8 carbon atoms is more preferred.

The alkyl group contained in the alkoxycarbonyl group is preferably the same as that represented by each of R₆₁ to R₆₃ above.

The cycloalkyl group may be monocyclic or polycyclic. The cycloalkyl group is preferably an optionally substituted monocycloalkyl group having 3 to 8 carbon atoms, such as a cyclopropyl group, a cyclopentyl group or a cyclohexyl group.

As the halogen atom, there can be mentioned a fluorine atom, a chlorine atom, a bromine atom or an iodine atom. A fluorine atom is preferred.

When R₆₂ is an alkylene group, the alkylene group is preferably an optionally substituted alkylene group having 1 to 8 carbon atoms, such as a methylene group, an ethylene group, a propylene group, a butylene group, a hexylene group or an octylene group.

The alkyl group represented by R₆₄ of the —CONR₆₄—(R₆₄ represents a hydrogen atom or an alkyl group) represented by X₆ is the same as set forth above as the alkyl group represented by each of R₆₁ to R₆₃.

X₆ is preferably a single bond, —COO— or —CONH—, more preferably a single bond or —COO—.

The alkylene group represented by L₆ is preferably an optionally substituted alkylene group having 1 to 8 carbon atoms, such as a methylene group, an ethylene group, a propylene group, a butylene group, a hexylene group or an octylene group. The ring formed by the mutual bonding of R₆₂ and L₆ is most preferably a 5- or 6-membered ring.

Ar₆ represents a bivalent aromatic ring group. A substituent may be introduced in the bivalent aromatic ring group. As preferred examples thereof, there can be mentioned an arylene group having 6 to 18 carbon atoms, such as a phenylene group, a tolylene group or a naphthylene group, and a bivalent aromatic ring group containing a heteroring, such as thiophene, furan, pyrrole, benzothiophene, benzofuran, benzopyrrole, triazine, imidazole, benzimidazole, triazole, thiadiazole or triazole.

Particular examples of the substituents that can be introduced in the above alkyl group, cycloalkyl group, alkoxycarbonyl group, alkylene group and bivalent aromatic ring group are the same as those which can be introduced in the above groups represented by R₅₁ to R₅₃ in general formula (V).

In the formula, n is preferably 1 or 2, more preferably 1.

Each of n Y₂s independently represents a hydrogen atom or a group that is cleaved by the action of an acid, provided that at least one of n Y₂s represents a group that is cleaved by the action of an acid.

As the group that is cleaved by the action of an acid, Y₂, there can be mentioned, for example, —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈), —CH(R₃₆)(Ar) or the like.

In the formulae, each of R₃₆ to R₃₉ independently represents an alkyl group, a cycloalkyl group, a monovalent aromatic ring group, a group composed of a combination of an alkylene group and a monovalent aromatic ring group, or an alkenyl group. R₃₆ and R₃₇ may be bonded to each other to thereby form a ring.

Each of R₀₁ and R₀₂ independently represents a hydrogen atom, an alkyl group, a cycloalkyl group, a monovalent aromatic ring group, a group composed of a combination of an alkylene group and a monovalent aromatic ring group, or an alkenyl group.

Ar represents a monovalent aromatic ring group.

Each of the alkyl groups represented by R₃₆ to R₃₉, R₀₁ and R₀₂ preferably has 1 to 8 carbon atoms. For example, there can be mentioned a methyl group, an ethyl group, a propyl group, an n-butyl group, a sec-butyl group, a hexyl group, an octyl group or the like.

The cycloalkyl groups represented by R₃₆ to R₃₉, R₀₁ and R₀₂ may be monocyclic or polycyclic. When the cycloalkyl group is monocyclic, it is preferably a cycloalkyl group having 3 to 8 carbon atoms. As such, there can be mentioned, for example, a cyclopropyl group, a cyclobutyl group, a cyclopentyl group, a cyclohexyl group, a cyclooctyl group or the like. When the cycloalkyl group is polycyclic, it is preferably a cycloalkyl group having 6 to 20 carbon atoms. As such, there can be mentioned, for example, an adamantyl group, a norbornyl group, an isobornyl group, a camphonyl group, a dicyclopentyl group, an α-pinanyl group, a tricyclodecanyl group, a tetracyclododecyl group, an androstanyl group or the like. With respect to these, the carbon atoms of each of the cycloalkyl groups may be partially substituted with a heteroatom, such as an oxygen atom.

Each of the monovalent aromatic ring groups represented by R₃₆ to R₃₉, R₀₁, R₀₂ and Ar is preferably one having 6 to 10 carbon atoms. For example, there can be mentioned an aryl group, such as a phenyl group, a naphthyl group or an anthryl group, or a monovalent aromatic ring group containing a heteroring, such as thiophene, furan, pyrrole, benzothiophene, benzofuran, benzopyrrole, triazine, imidazole, benzimidazole, triazole, thiadiazole or thiazole.

Each of the groups consisting of an alkylene group combined with a monovalent aromatic ring group, represented by R₃₆ to R₃₉, R₀₁ and R₀₂ is preferably an aralkyl group having 7 to 12 carbon atoms. For example, there can be mentioned a benzyl group, a phenethyl group, a naphthylmethyl group or the like.

Each of the alkenyl groups represented by R₃₆ to R₃₉, R₀₁ and R₀₂ preferably has 2 to 8 carbon atoms. For example, there can be mentioned a vinyl group, an allyl group, a butenyl group, a cyclohexenyl group or the like.

The ring formed by the mutual bonding of R₃₆ and R₃₇ may be monocyclic or polycyclic. The monocyclic structure is preferably a cycloalkyl structure having 3 to 8 carbon atoms. As such, there can be mentioned, for example, a cyclopropane structure, a cyclobutane structure, a cyclopentane structure, a cyclohexane structure, a cycloheptane structure, a cyclooctane structure or the like. The polycyclic structure is preferably a cycloalkyl structure having 6 to 20 carbon atoms. As such, there can be mentioned, for example, an adamantane structure, a norbornane structure, a dicyclopentane structure, a tricyclodecane structure, a tetracyclododecane structure or the like. With respect to these, the carbon atoms of each of the cycloalkyl structures may be partially substituted with a heteroatom, such as an oxygen atom.

Substituents may be introduced in the above groups represented by R₃₆ to R₃₉, R₀₁, R₀₂ and Ar. As the substituents, there can be mentioned, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, a nitro group and the like. Preferably, the number of carbon atoms of each of the substituents is up to 8.

The group that is cleaved by the action of an acid, Y₂, more preferably has any of the structures of general formula (VI-A) below.

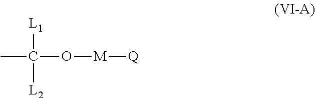

In the formula, each of L₁ and L₂ independently represents a hydrogen atom, an alkyl group, a cycloalkyl group, a monovalent aromatic ring group or a group consisting of an alkylene group combined with a monovalent aromatic ring group.

M represents a single bond or a bivalent connecting group.

Q represents an alkyl group, a cycloalkyl group optionally containing a heteroatom, a monovalent aromatic ring group optionally containing a heteroatom, an amino group, an ammonium group, a mercapto group, a cyano group or an aldehyde group.

At least two of Q, M and L₁ may be bonded to each other to thereby form a ring (preferably, a 5-membered or 6-membered ring).

The alkyl groups represented by L₁ and L₂ are, for example, alkyl groups each having 1 to 8 carbon atoms. As preferred examples thereof, there can be mentioned a methyl group, an ethyl group, a propyl group, an n-butyl group, a sec-butyl group, a hexyl group and an octyl group.

The cycloalkyl groups represented by L₁ and L₂ are, for example, cycloalkyl groups each having 3 to 15 carbon atoms. As preferred examples thereof, there can be mentioned a cyclopentyl group, a cyclohexyl group, a norbornyl group, an adamantyl group and the like.

The monovalent aromatic ring groups represented by L₁ and L₂ are, for example, aryl groups each having 6 to 15 carbon atoms. As preferred examples thereof, there can be mentioned a phenyl group, a tolyl group, a naphthyl group, an anthryl group and the like.

The groups each consisting of an alkylene group combined with a monovalent aromatic ring group, represented by L₁ and L₂ are, for example, those each having 6 to 20 carbon atoms. There can be mentioned aralkyl groups, such as a benzyl group and a phenethyl group.

The bivalent connecting group represented by M is, for example, an alkylene group (e.g., a methylene group, an ethylene group, a propylene group, a butylene group, a hexylene group, an octylene group, etc.), a cycloalkylene group (e.g., a cyclopentylene group, a cyclohexylene group, an adamantylene group, etc.), an alkenylene group (e.g., an ethylene group, a propenylene group, a butenylene group, etc.), a bivalent aromatic ring group (e.g., a phenylene group, a tolylene group, a naphthylene group, etc.), —S—, —O—, —CO—, —SO₂—, —N(R₀)— or a bivalent connecting group resulting from combination of these groups. R₀ represents a hydrogen atom or an alkyl group (for example, an alkyl group having 1 to 8 carbon atoms; in particular, a methyl group, an ethyl group, a propyl group, an n-butyl group, a sec-butyl group, a hexyl group, an octyl group or the like).

The alkyl group represented by Q is the same as mentioned above as being represented by each of L₁ and L₂.

As the aliphatic hydrocarbon ring group containing no heteroatom and monovalent aromatic ring group containing no heteroatom respectively contained in the cycloalkyl group optionally containing a heteroatom and monovalent aromatic ring group optionally containing a heteroatom, both represented by Q, there can be mentioned, for example, the cycloalkyl group and monovalent aromatic ring group mentioned above as being represented by each of L₁ and L₂. Preferably, each thereof has 3 to 15 carbon atoms.

As the cycloalkyl group containing a heteroatom and monovalent aromatic ring group containing a heteroatom, there can be mentioned, for example, groups having a heterocyclic structure, such as thiirane, cyclothiorane, thiophene, furan, pyrrole, benzothiophene, benzofuran, benzopyrrole, triazine, imidazole, benzimidazole, triazole, thiadiazole, thiazole and pyrrolidone. However, the above cycloalkyl groups and monovalent aromatic ring groups are not limited to these as long as a structure generally known as a heteroring (ring formed by carbon and a heteroatom, or ring formed by heteroatoms) is included.

As the ring that may be formed by the mutual bonding of at least two of Q, M and L₁, there can be mentioned one resulting from the mutual bonding of at least two of Q, M and L₁ so as to form, for example, a propylene group or a butylene group and subsequent formation of a 5-membered or 6-membered ring containing an oxygen atom.

Substituents may be introduced in the groups represented by L₁, L₂, M and Q in general formula (VI-A). As the substituents, there can be mentioned, for example, those mentioned above as being optionally introduced in R₃₆ to R₃₉, R₀₁, R₀₂ and Ar. Preferably, the number of carbon atoms of each of the substituents is up to 8.

The groups of the formula -M-Q are preferably groups each composed of 1 to 30 carbon atoms, more preferably 5 to 20 carbon atoms.

Particular examples of the repeating units of general formula (VI) are shown below as preferred particular examples of the repeating units (A), which however in no way limit the scope of the present invention.

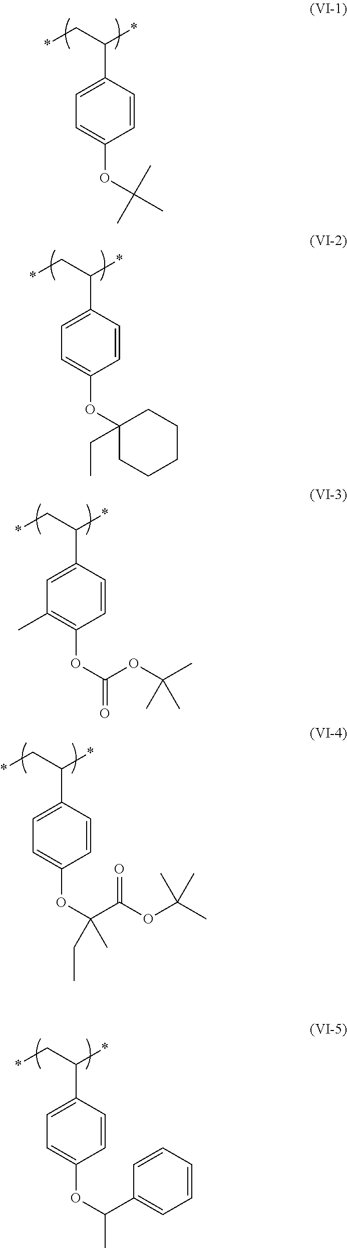

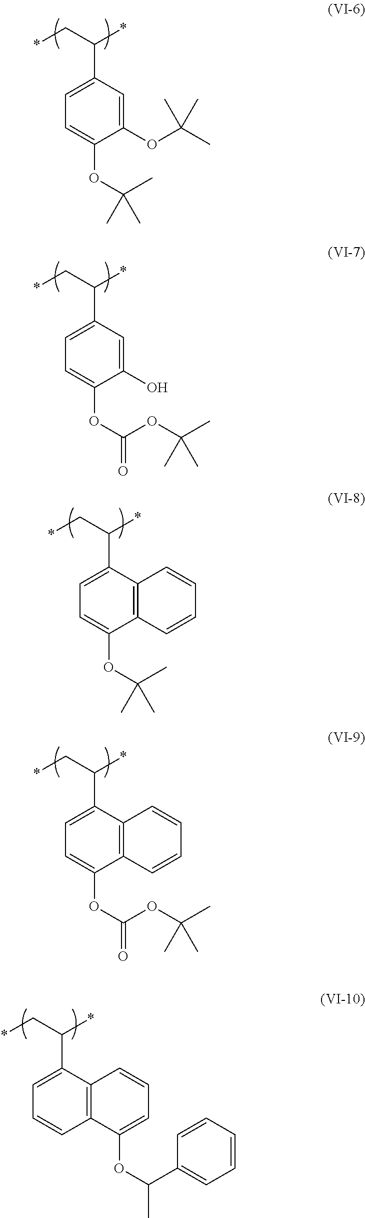

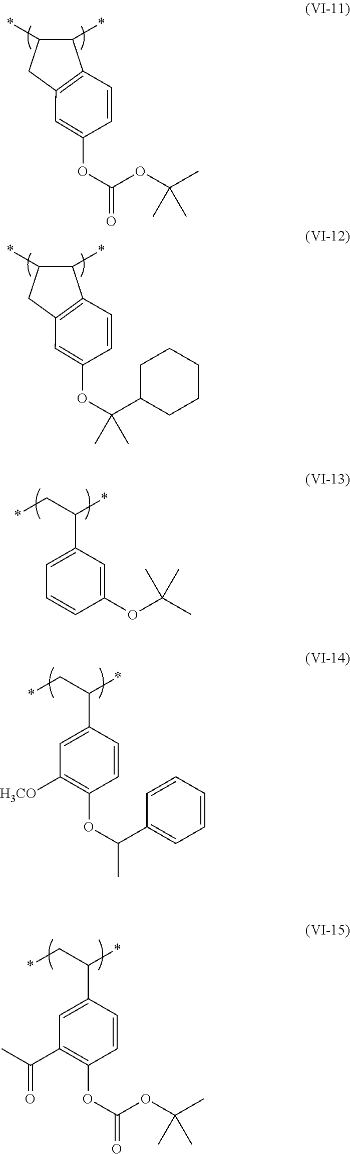

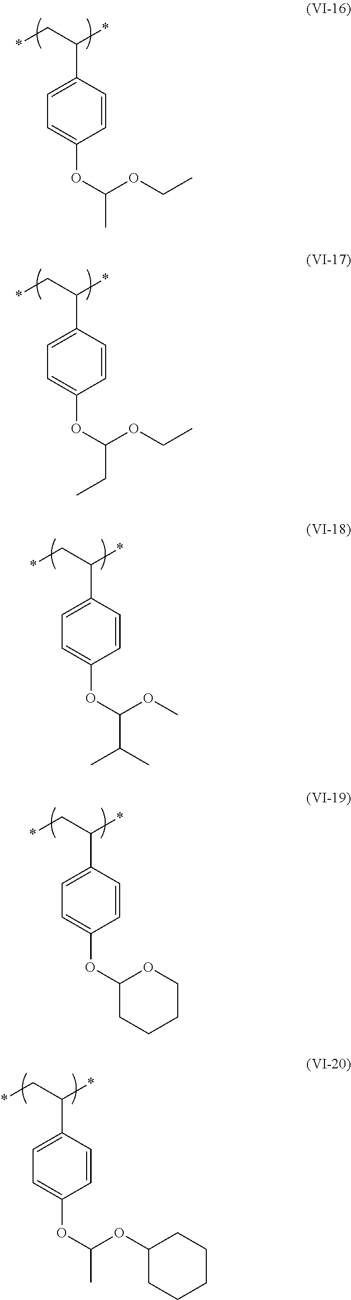

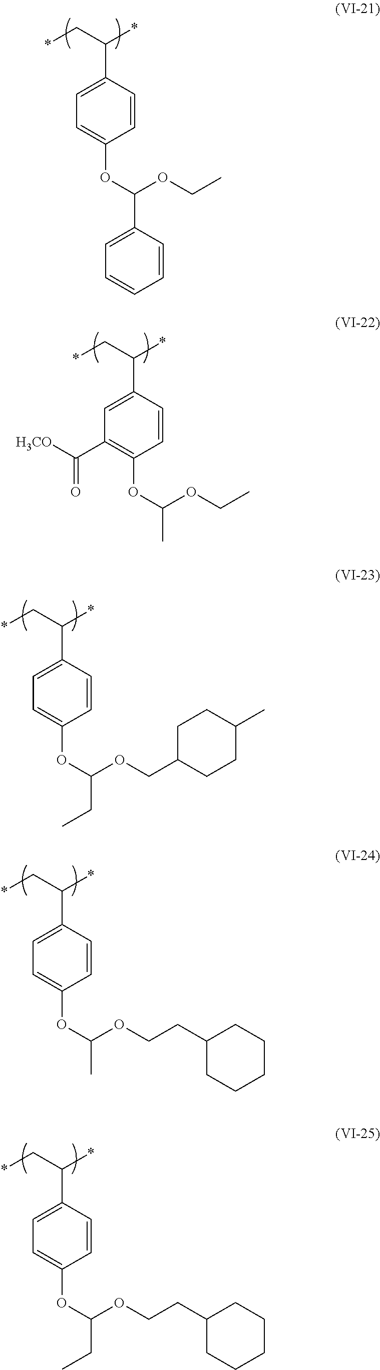

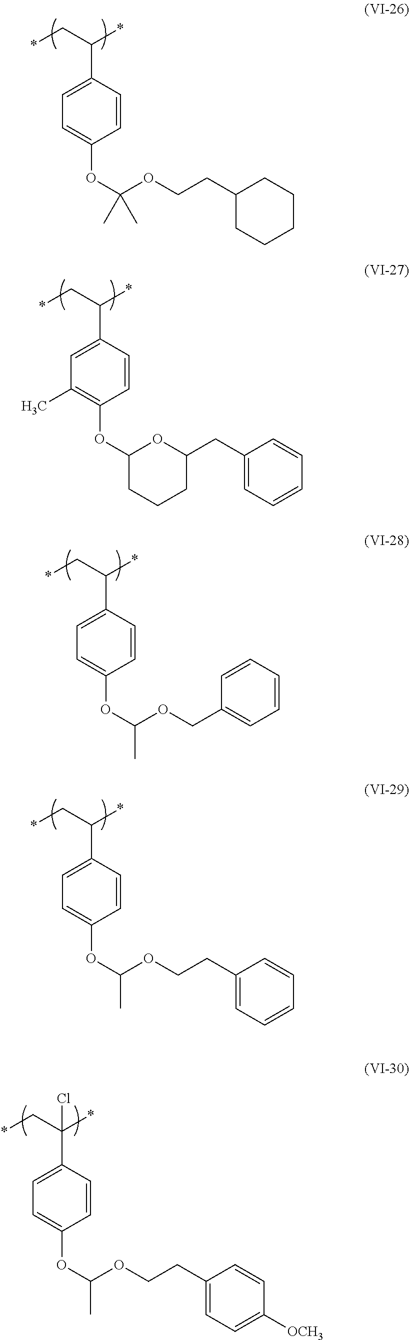

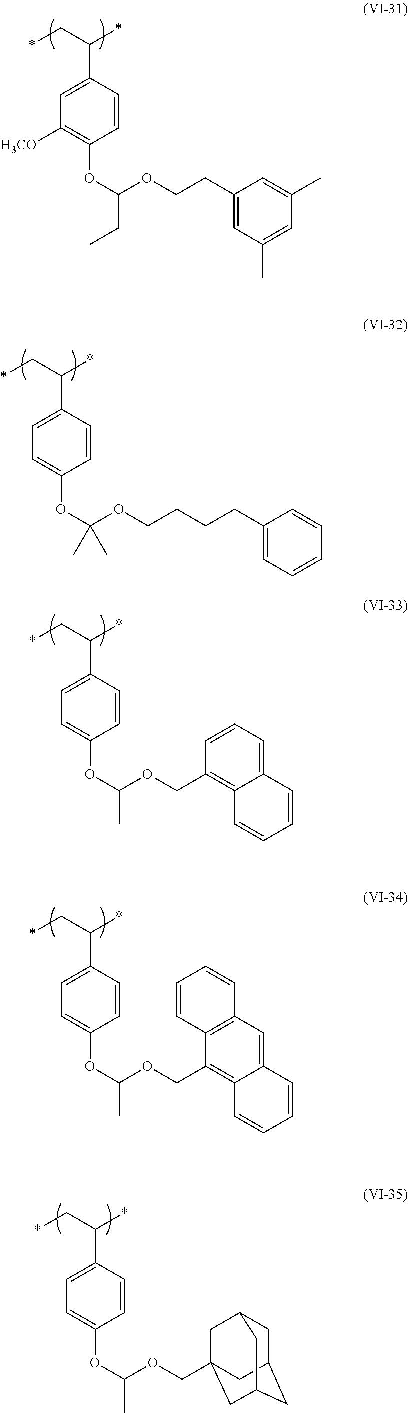

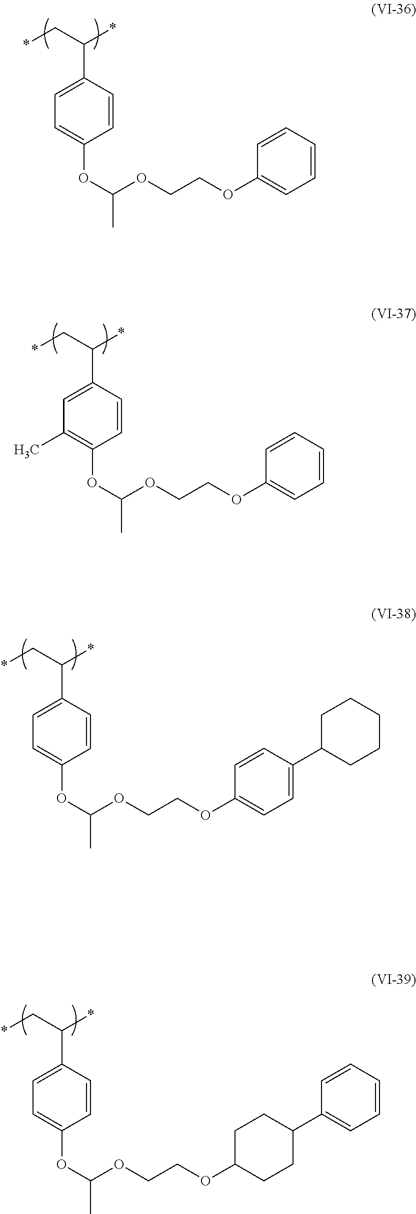

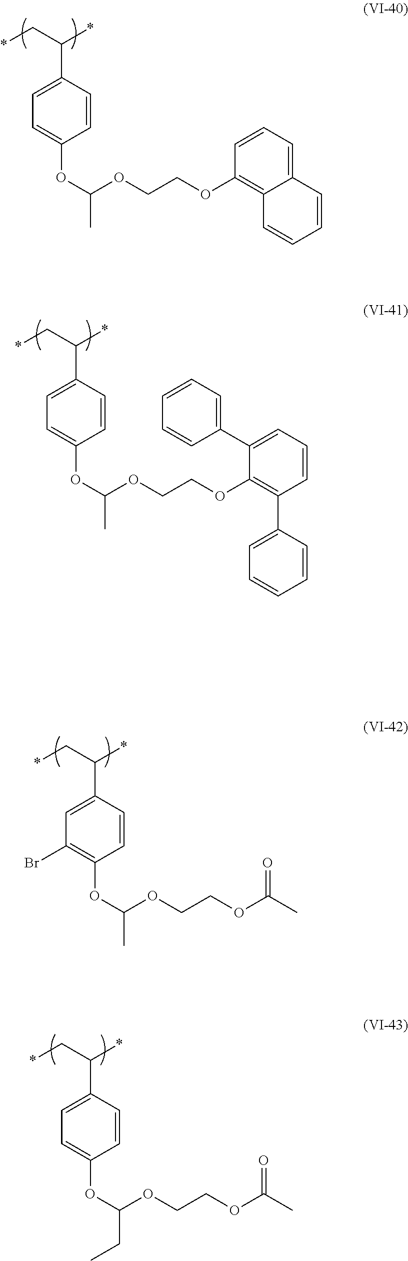

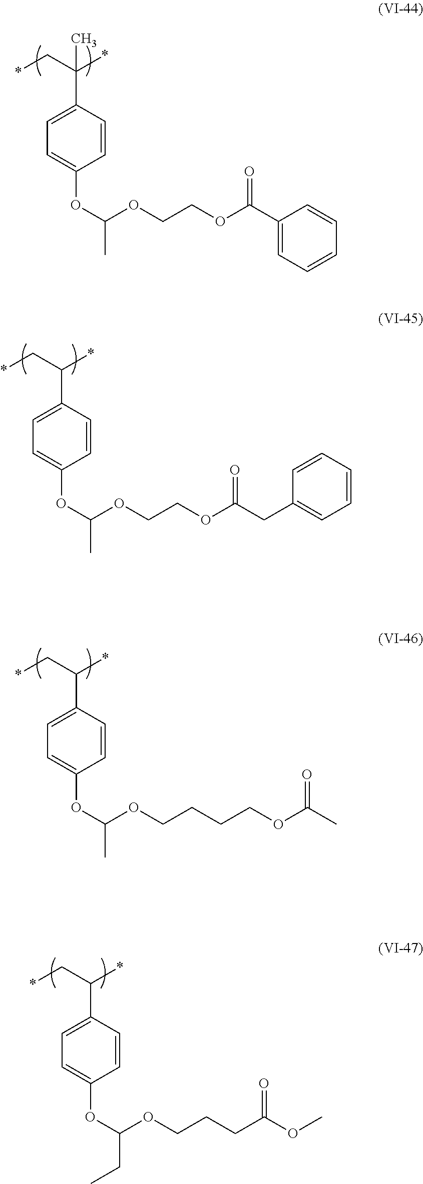

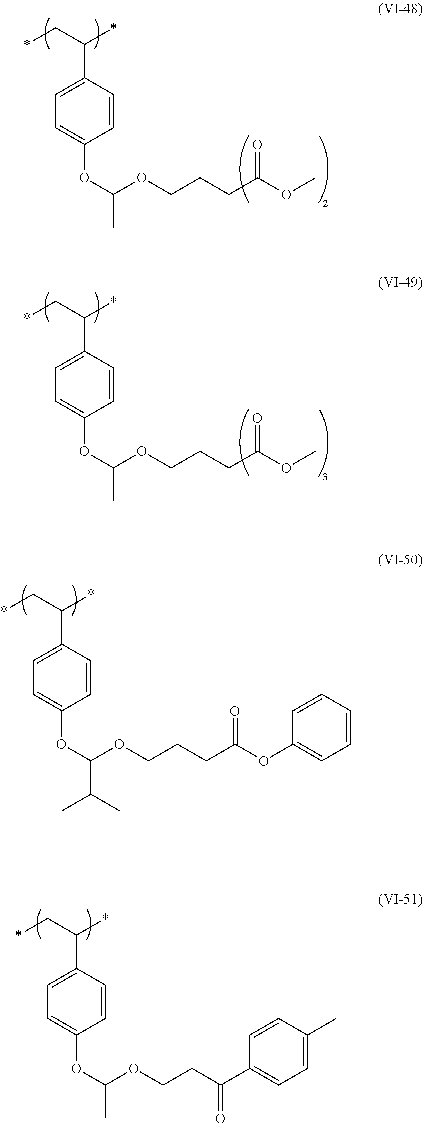

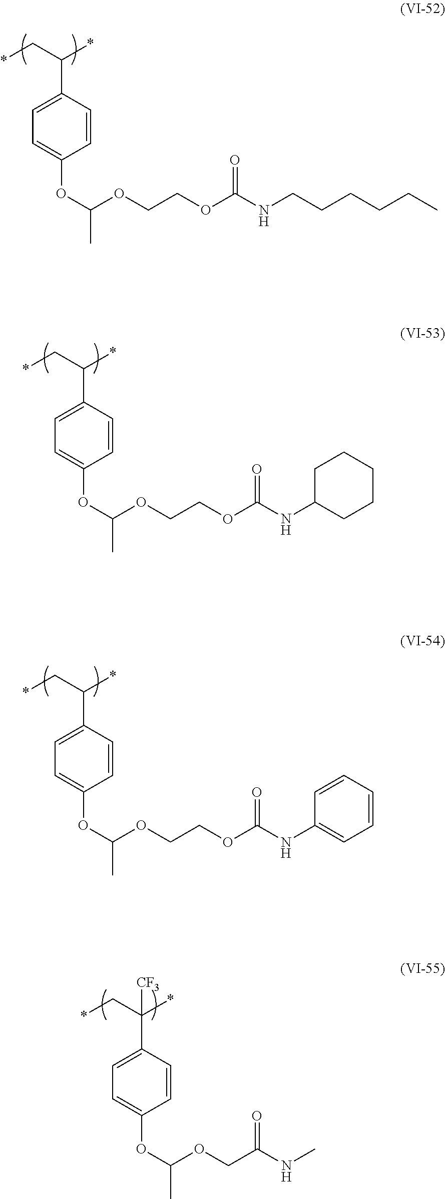

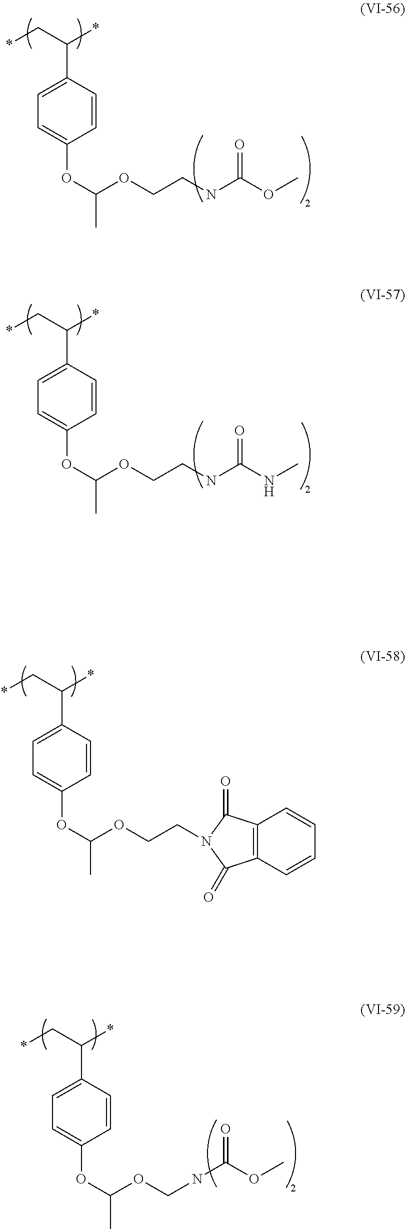

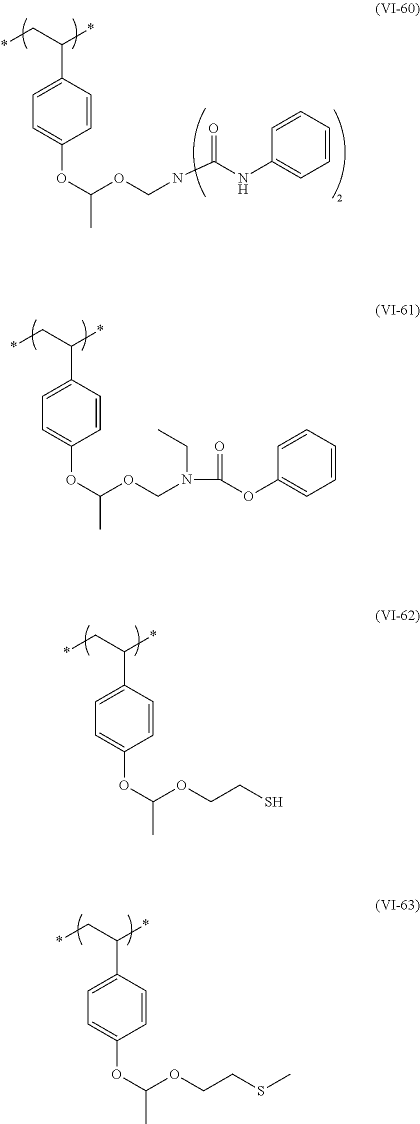

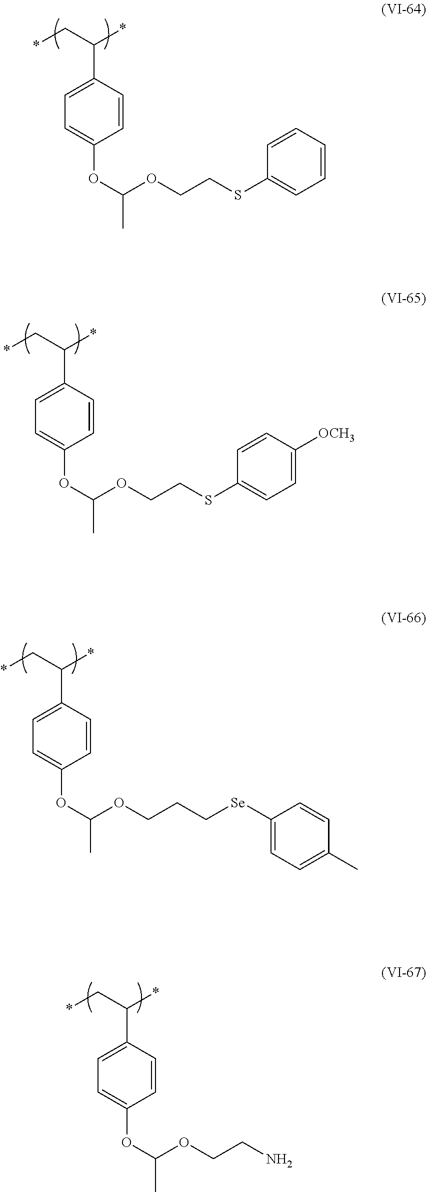

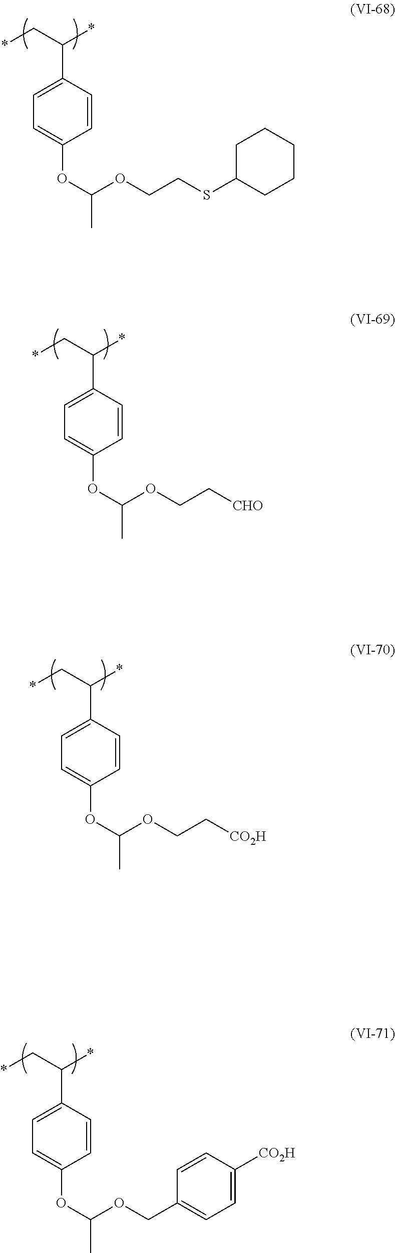

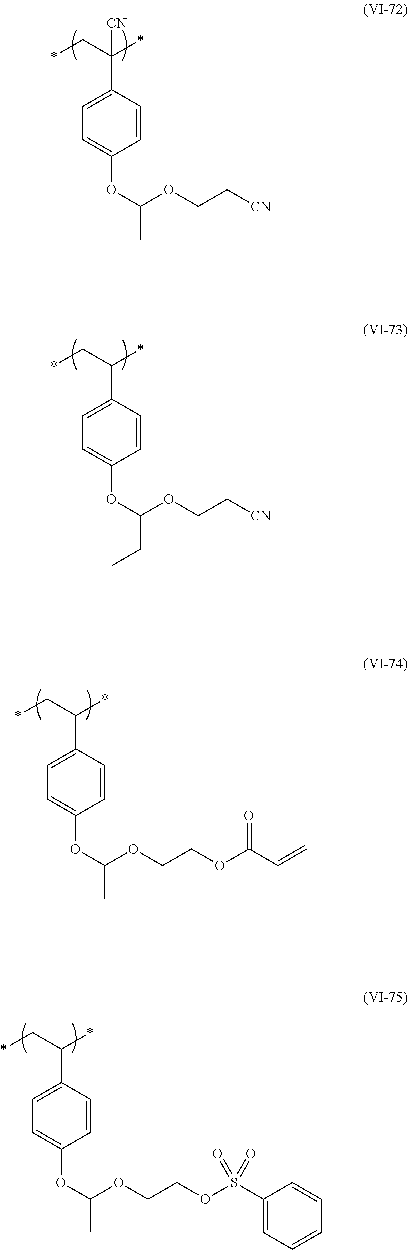

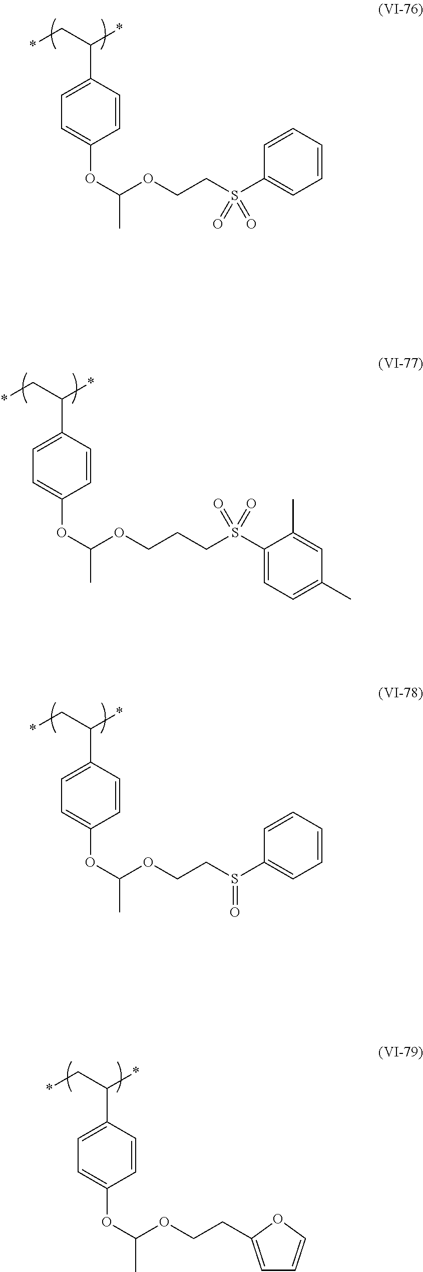

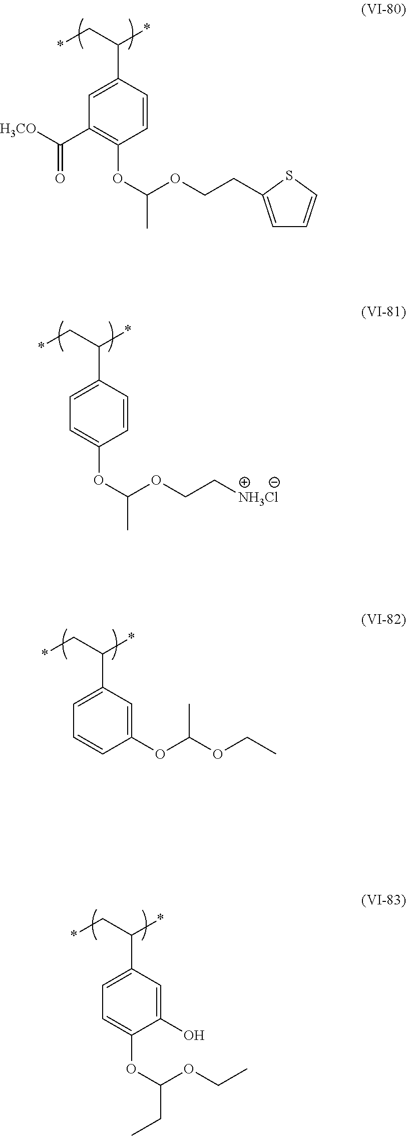

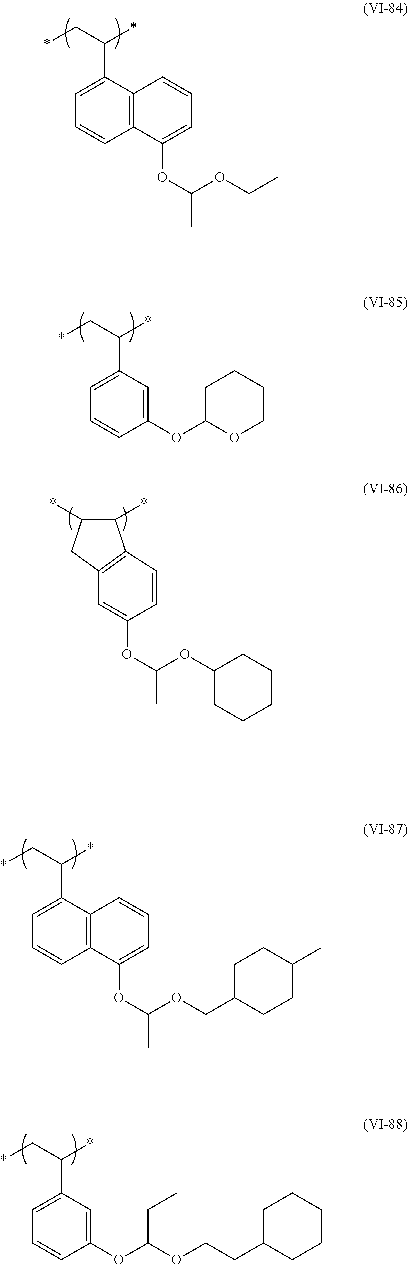

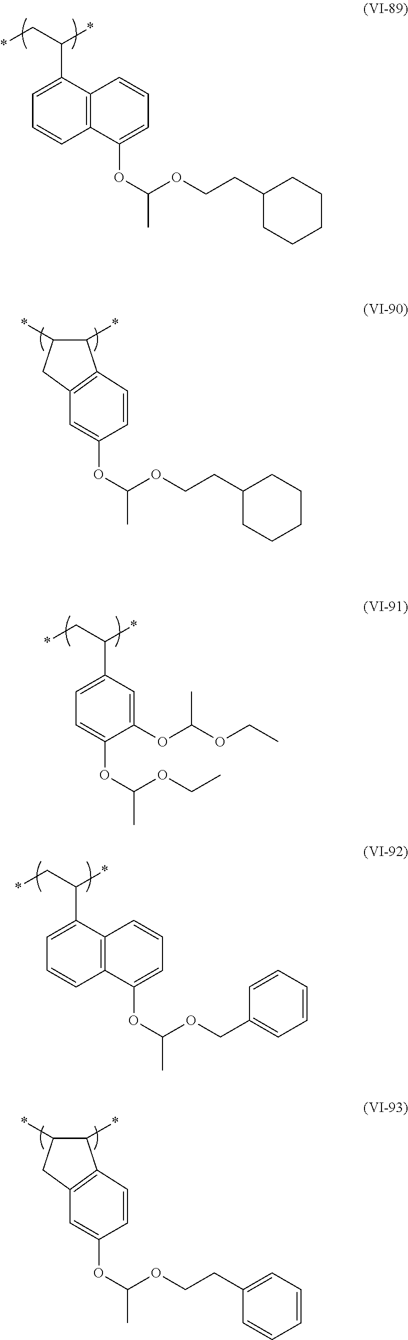

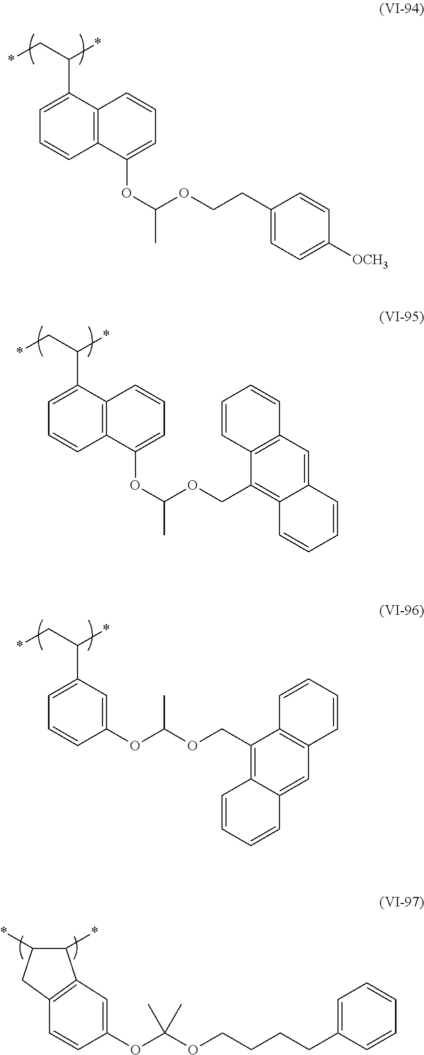

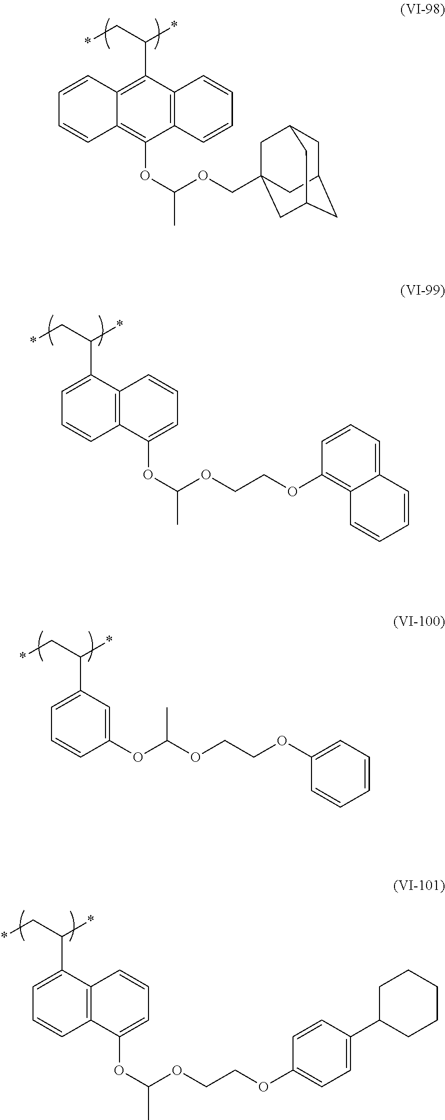

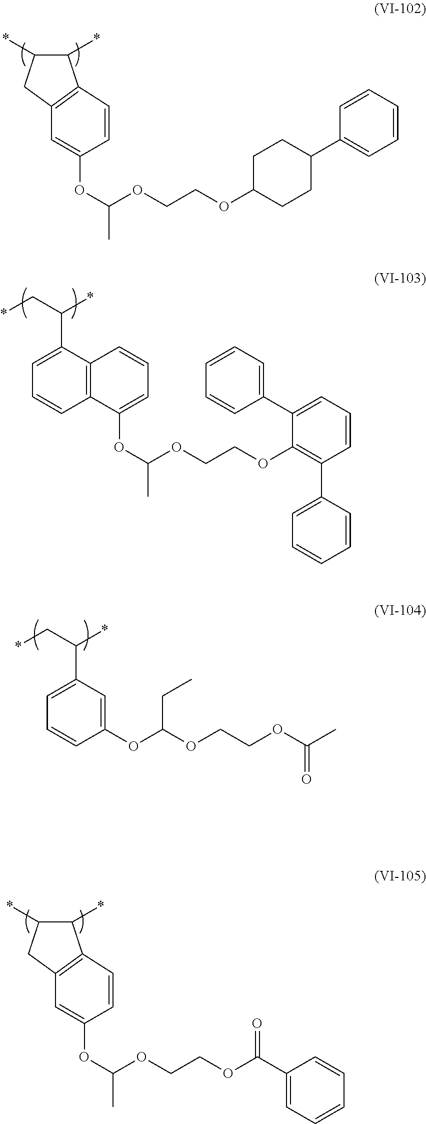

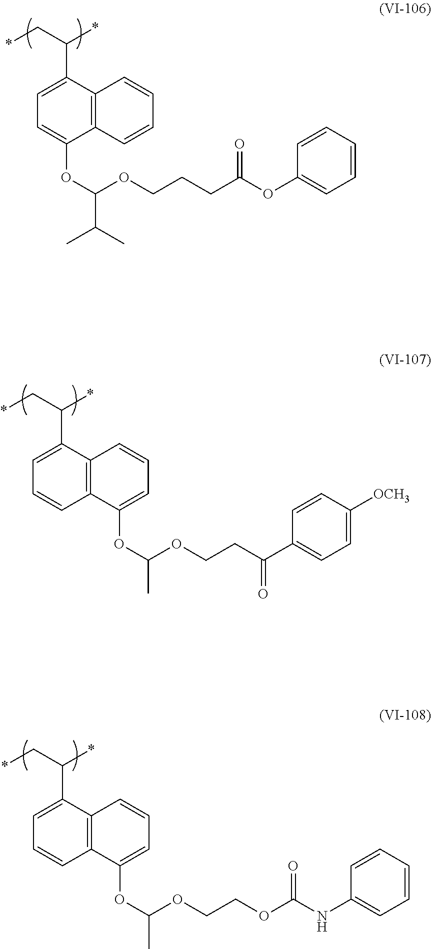

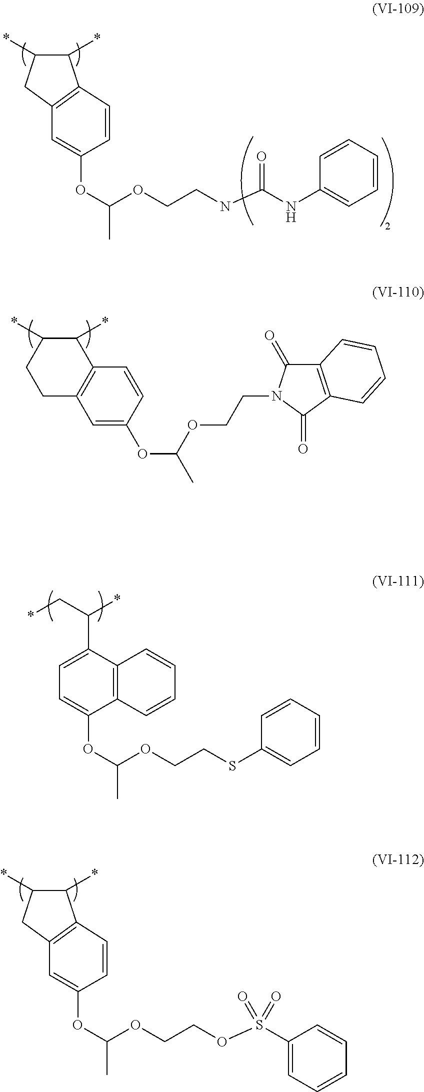

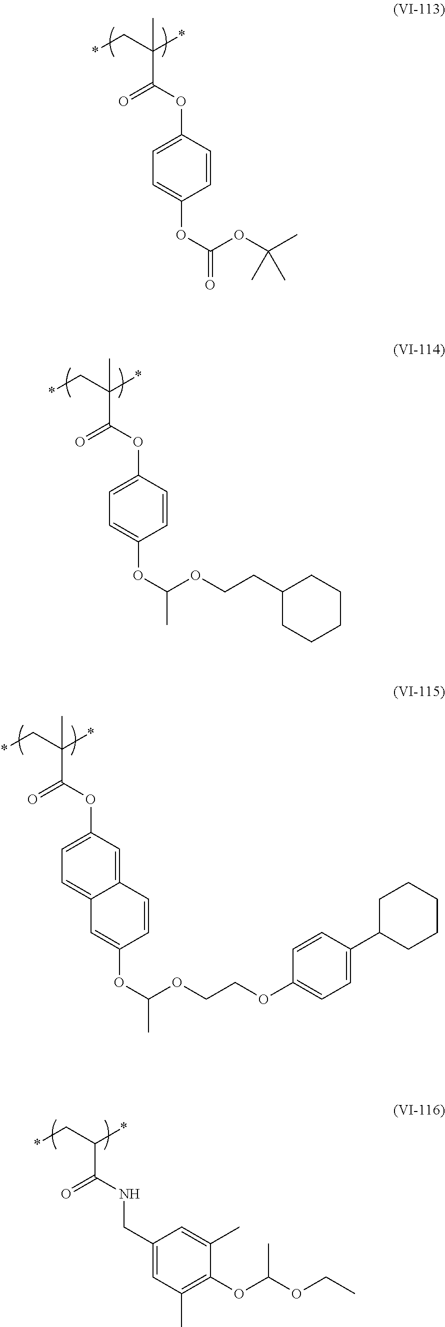

Furthermore, the resin (P) may contain any of the repeating units of general formula (BZ) below as the repeating unit (A). This is especially preferred when the exposure is performed using electron beams or EUV light.

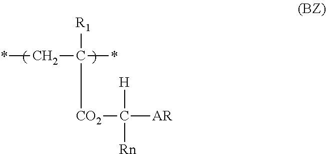

In general formula (BZ), AR represents an aryl group. Rn represents an alkyl group, a cycloalkyl group or an aryl group. Rn and AR may be bonded to each other to thereby form a nonaromatic ring.

R₁ represents a hydrogen atom, an alkyl group, a cycloalkyl group, a halogen atom, a cyano group or an alkyloxycarbonyl group.

The aryl group represented by AR is preferably one having 6 to 20 carbon atoms, such as a phenyl group, a naphthyl group, an anthryl group or a fluorene group. An aryl group having 6 to 15 carbon atoms is more preferred.

When AR is a naphthyl group, an anthryl group or a fluorene group, the position of bonding of AR to the carbon atom to which Rn is bonded is not particularly limited. For example, when AR is a naphthyl group, the carbon atom may be bonded to whichever position, α-position or β-position, of the naphthyl group. When AR is an anthryl group, the carbon atom may be bonded to any of the 1-position, 2-position and 9-position of the anthryl group.

One or more substituents may be introduced in each of the aryl groups represented by AR. As particular examples of such substituents, there can be mentioned a linear or branched alkyl group having 1 to 20 carbon atoms, such as a methyl group, an ethyl group, a propyl group, an isopropyl group, an n-butyl group, an isobutyl group, a t-butyl group, a pentyl group, a hexyl group, an octyl group or a dodecyl group; an alkoxy group containing any of these alkyl groups as its part; a cycloalkyl group, such as a cyclopentyl group or a cyclohexyl group; a cycloalkoxy group containing such a cycloalkyl group as its part; a hydroxyl group; a halogen atom; an aryl group; a cyano group; a nitro group; an acyl group; an acyloxy group; an acylamino group; a sulfonylamino group; an alkylthio group; an arylthio group; an aralkylthio group; a thiophenecarbonyloxy group; a thiophenemethylcarbonyloxy group; and a heterocyclic residue, such as a pyrrolidone residue. Among these substituents, a linear or branched alkyl group having 1 to 5 carbon atoms and an alkoxy group containing the alkyl group as its part are preferred. A paramethyl group and a paramethoxy group are more preferred.

When a plurality of substituents are introduced in the aryl group represented by AR, at least two members of the plurality of substituents may be bonded to each other to thereby form a ring. The ring is preferably a 5- to 8-membered one, more preferably a 5- or 6-membered one. Further, this ring may be a heteroring containing a heteroatom, such as an oxygen atom, a nitrogen atom or a sulfur atom, as a ring member.

A substituent may further be introduced in this ring. The substituent is the same as the further substituent mentioned below as being introducible in Rn.

From the viewpoint of roughness performance, it is preferred for each of the repeating units (A) of general formula (BZ) to contain two or more aromatic rings. Generally, the number of aromatic rings introduced in the repeating unit (A) is preferably up to 5, more preferably up to 3.

Also, from the viewpoint of roughness performance, it is preferred for AR of each of the repeating units (A) of general formula (BZ) to contain two or more aromatic rings. More preferably, AR is a naphthyl group or a biphenyl group. Generally, the number of aromatic rings introduced in AR is preferably up to 5, more preferably up to 3.

As mentioned above, Rn represents an alkyl group, a cycloalkyl group or an aryl group.

The alkyl group represented by Rn may be in the form of a linear or branched chain. As a preferred alkyl group, there can be mentioned an alkyl group having 1 to 20 carbon atoms, such as a methyl group, an ethyl group, a propyl group, an isopropyl group, an n-butyl group, an isobutyl group, a t-butyl group, a pentyl group, a hexyl group, an octyl group or a dodecyl group. The alkyl group represented by Rn more preferably has 1 to 5 carbon atoms, further more preferably 1 to 3 carbon atoms.

As the cycloalkyl group represented by Rn, there can be mentioned, for example, one having 3 to 15 carbon atoms, such as a cyclopentyl group or a cyclohexyl group.

The aryl group represented by Rn is preferably, for example, one having 6 to 14 carbon atoms, such as a phenyl group, a xylyl group, a tolyl group, a cumenyl group, a naphthyl group or an anthryl group.

Substituents may further be introduced in the alkyl group, cycloalkyl group and aryl group represented by Rn. As such substituents, there can be mentioned, for example, an alkoxy group, a hydroxyl group, a halogen atom, a nitro group, an acyl group, an acyloxy group, an acylamino group, a sulfonylamino group, a dialkylamino group, an alkylthio group, an arylthio group, an aralkylthio group, a thiophenecarbonyloxy group, a thiophenemethylcarbonyloxy group, and a heterocyclic residue, such as a pyrrolidone residue. Among these substituents, an alkoxy group, a hydroxyl group, a halogen atom, a nitro group, an acyl group, an acyloxy group, an acylamino group and a sulfonylamino group are especially preferred.

As mentioned above, R₁ represents a hydrogen atom, an alkyl group, a cycloalkyl group, a halogen atom, a cyano group or an alkyloxycarbonyl group.

The alkyl group and cycloalkyl group represented by R₁ are, for example, the same as mentioned above in connection with Rn. Substituents may be introduced in the alkyl group and cycloalkyl group. The substituents are, for example, the same as set forth above in connection with Rn.

When R₁ is a substituted alkyl group or cycloalkyl group, it is especially preferred for R₁ to be, for example, a trifluoromethyl group, an alkyloxycarbonylmethyl group, an alkylcarbonyloxymethyl group, a hydroxymethyl group or an alkoxymethyl group.

As the halogen atom represented by R₁, there can be mentioned a fluorine atom, a chlorine atom, a bromine atom or an iodine atom. A fluorine atom is most preferred.

As the part of alkyl group contained in the alkyloxycarbonyl group represented by R₁, there can be employed, for example, any of the structures mentioned above as the alkyl group represented by R₁.

Preferably, Rn and AR are bonded to each other to thereby form a nonaromatic ring. In particular, this can enhance the roughness performance.

The nonaromatic ring that may be formed by the mutual bonding of Rn and AR is preferably a 5- to 8-membered ring, more preferably a 5- or 6-membered ring.

The nonaromatic ring may be an aliphatic ring or a heteroring containing a heteroatom, such as an oxygen atom, a nitrogen atom or a sulfur atom, as a ring member.

A substituent may be introduced in the nonaromatic ring. The substituent is, for example, the same as the further substituent mentioned above as being introducible in Rn.

Non-limiting specific examples of the repeating units (A) of general formula (BZ) are shown below.

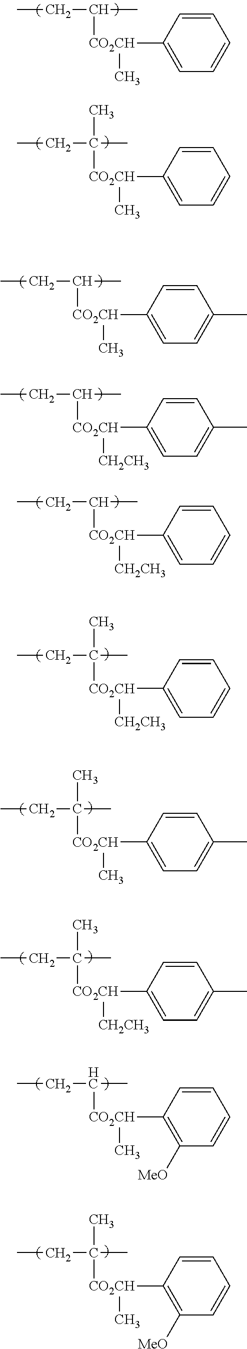

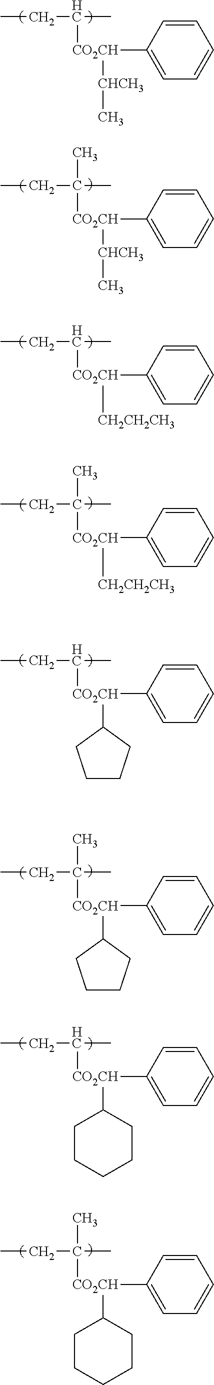

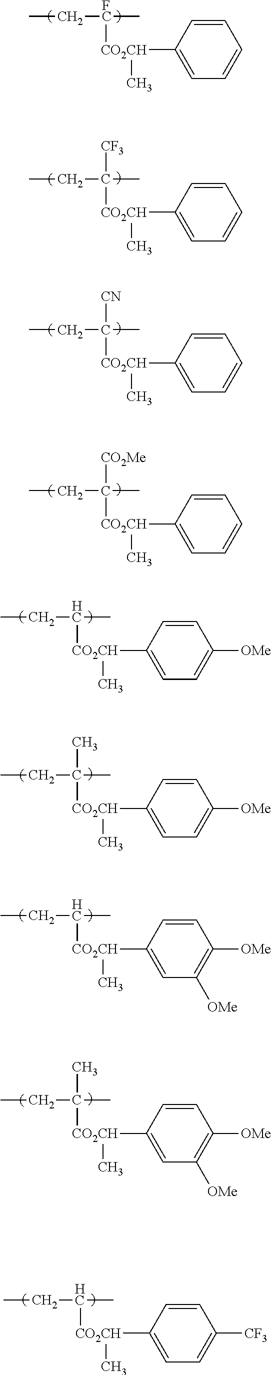

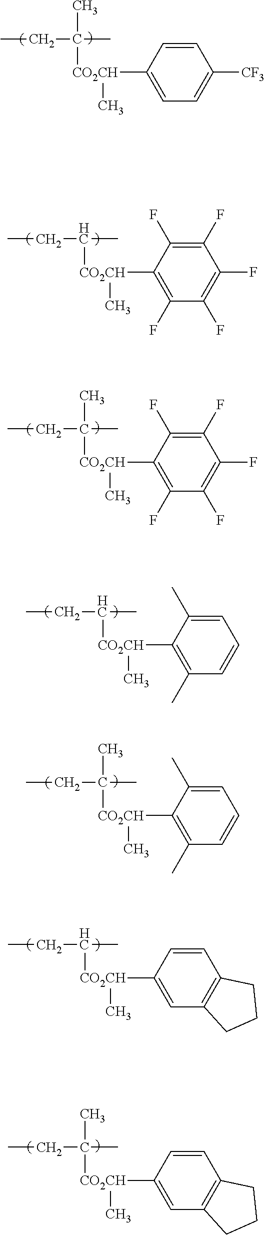

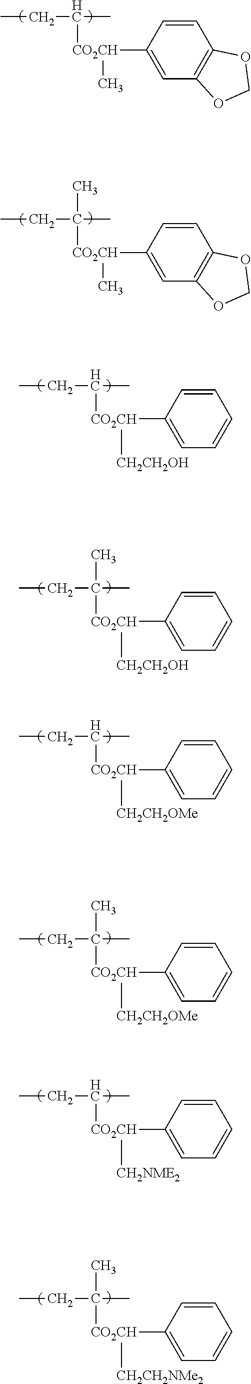

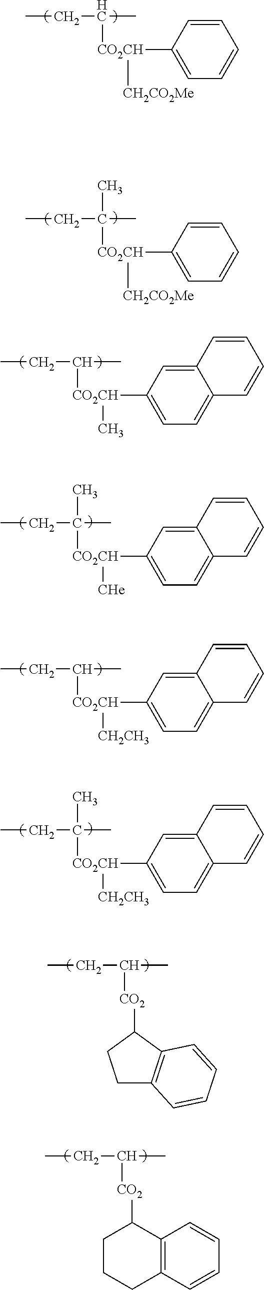

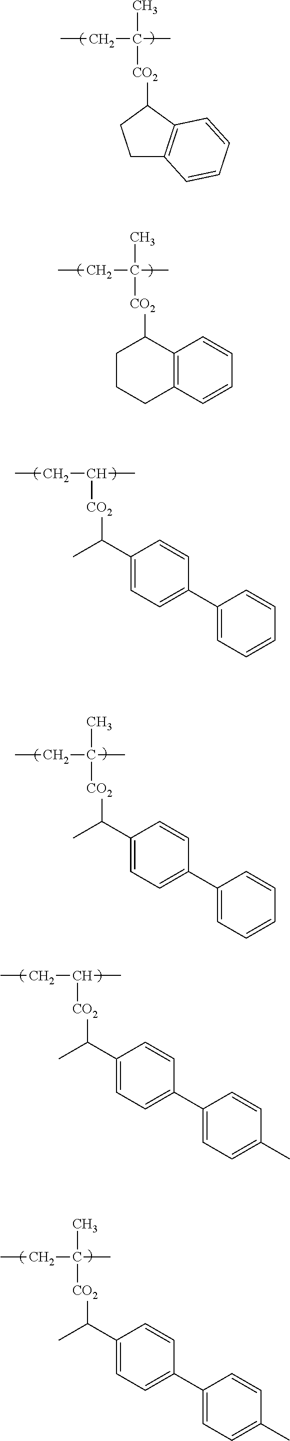

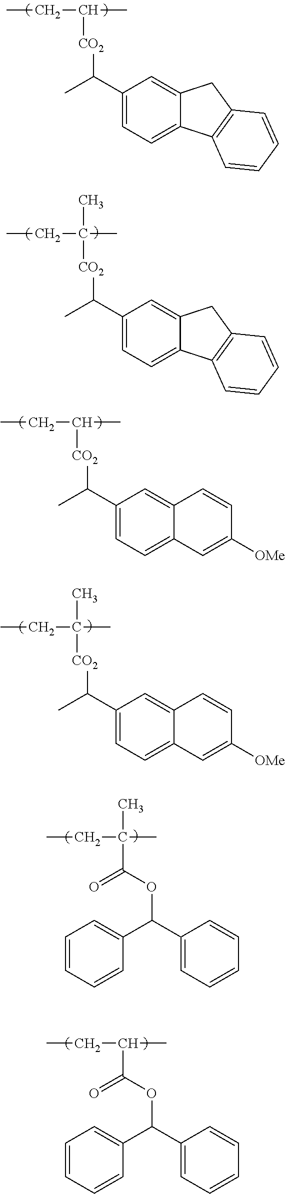

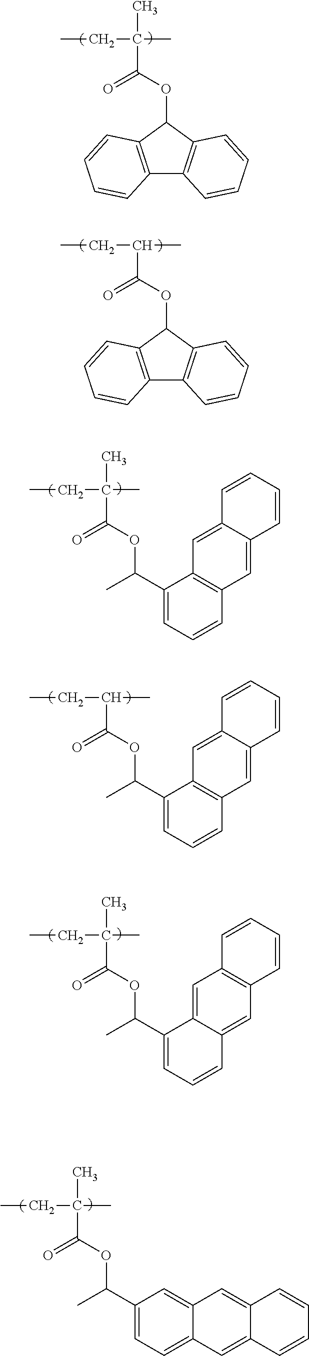

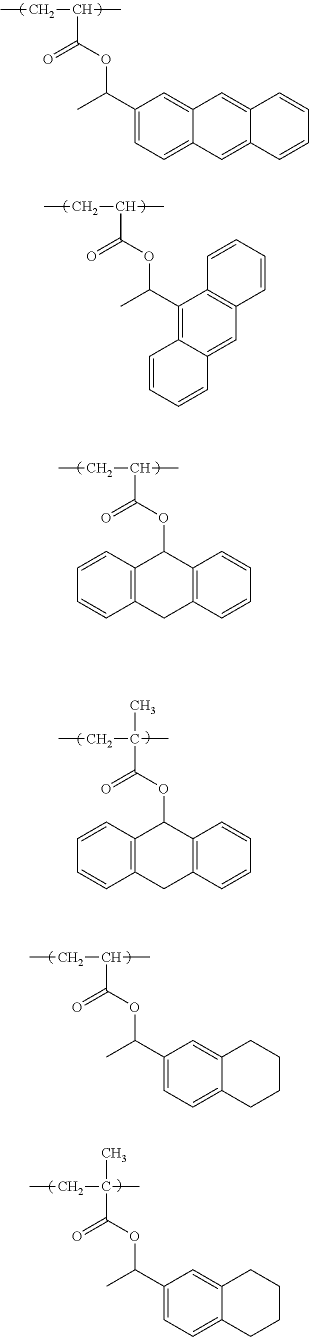

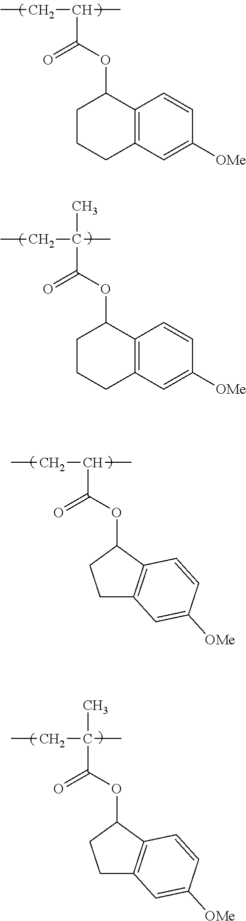

Two or more types of acid-decomposable repeating units (A) may be contained in the resin (P).

The content of repeating unit (A) in the resin (P), based on all the repeating units of the resin, is preferably in the range of 3 to 90 mol %, more preferably 5 to 80 mol % and most preferably 7 to 70 mol %.

[Repeating Unit (B)]

The resin (P) according to the present invention may further contain a repeating unit (B) containing an alkali-soluble group. The alkali-soluble group is preferably one comprising an aromatic ring group.

The repeating unit (B) preferably has the structure of general formula (I) below.

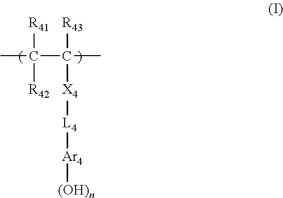

In the formula,

each of R₄₁, R₄₂ and R₄₃ independently represents a hydrogen atom, an alkyl group, a halogen atom, a cyano group or an alkoxycarbonyl group.

X₄ represents a single bond, —COO— or —CONR₆₄— in which R₆₄ represents a hydrogen atom or an alkyl group.

L₄ represents a single bond or an alkylene group.

Ar₄ represents a (n+1)-valent aromatic ring group, and

n is an integer of 1 to 4.

Particular examples of the alkyl groups, cycloalkyl groups, halogen atoms and alkoxycarbonyl groups represented by R₄₁, R₄₂ and R₄₃ in formula (I) and substituents introducible therein are the same as set forth above in connection with general formula (V).

A substituent may be introduced in the aromatic ring group represented by Ar₄. As preferred examples of the aromatic ring groups, there can be mentioned an arylene group having 6 to 18 carbon atoms, such as a phenylene group, a tolylene group, a naphthylene group or an anthracenylene group, and an aromatic ring group containing a heteroring, such as thiophene, furan, pyrrole, benzothiophene, benzofuran, benzopyrrole, triazine, imidazole, benzimidazole, triazole, thiadiazole or thiazole.

Preferred substituents that can be introduced in these groups include an alkyl group, an alkoxy group such as a methoxy group, an ethoxy group, a hydroxyethoxy group, a propoxy group, a hydroxypropoxy group or a butoxy group and an aryl group such as a phenyl group, as mentioned above in connection with R₅₁ to R₅₃ of general formula (V).

The alkyl group represented by R₆₄ of the —CONR₆₄—(R₆₄ represents a hydrogen atom or an alkyl group) represented by X₄ is the same as set forth above as the alkyl group represented by each of R₆₁ to R₆₃.

X₄ is preferably a single bond, —COO— or —CONH—, more preferably a single bond or —COO—.

The alkylene group represented by L₄ is preferably an optionally substituted alkylene group having 1 to 8 carbon atoms, such as a methylene group, an ethylene group, a propylene group, a butylene group, a hexylene group or an octylene group.

Ar₄ is more preferably an optionally substituted arylene group having 6 to 18 carbon atoms. A phenylene group, a naphthylene group and a biphenylene group are most preferred.

It is preferred for the repeating unit (B) to contain a hydroxystyrene structure. Namely, it is preferred for Ar₄ to be a phenylene group.

Particular examples of the repeating units (B) of general formula (1) are shown below, which in no way limit the scope of the present invention. In the following formulae, a is an integer of 0 to 2.

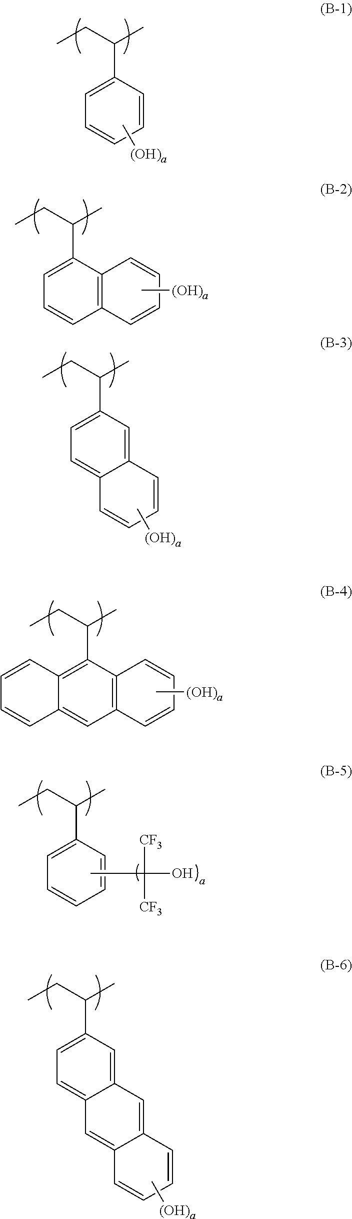

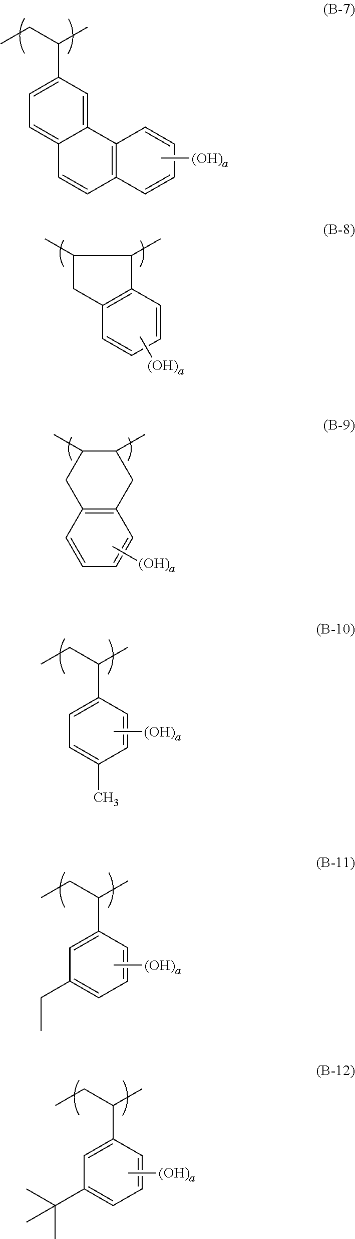

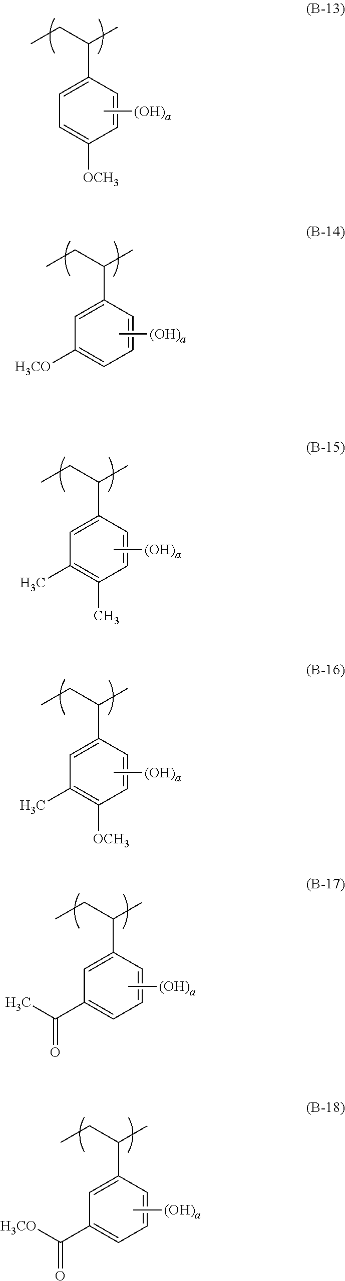

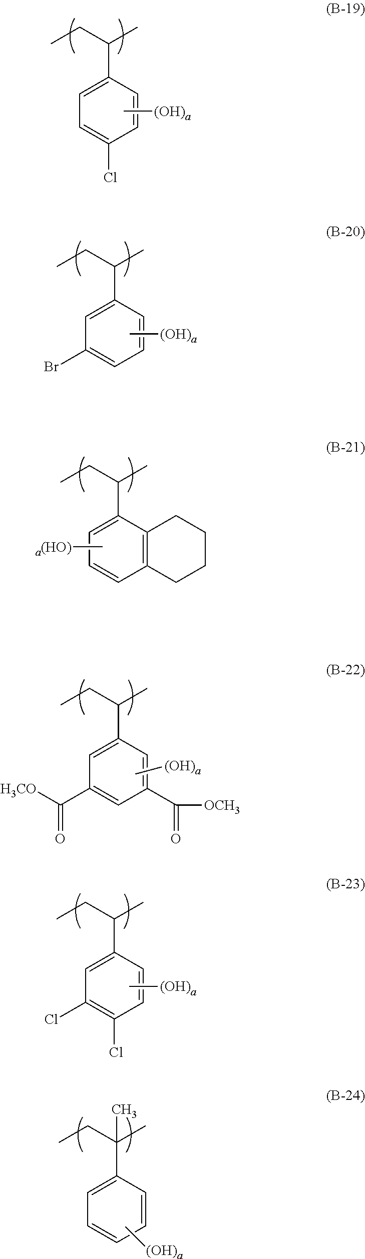

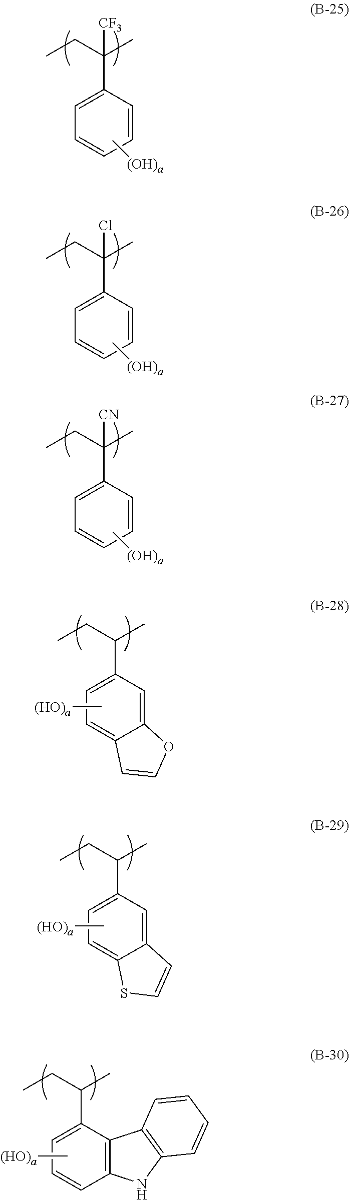

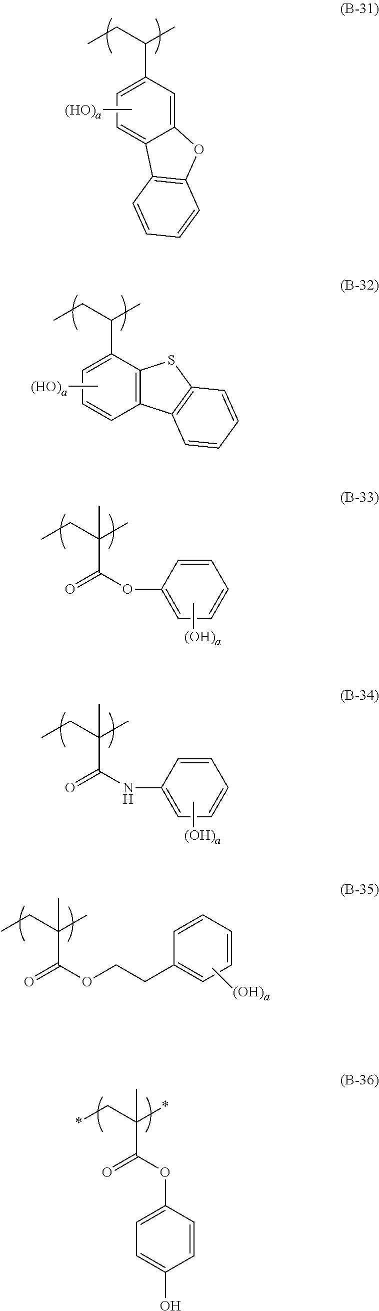

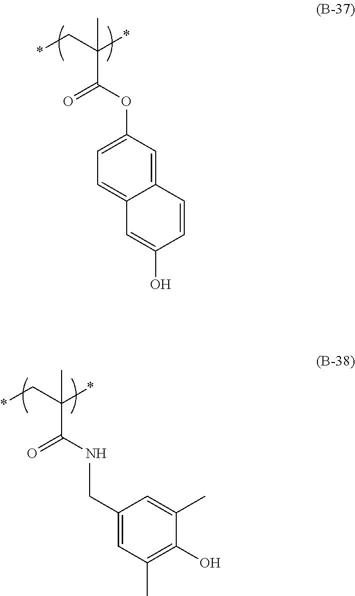

The resin (P) may comprise two or more types of repeating units (B).

The content of repeating unit (B) containing an alkali-soluble group, expressed by general formula (1) is preferably in the range of 5 to 90 mol %, more preferably 10 to 80 mol % and further more preferably 20 to 70 mol %, based on all the repeating units of the resin (P).

[Repeating Unit (C)]

The resin (P) may further comprise a repeating unit (C) containing a group that when acted on by an alkali developer, is decomposed to thereby increase its rate of dissolution in the alkali developer. As the group that when acted on by an alkali developer, is decomposed to thereby increase its rate of dissolution in the alkali developer, there can be mentioned a lactone structure, a phenyl ester structure or the like. The repeating units of general formula (AII) below are preferred.

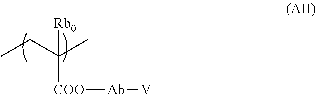

In general formula (AII), V represents a group that is decomposed by the action of an alkali developer to thereby increase its rate of dissolution into the alkali developer. Ab represents a single bond, an alkylene group, a bivalent connecting group with a monocyclic or polycyclic aliphatic hydrocarbon ring structure, an ether group, an ester group, a carbonyl group, or a bivalent connecting group resulting from combination of these. Rb₀ represents a hydrogen atom, a halogen atom or an alkyl group.

As preferred alkyl group represented by Rb₀, there can be mentioned an alkyl group having 1 to 4 carbon atoms. The alkyl group may have a substituent. As preferred examples thereof, there can be mentioned a hydroxyl group and a halogen atom. As the halogen atom represented by Rb₀, there can be mentioned a fluorine atom, a chlorine atom, a bromine atom or an iodine atom. Rb₀ is preferably a hydrogen atom, a methyl group, a hydroxymethyl group or a trifluoromethyl group. A hydrogen atom and a methyl group are especially preferred.

Ab is preferably a single bond or any of the bivalent connecting groups of the formula -Ab₁-CO₂— in which Ab₁ represents an alkylene group or a cycloalkylene group, preferably a methylene group, an ethylene group, a cyclohexylene group, an adamantylene group or a norbornylene group.

V represents a group that is decomposed by the action of an alkali developer to thereby increase its rate of dissolution into the alkali developer. V is preferably a group with an ester bond. In particular, a group with a lactone structure is more preferred.

The group with a lactone structure is not limited as long as a lactone structure is introduced therein. A 5 to 7-membered ring lactone structure is preferred, and one resulting from the condensation of a 5 to 7-membered ring lactone structure with another cyclic structure effected in a fashion to form a bicyclo structure or spiro structure is especially preferred. More preferably, V is a group with any of the lactone structures of general formulae (LC1-1) to (LC1-17) below. The lactone structures may be directly bonded to the principal chain. Preferred lactone structures are those of formulae (LC1-1), (LC1-4), (LC1-5), (LC1-6), (LC1-13) and (LC1-14).

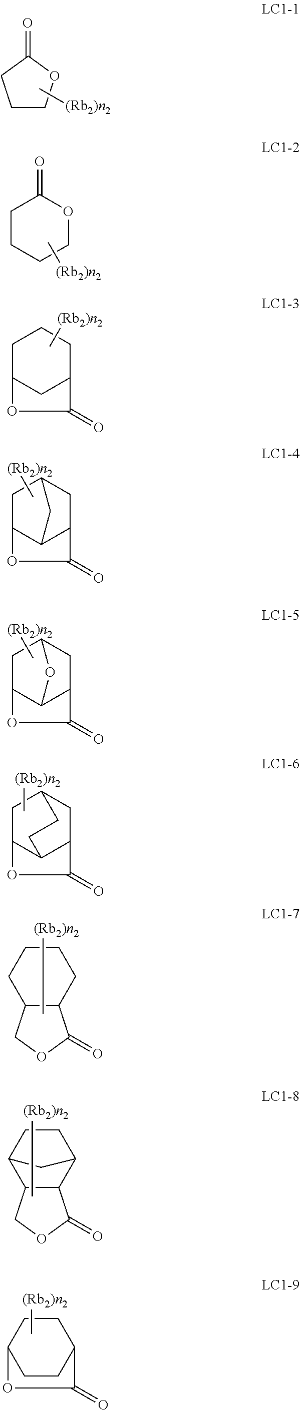

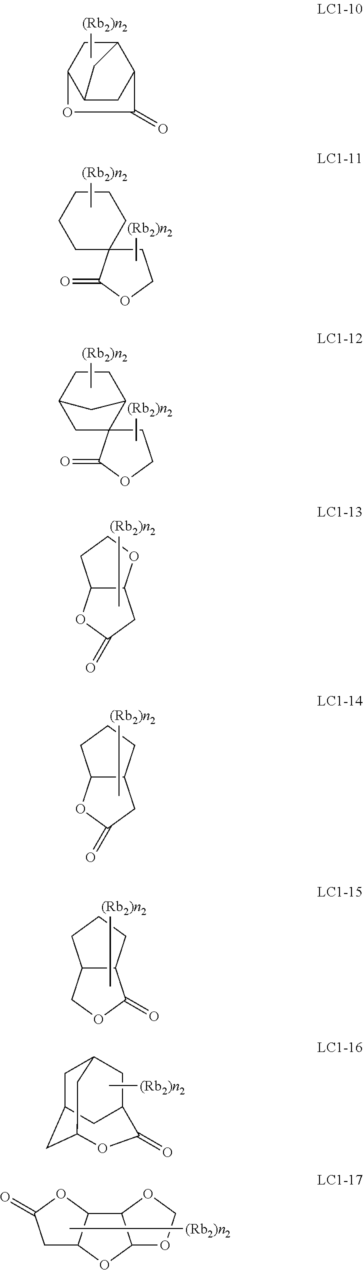

The presence of a substituent (Rb₂) on the portion of the lactone structure is optional. As preferred substituents (Rb₂), there can be mentioned an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, an acid-decomposable group and the like. An alkyl group having 1 to 4 carbon atoms, a cyano group and an acid-decomposable group are more preferred. In the formulae, n₂ is an integer of 0 to 4. When n₂ is 2 or greater, the plurality of introduced substituents (Rb₂) may be identical to or different from each other. Further, the plurality of introduced substituents (Rb₂) may be bonded to each other to thereby form a ring.

The repeating unit containing a lactone group is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity (ee) thereof is preferably 90% or higher, more preferably 95% or higher.

When repeating unit (C) is contained in the resin (P), the content thereof in the resin (F), based on all the repeating units of the resin, is preferably in the range of 0.5 to 80 mol %, more preferably 1 to 60 mol % and further more preferably 2 to 40 mol %. A single type of repeating unit (C) may be used alone, or two or more types may be used in combination. Line edge roughness and development defect performance can be enhanced by employing specified lactone structures.

Particular examples of the repeating units (C) are shown below. In the following formulae, Rx represents H, CH₃, CH₂OH or CF₃.

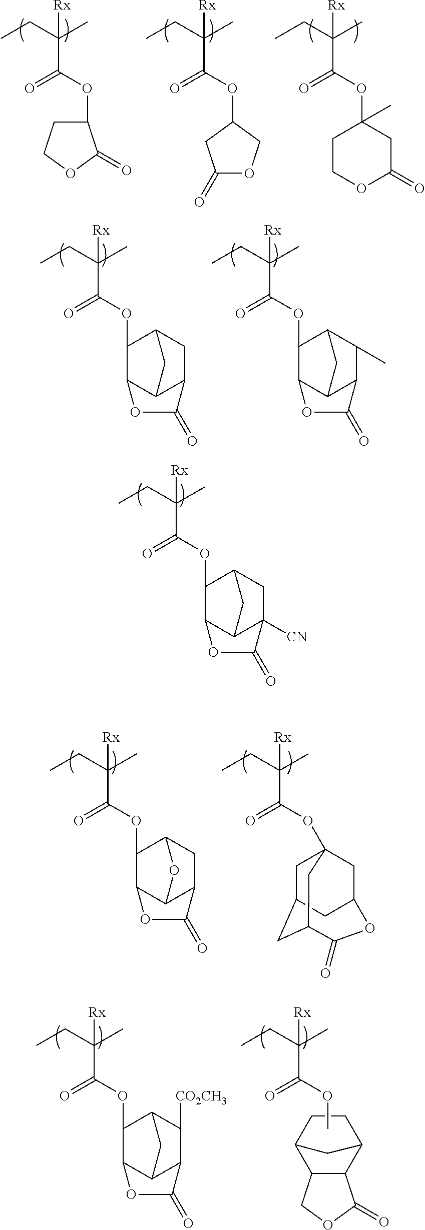

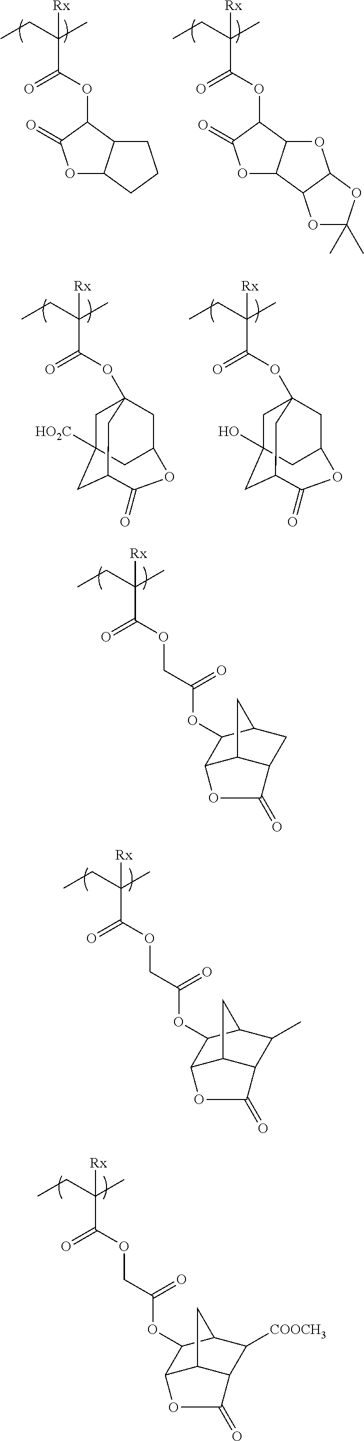

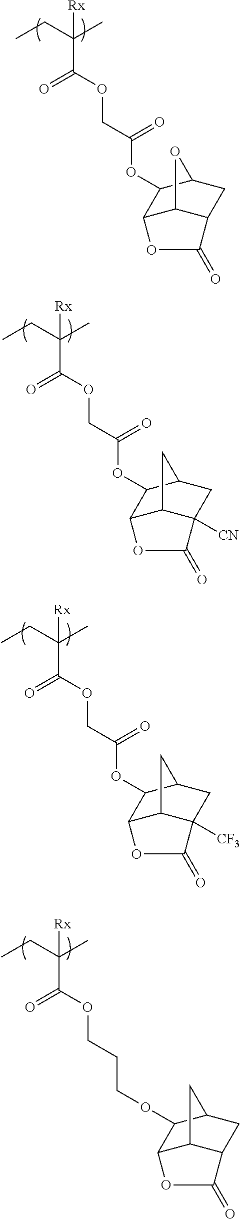

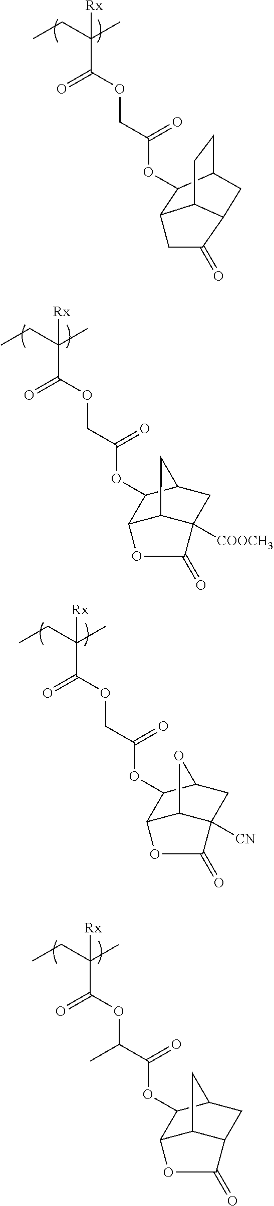

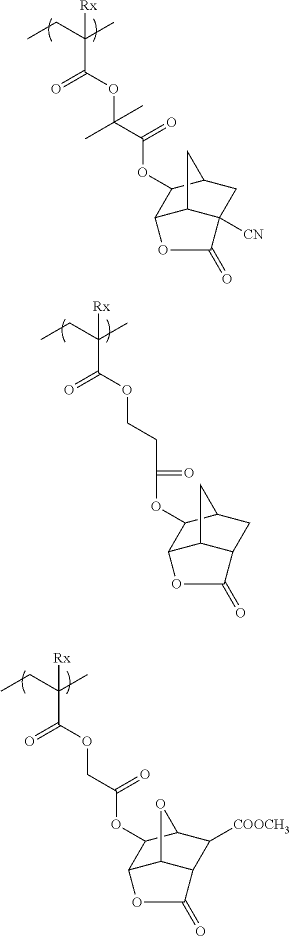

[Other Repeating Unit]

As a repeating unit other than the repeating units mentioned hereinbefore that may be introduced in the resin (P), there can be mentioned a repeating unit containing an alicyclic hydrocarbon in which a hydroxyl group or a cyano group is introduced, or a repeating unit containing an alicyclic hydrocarbon in which no polar group is introduced. It is preferred for such a repeating unit to contain substantially no acid-decomposable group.

In particular, the adherence to substrate and the developer affinity can be enhanced by the further introduction of the repeating unit containing an alicyclic hydrocarbon in which a hydroxyl group or a cyano group is introduced. The alicyclic hydrocarbon is preferably an adamantyl group, a diamantyl group or a norbornane group. As this repeating unit, there can be mentioned any of those of general formulae (AIIa) to (AIId) below.

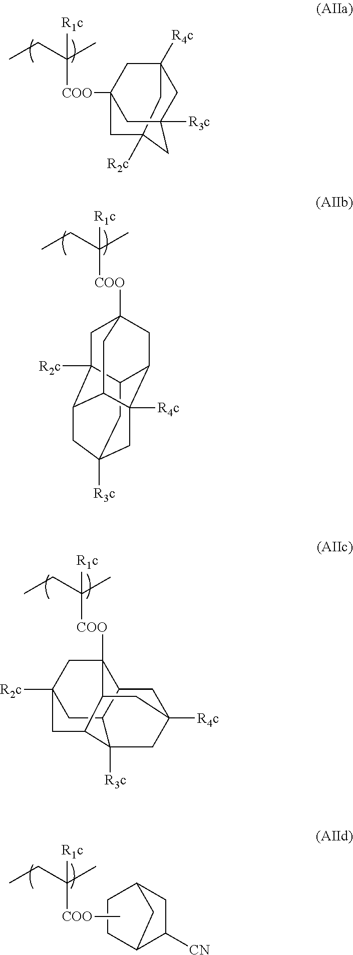

In general formulae (AIIa) to (AIId), at least one of R₂c to R₄c represents a hydroxyl group or a cyano group, and the remainder is a hydrogen atom. Preferably, one or two of R₂c to R₄c are hydroxyl groups, and the remainder is a hydrogen atom. Further more preferably, two of R₂c to R₄c are hydroxyl groups, and the remainder is a hydrogen atom. R₁c represents a hydrogen atom, a methyl group, a trifluoromethyl group or a hydroxymethyl group.

Specific examples of the repeating units each containing a hydroxyl group or a cyano group are shown below.

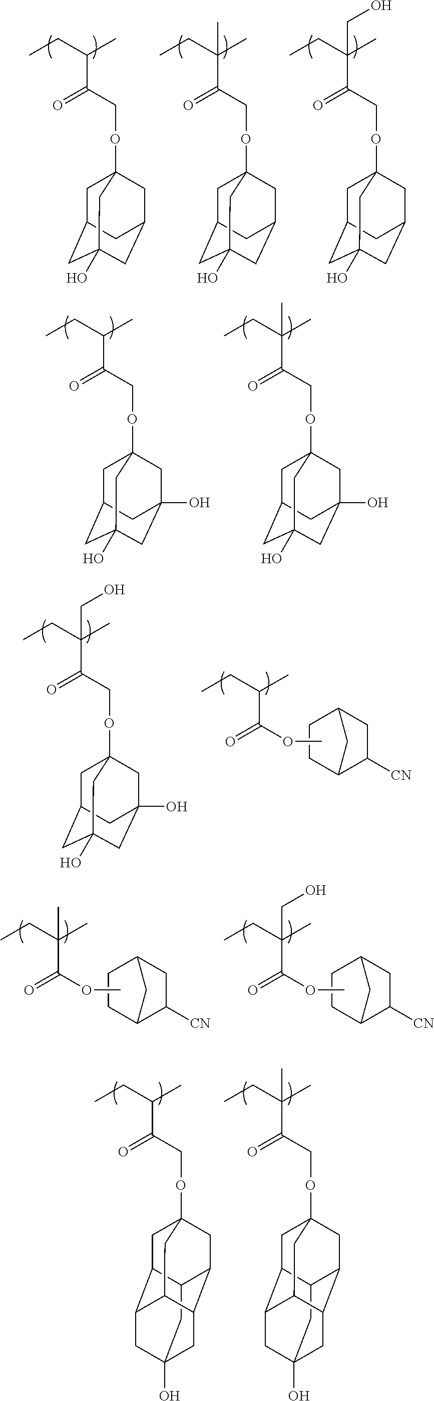

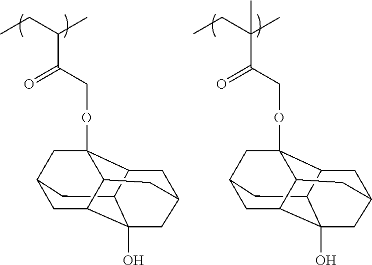

As the repeating unit having an alicyclic hydrocarbon structure in which no polar group is introduced, there can be mentioned, for example, any of the repeating units of general formula (VII) below.

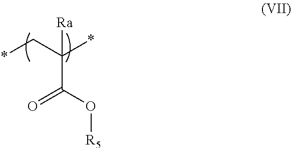

In general formula (VII), R₅ represents an alicyclic hydrocarbon, and Ra represents a hydrogen atom, an alkyl group, a hydroxymethyl group or a trifluoromethyl group.

Ra is preferably a hydrogen atom or an alkyl group, most preferably a hydrogen atom or a methyl group.

For example, R₅ represents a cycloalkyl group having 3 to 12 carbon atoms, such as a cyclopentyl group, a cyclohexyl group, a cycloheptyl group or a cyclooctyl group; a cycloalkenyl group having 3 to 12 carbon atoms, such as a cyclohexenyl group; a ring-assembly hydrocarbon group, such as a bicyclohexyl group or a perhydronaphthalenyl group; or any of crosslinked-ring hydrocarbon rings, such as pinane, bornane, norpinane, norbornane and bicyclooctane rings (e.g., bicyclo[2.2.2]octane ring or bicyclo[3.2.1]octane ring), homobledane, adamantane, tricyclo[5.2.1.0^{2,6}]decane and tricyclo[4.3.1.1^{2,5}]undecane rings, tetracyclo[4.4.0.1^{2,5}.1^{7,10}]dodecane and perhydro-1,4-methano-5,8-methanonaphthalene rings, and perhydronaphthalene (decalin), perhydroanthracene, perhydrophenanthrene, perhydroacenaphthene, perhydrofluorene, perhydroindene and perhydrophenalene rings. R₅ is preferably a cyclopentyl group, a cyclohexyl group, a norbornyl group, an adamantyl group, a bicyclooctanyl group or a tricyclo[5,2,1,0^{2,6}]decanyl group or the like. As more preferred crosslinked-ring hydrocarbon rings, there can be mentioned a norbornyl group and an adamantyl group.

Substituents may be introduced in these alicyclic hydrocarbon groups. As preferred substituents, there can be mentioned a halogen atom, an alkyl group, a hydroxyl group protected by a protective group, an amino group protected by a protective group and the like.

Particular examples of the repeating units each having an alicyclic hydrocarbon structure in which no polar group is introduced are shown below, which in no way limit the scope of the present invention. In the formulae, Ra represents H, CH₃, CH₂OH or CF₃.

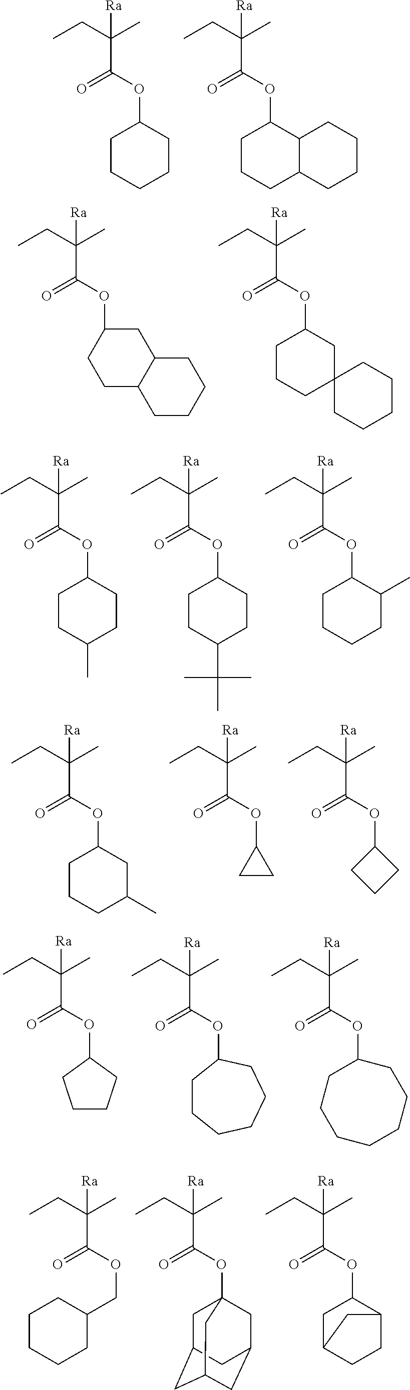

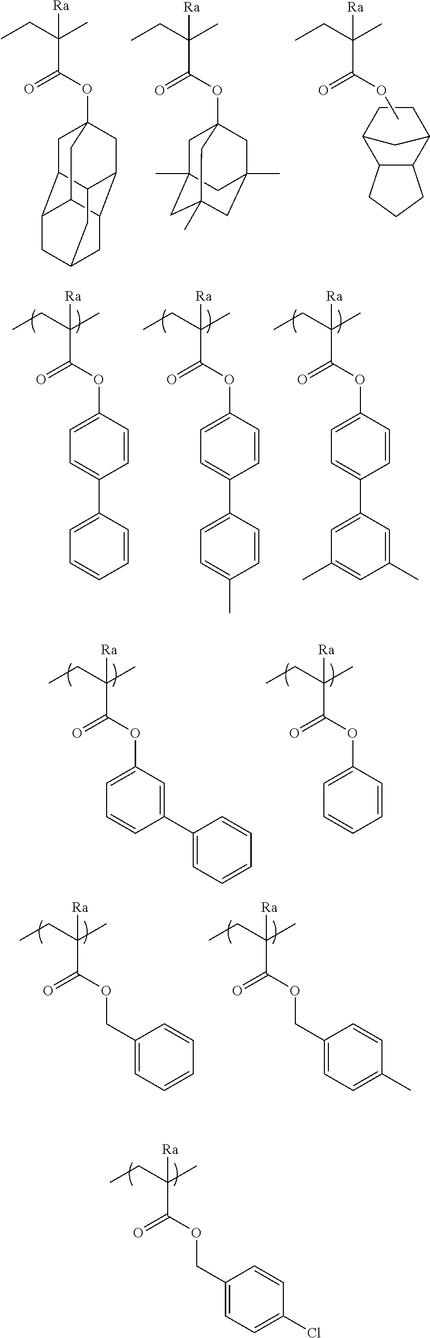

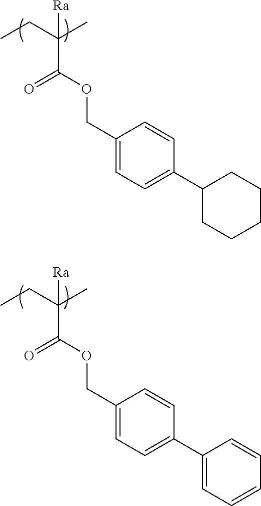

The content of repeating unit having an alicyclic hydrocarbon structure in which no polar group is introduced, based on all the repeating units of the resin (P), is preferably in the range of 1 to 40 mol %, more preferably 1 to 20 mol %.

The resin (P) according to the present invention can contain, in addition to the foregoing repeating structural units, various repeating structural units for the purpose of regulating the dry etching resistance, standard developer adaptability, substrate adhesion, resist profile and generally required properties of the resist such as resolving power, heat resistance and sensitivity.

As such repeating structural units, there can be mentioned, for example, those from a compound having an unsaturated bond capable of addition polymerization, selected from among acrylic esters, methacrylic esters, acrylamides, methacrylamides, allyl compounds, vinyl ethers, vinyl esters, styrenes, crotonic esters and the like.

The incorporation of such repeating structural units would allow fine regulation of the required properties of the resin for use in the composition of the present invention, especially (1) solubility in application solvents, (2) film forming easiness (glass transition point), (3) alkali developability, (4) film thinning (selections of hydrophilicity/hydrophobicity and alkali-soluble group), (5) adhesion of unexposed area to substrate, (6) dry etching resistance, etc.

In the resin (P) for use in the composition of the present invention, the molar ratios of individual repeating structural units contained are appropriately determined from the viewpoint of regulation of not only the dry etching resistance of the resist but also the standard developer adaptability, substrate adhesion, resist profile and generally required properties of the resist such as the resolving power, heat resistance and sensitivity.

The resin (P) according to the present invention may have any of the random, block, comb and star configurations.

The resin (P) can be synthesized by, for example, the radical, cation or anion polymerization of unsaturated monomers corresponding to given structures. Further, the intended resin can be obtained by first polymerizing unsaturated monomers corresponding to the precursors of given structures and thereafter carrying out a polymer reaction.

For example, as general synthetic methods, there can be mentioned a batch polymerization method in which an unsaturated monomer and a polymerization initiator are dissolved in a solvent and heated so as to accomplish polymerization, a dropping polymerization method in which a solution of unsaturated monomer and polymerization initiator is dropped into a heated solvent over a period of 1 to 10 hours, etc. The dropping polymerization method is preferred.

As the solvents for use in polymerization, there can be mentioned, for example, those employable in the preparation of the actinic-ray- or radiation-sensitive resin composition to be described hereinafter. It is preferred to perform the polymerization with the use of the same solvent as employed in the composition of the present invention. This inhibits any particle generation during storage.

The polymerization reaction is preferably carried out in an atmosphere of inert gas, such as nitrogen or argon. The polymerization is initiated using a commercially available radical initiator (azo initiator, peroxide, etc.) as a polymerization initiator. Among the radical initiators, an azo initiator is preferred. An azo initiator having an ester group, a cyano group or a carboxyl group is preferred. As preferred initiators, there can be mentioned azobisisobutyronitrile, azobisdimethylvaleronitrile, dimethyl 2,2′-azobis(2-methylpropionate) and the like. According to necessity, the polymerization may be carried out in the presence of a chain transfer agent (for example, an alkyl mercaptan or the like).

The concentration of the reaction system is in the range of 5 to 70 mass %, preferably 10 to 50 mass %. The reaction temperature is generally in the range of 10 to 150° C., preferably 30 to 120° C. and more preferably 40 to 100° C.

The reaction time is generally in the range of 1 to 48 hours, preferably 1 to 24 hours and more preferably 1 to 12 hours.

After the completion of the reaction, the reaction mixture is allowed to stand still to cool to room temperature and purified. In the purification, use can be made of routine methods, such as a liquid-liquid extraction method in which residual monomers and oligomer components are removed by water washing or by the use of a combination of appropriate solvents, a method of purification in solution form such as ultrafiltration capable of extraction removal of only components of a given molecular weight or below, a re-precipitation method in which a resin solution is dropped into a poor solvent to thereby coagulate the resin in the poor solvent and thus remove residual monomers, etc., and a method of purification in solid form such as washing of a resin slurry obtained by filtration with the use of a poor solvent. For example, the reaction solution is brought into contact with a solvent wherein the resin is poorly soluble or insoluble (poor solvent) amounting to 10 or less, preferably 10 to 5 times the volume of the reaction solution to thereby precipitate the resin as a solid.

The solvent for use in the operation of precipitation or re-precipitation from a polymer solution (precipitation or re-precipitation solvent) is not limited as long as the solvent is a poor solvent for the polymer. Use can be made of any solvent appropriately selected from among a hydrocarbon, a halogenated hydrocarbon, a nitro compound, an ether, a ketone, an ester, a carbonate, an alcohol, a carboxylic acid, water, a mixed solvent containing these solvents and the like, according to the type of the polymer. Of these, it is preferred to employ a solvent containing at least an alcohol (especially methanol or the like) or water as the precipitation or re-precipitation solvent.

The amount of precipitation or re-precipitation solvent used can be appropriately selected taking efficiency, yield, etc. into account. Generally, the amount is in the range of 100 to 10,000 parts by mass, preferably 200 to 2000 parts by mass and more preferably 300 to 1000 parts by mass per 100 parts by mass of polymer solution.

The temperature at which the precipitation or re-precipitation is carried out can be appropriately selected taking efficiency and operation easiness into account. Generally, the temperature is in the range of about 0 to 50° C., preferably about room temperature (for example, about 20 to 35° C.). The operation of precipitation or re-precipitation can be carried out by a routine method, such as a batch or continuous method, with the use of a customary mixing container, such as an agitation vessel.

The polymer resulting from the precipitation or re-precipitation is generally subjected to customary solid/liquid separation, such as filtration or centrifugal separation, and dried, before use. The filtration is carried out with the use of a filter medium ensuring solvent resistance, preferably under pressure. The drying is performed at about 30 to 100° C., preferably about 30 to 50° C. under ordinary pressure or reduced pressure (preferably reduced pressure).

Alternatively, after the precipitation and separation of the resin, the resultant resin may be once more dissolved in a solvent and brought into contact with a solvent in which the resin is poorly soluble or insoluble. Specifically, the method may include the steps of, after the completion of the radical polymerization reaction, bringing the polymer into contact with a solvent wherein the polymer is poorly soluble or insoluble to thereby attain resin precipitation (step a), separating the resin from the solution (step b), re-dissolving the resin in a solvent to thereby obtain a resin solution A (step c), thereafter bringing the resin solution A into contact with a solvent wherein the resin is poorly soluble or insoluble amounting to less than 10 times (preferably 5 times or less) the volume of the resin solution A to thereby precipitate a resin solid (step d) and separating the precipitated resin (step e).

The polymerization reaction is preferably carried out in an atmosphere of inert gas, such as nitrogen or argon. The polymerization is initiated using a commercially available radical initiator (azo initiator, peroxide, etc.) as a polymerization initiator. Among the radical initiators, an azo initiator is preferred. An azo initiator having an ester group, a cyano group or a carboxyl group is preferred. As preferred initiators, there can be mentioned azobisisobutyronitrile, azobisdimethylvaleronitrile, dimethyl 2,2′-azobis(2-methylpropionate) and the like. If desirable, the initiator may be supplemented, or may be added in fractional amounts. After the completion of the reaction, the reaction liquid is poured into a solvent, and the intended polymer is recovered by a method of powder or solid recovery or the like. The concentration of the reaction system is in the range of 5 to 50 mass %, preferably 10 to 30 mass %. The reaction temperature is generally in the range of 10 to 130° C., preferably 30 to 120° C. and more preferably 60 to 100° C.

The molecular weight of the resin (P) according to the present invention is not particularly limited. Preferably, the weight average molecular weight thereof is in the range of 1000 to 100,000. It is more preferably in the range of 1500 to 60,000, most preferably 2000 to 30,000. By regulating the weight average molecular weight so as to fall within the range of 1000 to 100,000, not only can any deteriorations of heat resistance and dry etching resistance be prevented but also any deterioration of developability and any increase of viscosity leading to poor film forming property can be prevented. Herein, the weight average molecular weight of the resin refers to the polystyrene-equivalent molecular weight measured by GPC (carrier: THF or N-methyl-2-pyrrolidone (NMP)).

The molecular weight dispersity (Mw/Mn) of the resin is preferably in the range of 1.00 to 5.00, more preferably 1.03 to 3.50 and further more preferably 1.05 to 2.50. The narrower the molecular weight distribution, the more favorable the resolution and resist shape and also the smoother the side wall of the resist pattern to thereby attain an excellence in roughness characteristics.

One type of rein (P) according to the present invention may be used alone, or two or more types thereof may be used in combination. The content of resin (P) is preferably in the range of 30 to 99.99 mass %, more preferably 50 to 99.97 mass % and most preferably 70 to 99.95 mass %, based on the total solids of the actinic-ray- or radiation-sensitive resin composition of the present invention.

Particular examples of the resins (P) are shown below.

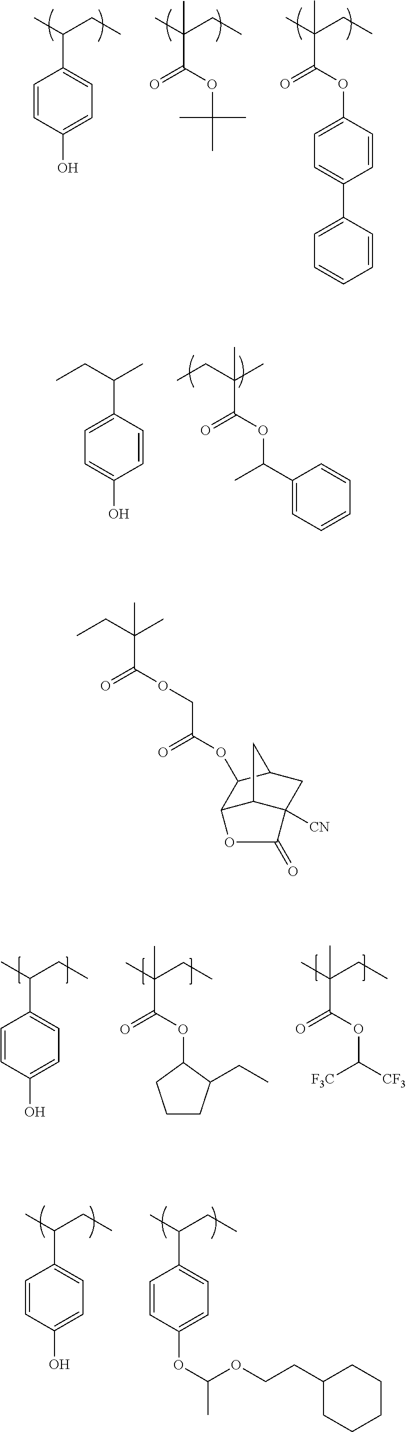

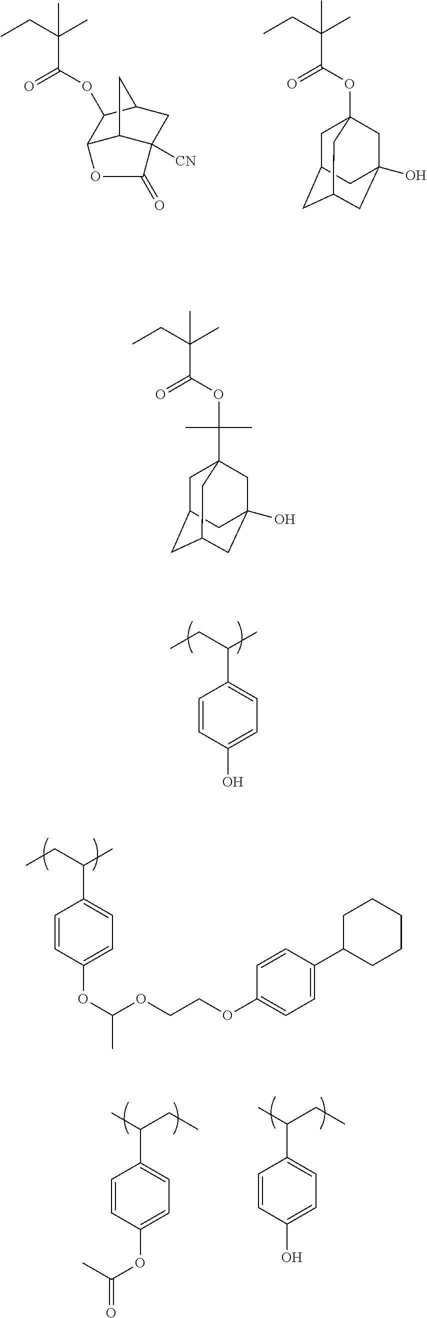

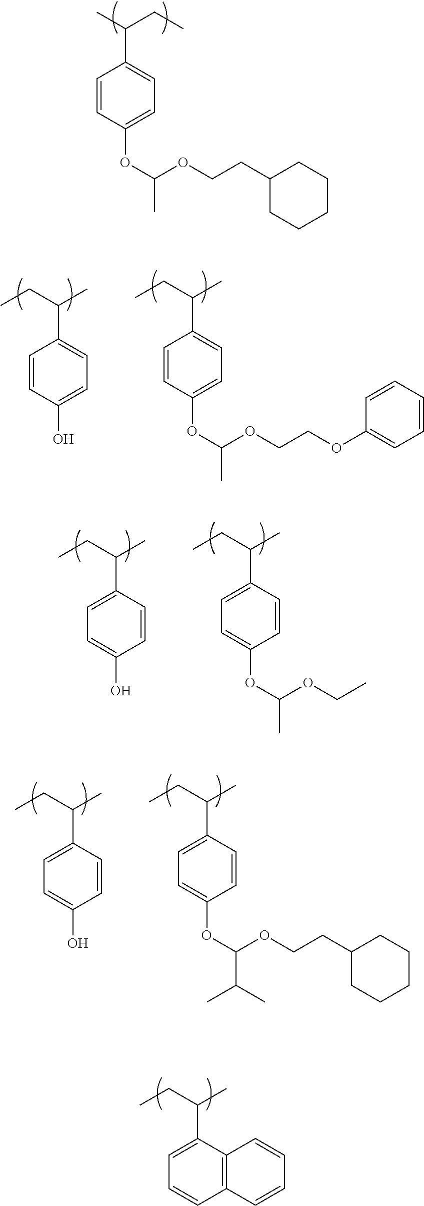

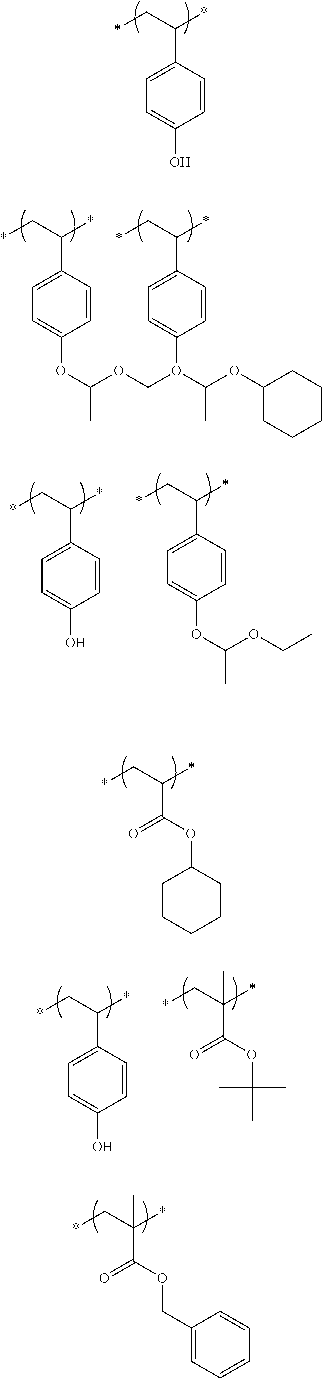

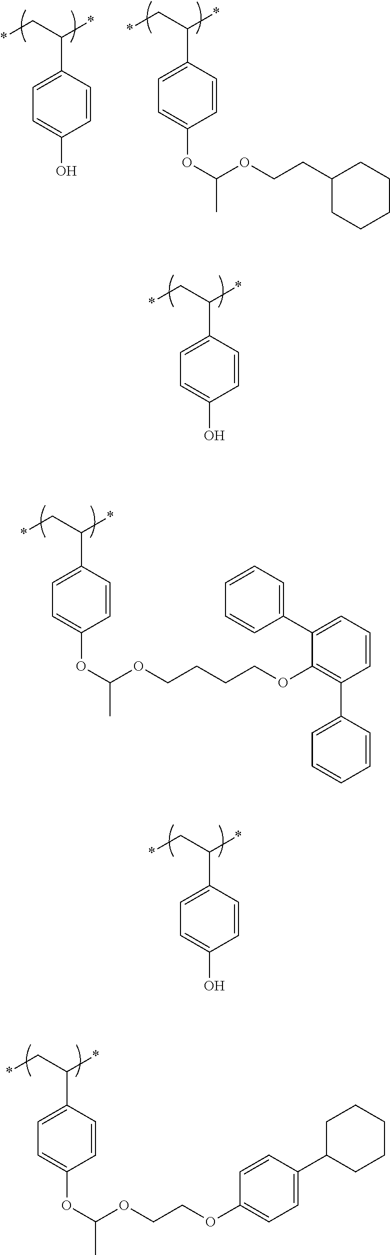

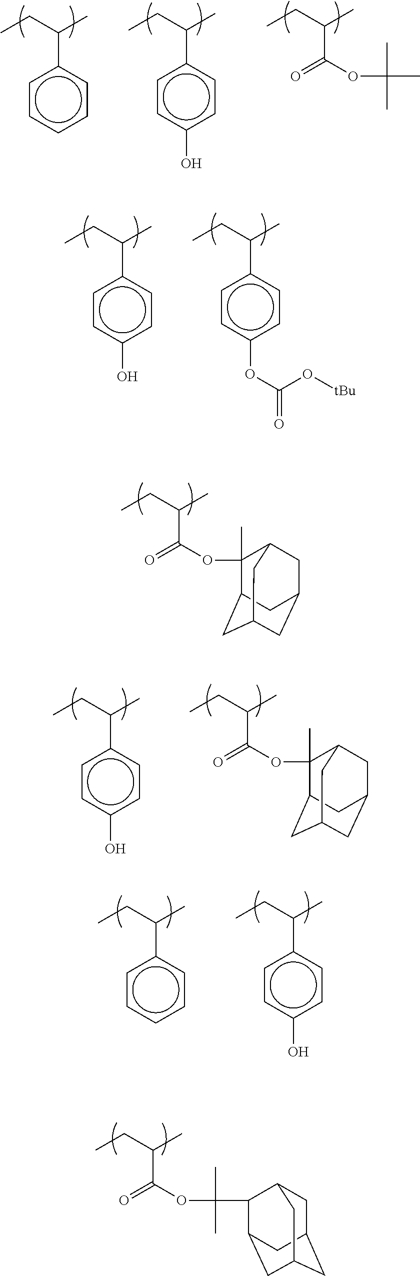

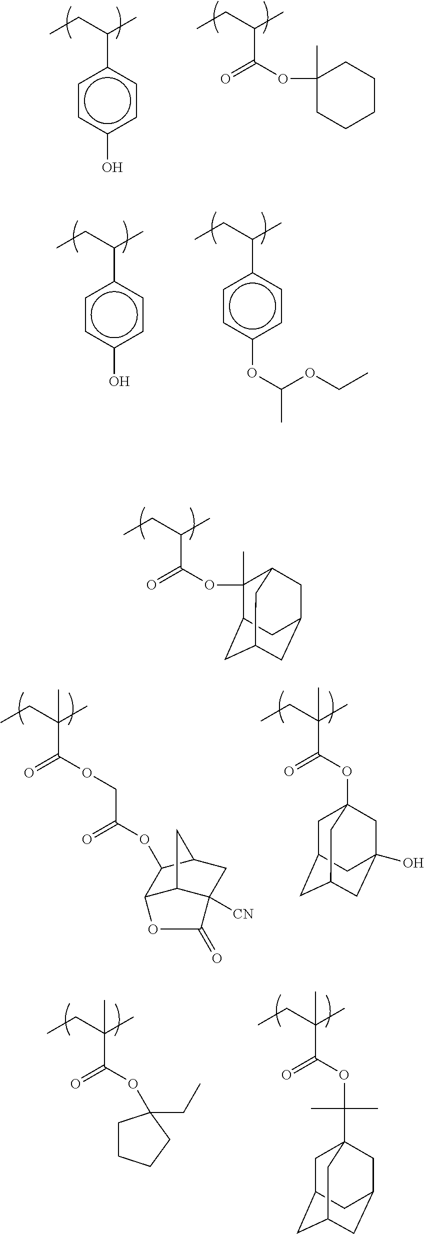

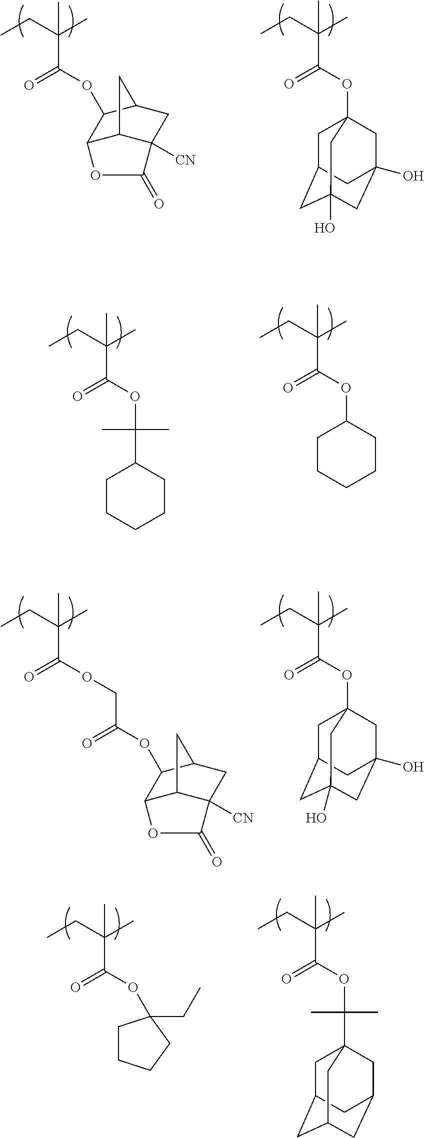

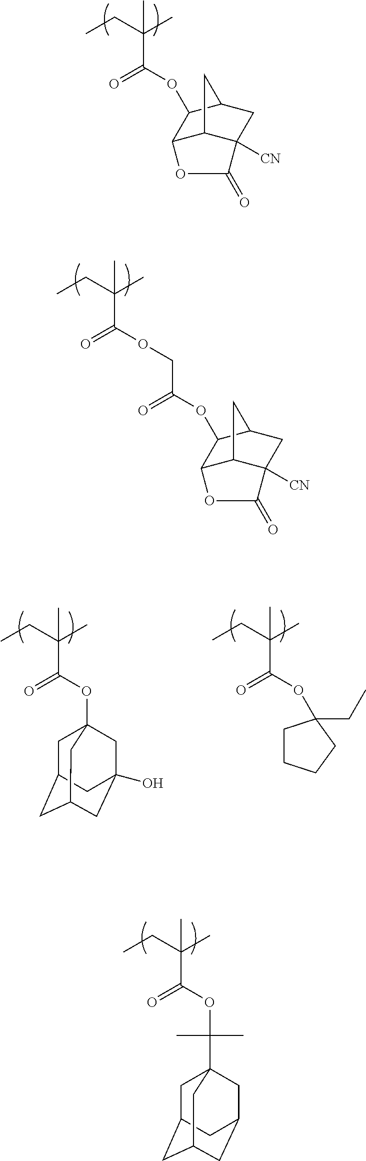

[2] Photoacid Generator

The composition of the present invention contains a photoacid generator.

The photoacid generator may be a low-molecular compound or a high-molecular compound. A compound that generates an organic acid, such as sulfonic acid, a bis(alkylsulfonyl)imide or a tris(alkylsulfonyl)methide, is preferred.

As the low-molecular acid generator, there can be mentioned, for example, any the compounds of general formulae (ZI), (ZII) and (ZIII) below.

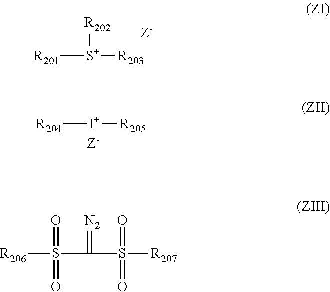

In general formula (ZI) above,

each of R₂₀₁, R₂₀₂ and R₂₀₃ independently represents an organic group.

The number of carbon atoms of each of the organic groups represented by R₂₀₁, R₂₀₂ and R₂₀₃ is generally in the range of 1 to 30, preferably 1 to 20.

Two of R₂₀₁ to R₂₀₃ may be bonded to each other to thereby form a ring structure, and the ring within the same may contain an oxygen atom, a sulfur atom, an ester bond, an amido bond or a carbonyl group. As the group formed by bonding of two of R₂₀₁ to R₂₀₃, there can be mentioned an alkylene group (for example, a butylene group or a pentylene group).

Z⁻ represents a normucleophilic anion. The normucleophilic anion means an anion whose capability of inducing a nucleophilic reaction is extremely low.

As the normucleophilic anion represented by Z⁻, there can be mentioned, for example, a sulfonate anion (for example, an aliphatic sulfonate anion, an aromatic sulfonate anion, a camphor sulfonate anion or the like), a carboxylate anion (for example, an aliphatic carboxylate anion, an aromatic carboxylate anion, an aralkyl carboxylate anion or the like), a sulfonylimido anion, a bis(alkylsulfonyl)imido anion, a tris(alkylsulfonyl)methide anion or the like.

The aliphatic moiety of the aliphatic sulfonate anion and the aliphatic carboxylate anion may be an alkyl group or a cycloalkyl group, being preferably a linear or branched alkyl group having 1 to 30 carbon atoms or a cycloalkyl group having 3 to 30 carbon atoms.

As a preferred aromatic group of the aromatic sulfonate anion and the aromatic carboxylate anion, there can be mentioned an aryl group having 6 to 14 carbon atoms, for example, a phenyl group, a tolyl group, a naphthyl group or the like.

The alkyl group, cycloalkyl group and aryl group mentioned above may have a substituent. As the substituent, there can be mentioned, for example, a nitro group, a halogen atom (e.g., a fluorine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) or the like. The aryl group or ring structure of these groups may further have an alkyl group (preferably having 1 to 15 carbon atoms) as its substituent.

As a preferred aralkyl group of the aralkyl carboxylate anion, there can be mentioned an aralkyl group having 6 to 12 carbon atoms, for example, a benzyl group, a phenethyl group, a naphthylmethyl group, a naphthylethyl group, a naphthylbutyl group or the like.

As the sulfonylimido anion, there can be mentioned, for example, a saccharin anion.

The alkyl group of the bis(alkylsulfonyl)imido anion and tris(alkylsulfonyl)methide anion is preferably an alkyl group having 1 to 5 carbon atoms.

As a substituent of these alkyl groups, there can be mentioned a halogen atom, an alkyl group substituted with a halogen atom, an alkoxy group, an alkylthio group, an alkyloxysulfonyl group, an aryloxysulfonyl group, a cycloalkylaryloxysulfonyl group or the like. A fluorine atom or an alkyl group substituted with a fluorine atom is preferred.

Each of the alkyl groups contained in the bis(alkylsulfonyl)imido anion may be linked to each other to thereby form a ring structure. Accordingly, there can be attained an enhancement of acid strength.

As the other normucleophilic anions, there can be mentioned, for example, phosphorus fluoride (for example, PF₆⁻), boron fluoride (for example, BF₄⁻), antimony fluoride (for example, SbF₆⁻) and the like.

The normucleophilic anion represented by Z⁻ is preferably selected from among an aliphatic sulfonate anion substituted at its α-position of sulfonic acid with a fluorine atom, an aromatic sulfonate anion substituted with a fluorine atom or a group having a fluorine atom, a bis(alkylsulfonyl)imido anion whose alkyl group is substituted with a fluorine atom and a tris(alkylsulfonyl)methide anion whose alkyl group is substituted with a fluorine atom. More preferably, the normucleophilic anion is a perfluorinated aliphatic sulfonate anion (still more preferably having 4 to 8 carbon atoms) or a benzene sulfonate anion having a fluorine atom. Still more preferably, the normucleophilic anion is a nonafluorobutane sulfonate anion, a perfluorooctane sulfonate anion, a pentafluorobenzene sulfonate anion or a 3,5-bis(trifluoromethyl)benzene sulfonate anion.

From the viewpoint of acid strength, it is preferred for the pKa value of generated acid to be −1 or less so as to ensure a sensitivity enhancement.

Further, as preferred forms of the normucleophilic anions, there can be mentioned the anions of general formula (AN1) below.

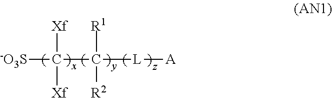

In the formula,

each of Xf's independently represents a fluorine atom or an alkyl group substituted with at least one fluorine atom.

Each of R¹ and R² independently represents a member selected from among a hydrogen atom, a fluorine atom, an alkyl group and an alkyl group substituted with at least one fluorine atom. When two or more R¹s or R²s are contained, the two or more may be identical to or different from each other.

L represents a single bond or a bivalent connecting group. When two or more L's are contained, they may be identical to or different from each other.

A represents a group with a cyclic structure.

In the formula, x is an integer of 1 to 20, y an integer of 0 to 10 and z an integer of 0 to 10.

General formula (AN1) will be described in greater detail below.

The alkyl group of the alkyl group substituted with a fluorine atom, represented by Xf preferably has 1 to 10 carbon atoms, more preferably 1 to 4 carbon atoms. The alkyl group substituted with a fluorine atom, represented by Xf is preferably a perfluoroalkyl group.

Xf is preferably a fluorine atom or a perfluoroalkyl group having 1 to 4 carbon atoms. In particular, there can be mentioned a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉. Of these, a fluorine atom and CF₃ are preferred.

Each of the alkyl group and the alkyl group of the alkyl group substituted with at least one fluorine atom, represented by each of R¹ and R² preferably has 1 to 4 carbon atoms.

Each of the alkyl group and the alkyl group of the alkyl group substituted with at least one fluorine atom, represented by R¹ or R² preferably has 1 to 4 carbon atoms.

In the formula, x is preferably 1 to 10, more preferably 1 to 5;

y is preferably 0 to 4, more preferably 0; and

z is preferably 0 to 5, more preferably 0 to 3.

The bivalent connecting group represented by L is not particularly limited. As the same, there can be mentioned —COO—, —COO—, —CO—, —O—, —S—, —SO—, —SO₂—, an alkylene group, a cycloalkylene group, an alkenylene group or the like. Of these, —COO—, —OCO—, —CO— and —O— are preferred. —COO— and —COO— are more preferred.

The group with a cyclic structure represented by A is not particularly limited as long as a cyclic structure is contained. As the group, there can be mentioned an alicyclic group, an aryl group, a group with any of heterocyclic structures (including not only those exhibiting aromaticity but also those exhibiting no aromaticity) or the like.

The alicyclic group may be monocyclic or polycyclic. Preferably, the alicyclic group is a monocycloalkyl group, such as a cyclopentyl group, a cyclohexyl group or a cyclooctyl group, or a polycycloalkyl group, such as a norbornyl group, a tricyclodecanyl group, a tetracyclodecanyl group, a tetracyclododecanyl group or an adamantyl group. Of the mentioned groups, alicyclic groups with a bulky structure having at least 7 carbon atoms, namely, a norbornyl group, a tricyclodecanyl group, a tetracyclodecanyl group, a tetracyclododecanyl group and an adamantyl group are preferred from the viewpoint of inhibiting any in-film diffusion in the step of post-exposure bake to thereby enhance MEEE.

As the aryl group, there can be mentioned a benzene ring, a naphthalene ring, a phenanthrene ring or an anthracene ring.

As the group with a heterocyclic structure, there can be mentioned a furan ring, a thiophene ring, a benzofuran ring, a benzothiophene ring, a dibenzofuran ring, a dibenzothiophene ring or a pyridine ring. Of these, a furan ring, a thiophene ring and a pyridine ring are preferred.

A substituent may be introduced in the above group with a cyclic structure. As the substituent, there can be mentioned an alkyl group (may be linear, branched or cyclic, preferably having 1 to 12 carbon atoms), an aryl group (preferably having 6 to 14 carbon atoms), a hydroxyl group, an alkoxy group, an ester group, an amido group, a urethane group, a ureido group, a thioether group, a sulfonamido group, a sulfonic ester group or the like.

The organic group represented by R₂₀₁, R₂₀₂ or R₂₀₃ is, for example, an aryl group, an alkyl group, a cycloalkyl group or the like.

Preferably, at least one of R₂₀₁, R₂₀₂ and R₂₀₃ is an aryl group. More preferably, these three are simultaneously aryl groups. The aryl groups include not only a phenyl group, a naphthyl group and the like but also heteroaryl groups, such as an indole residue and a pyrrole residue. As preferred alkyl groups and cycloalkyl groups represented by R₂₀₁ to R₂₀₃, there can be mentioned linear or branched alkyl groups each having 1 to 10 carbon atoms and cycloalkyl groups each having 3 to 10 carbon atoms. The alkyl group is more preferably a methyl group, an ethyl group, an n-propyl group, an i-propyl group, an n-butyl group or the like. The cycloalkyl group is more preferably a cyclopropyl group, a cyclobutyl group, a cyclopentyl group, a cyclohexyl group, a cycloheptyl group or the like. Substituents may further be introduced in these groups. As the substituents, there can be mentioned a nitro group, a halogen atom such as a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms) and the like. The appropriate substituents are not limited to these.

When any two of R₂₀₁ to R₂₀₃ are bonded to each other to thereby form a cyclic structure, the cyclic structure is preferably any of the structures of general formula (A1) below.

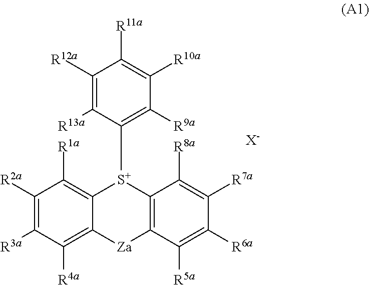

In general formula (A1), each of R^{1a} to R^{13a} independently represents a hydrogen atom or a substituent.

Preferably, one to three of R^{1a} to R^{13a} are not hydrogen atoms. More preferably, any one of R^{9a} to R^{13a} is not a hydrogen atom.

Za represents a single bond or a bivalent connecting group.

X⁻ has the same meaning as that of Z⁻ of general formula (ZI).

When R^{1a} to R^{13a} are not hydrogen atoms, particular examples thereof include a halogen atom, a linear, branched or cyclic alkyl group, an alkenyl group, an alkynyl group, an aryl group, a heterocyclic group, a cyano group, a nitro group, a carboxyl group, an alkoxy group, an aryloxy group, a silyloxy group, a heterocyclic oxy group, an acyloxy group, a carbamoyloxy group, an alkoxycarbonyloxy group, an aryloxycarbonyloxy group, any of amino groups (including an anilino group), an ammonia group, an acylamino group, an aminocarbonylamino group, an alkoxycarbonylamino group, an aryloxycarbonylamino group, a sulfamoylamino group, an alkyl- or arylsulfonylamino group, a mercapto group, an alkylthio group, an arylthio group, a heterocyclic thio group, a sulfamoyl group, a sulfo group, an alkyl- or arylsulfinyl group, an alkyl- or arylsulfonyl group, an acyl group, an aryloxycarbonyl group, an alkoxycarbonyl group, a carbamoyl group, an aryl- or heterocyclic azo group, an imido group, a phosphine group, a phosphinyl group, a phosphinyloxy group, a phosphinylamino group, a phosphono group, a silyl group, a hydrazino group, a ureido group, a boronic acid residue (—B(OH)₂), a phosphato group (—OPO (OH)₂), a sulfato group (—OSO₃H) or any of other substituents known in the art.

When R^{1a} to R^{13a} are not hydrogen atoms, they each preferably represent a hydroxylated linear, branched or cyclic alkyl group.

As the bivalent connecting group represented by Za, there can be mentioned an alkylene group, an arylene group, a carbonyl group, a sulfonyl group, a carbonyloxy group, a carbonylamino group, a sulfonylamido group, an ether group, a thioether group, an amino group, a disulfide group, —(CH₂)ₙ—CO—, —(CH₂)ₙ—SO₂—, —CH═CH—, an aminocarbonylamino group, an aminosulfonylamino group or the like (n is an integer of 1 to 3).

When at least one of R₂₀₁, R₂₀₂ and R₂₀₃ is not an aryl group, as preferred structures, there can be mentioned cationic structures, such as the compounds set forth in sections 0047 and 0048 of JP-A-2004-233661 and sections 0040 to 0046 of JP-A-2003-35948, the compounds of formulae (I-1) to (1-70) shown as examples in US Patent Application Publication No. 2003/0224288 A1 and the compounds of formulae (IA-1) to (IA-54) and (IB-1) to (IB-24) shown as examples in US Patent Application Publication No. 2003/0077540 A1.

In general formulae (ZII) and (ZIII),

each of R₂₀₄ to R₂₀₇ independently represents an aryl group, an alkyl group or a cycloalkyl group.

The examples of the aryl group, alkyl group and cycloalkyl group represented by R₂₀₄ to R₂₀₇ are the same as mentioned with respect to (ZI) above.

The aryl group, alkyl group and cycloalkyl group represented by R₂₀₄ to R₂₀₇ may have a substituent. As a possible substituent on the aryl group, alkyl group and cycloalkyl group, there can also be mentioned the same as in general formula (ZI) above.

Z⁻ represents a normucleophilic anion. As such, there can be mentioned the same normucleophilic anions as mentioned with respect to the Z⁻ of general formula (ZI).

As the acid generators, there can be further mentioned the compounds of formulae (ZIV), (ZV) and (ZVI) below.

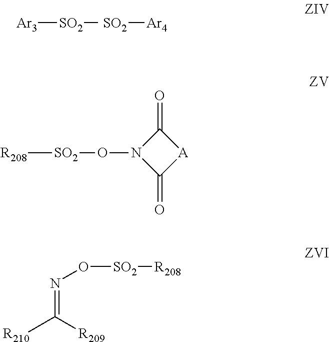

In general formulae (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Particular examples of the aryl groups represented by Ar₃, Ar₄, R₂₀₈, R₂₀₉ and R₂₁₀ are the same as those of the aryl groups represented by R₂₀₁, R₂₀₂, and R₂₀₃ of general formula (ZI) mentioned above.

Particular examples of the alkyl groups and the cycloalkyl groups represented by R₂₀₈, R₂₀₉ and R₂₁₀ are the same as those of the alkyl groups and the cycloalkyl groups represented by R₂₀₁, R₂₀₂, and R₂₀₃ of general formula (ZI-2) mentioned above. Particular examples of the alkyl group and cycloalkyl group represented by each of R₂₀₈, R₂₀₉ and R₂₁₀ are the same as mentioned above with respect to the alkyl group and cycloalkyl group represented by each of R₂₀₁, R₂₀₂ and R₂₀₃ of general formula (ZI) above.

As the alkylene group represented by A, there can be mentioned an alkylene group having 1 to 12 carbon atoms (for example, a methylene group, an ethylene group, a propylene group, an isopropylene group, a butylene group or an isobutylene group). As the alkenylene group represented by A, there can be mentioned an alkenylene group having 2 to 12 carbon atoms (for example, an ethynylene group, a propenylene group or a butenylene group). As the arylene group represented by A, there can be mentioned an arylene group having 6 to 10 carbon atoms (for example, a phenylene group, a tolylene group or a naphthylene group).

Especially preferred examples of the acid generators will be shown below.

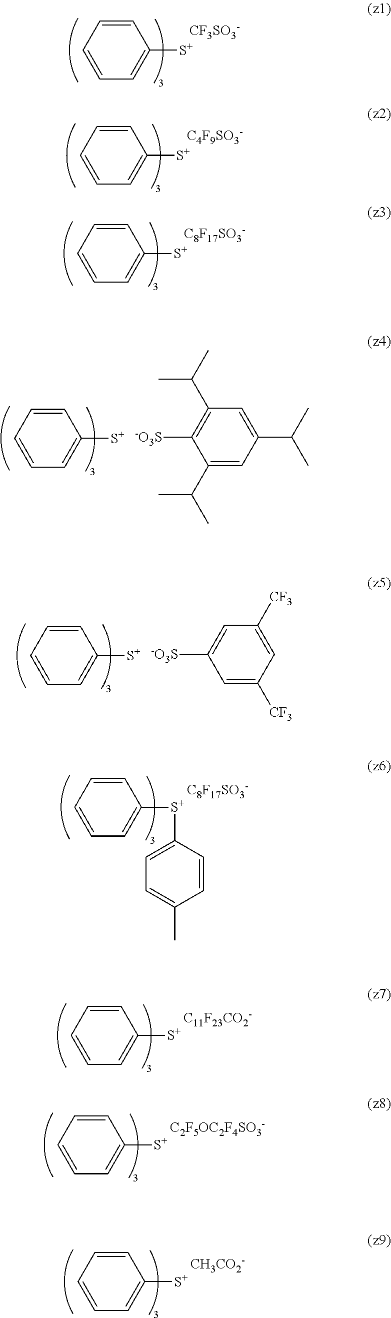

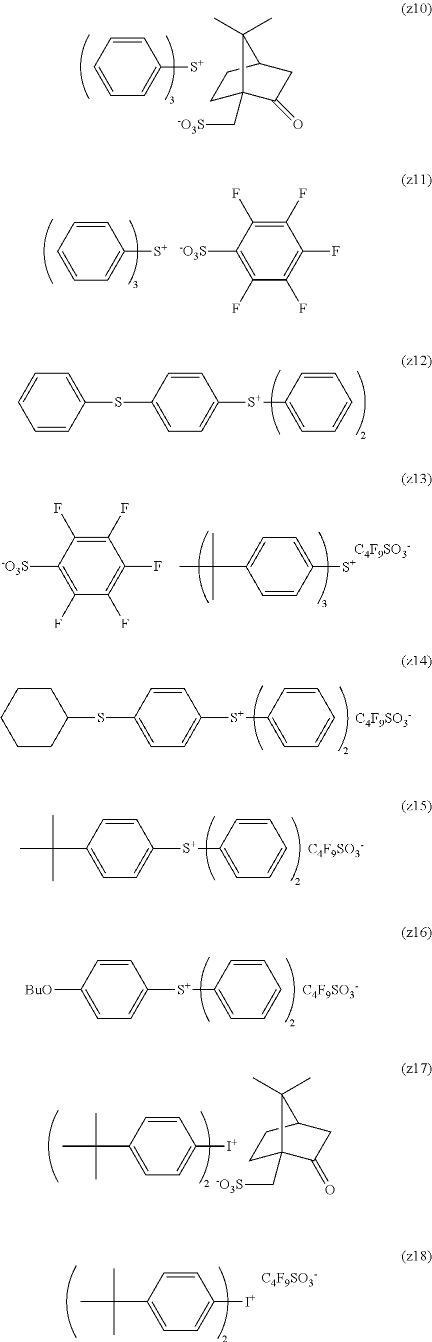

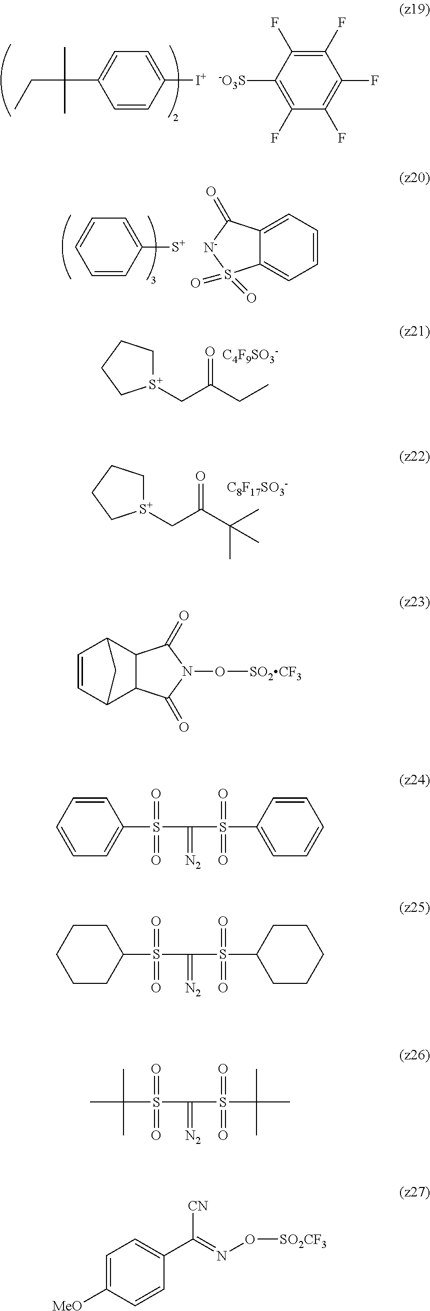

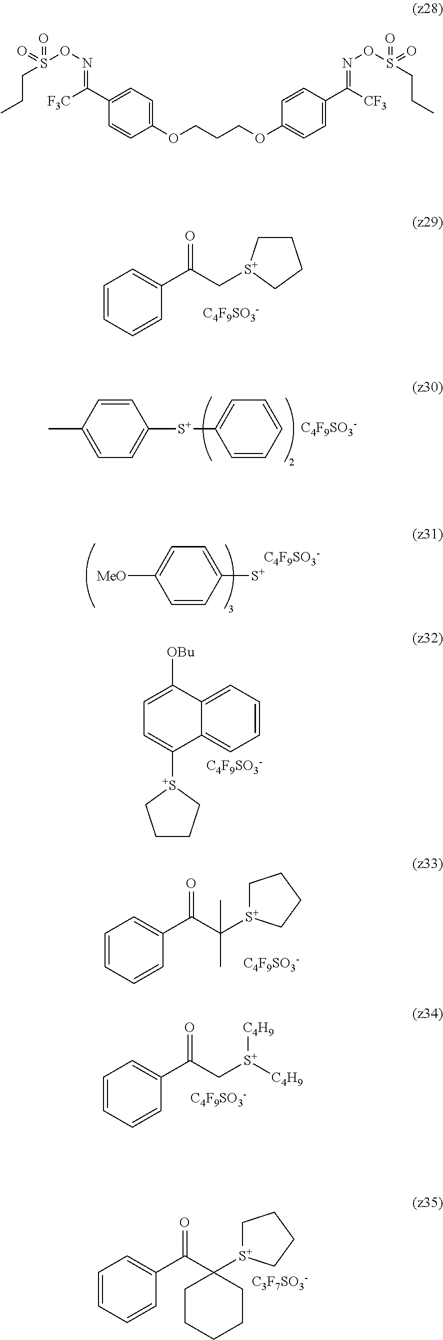

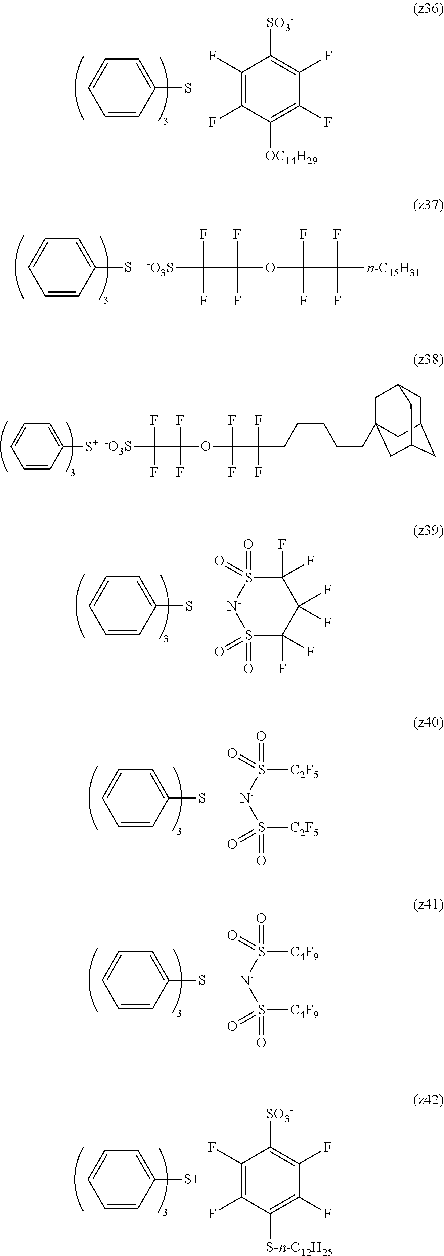

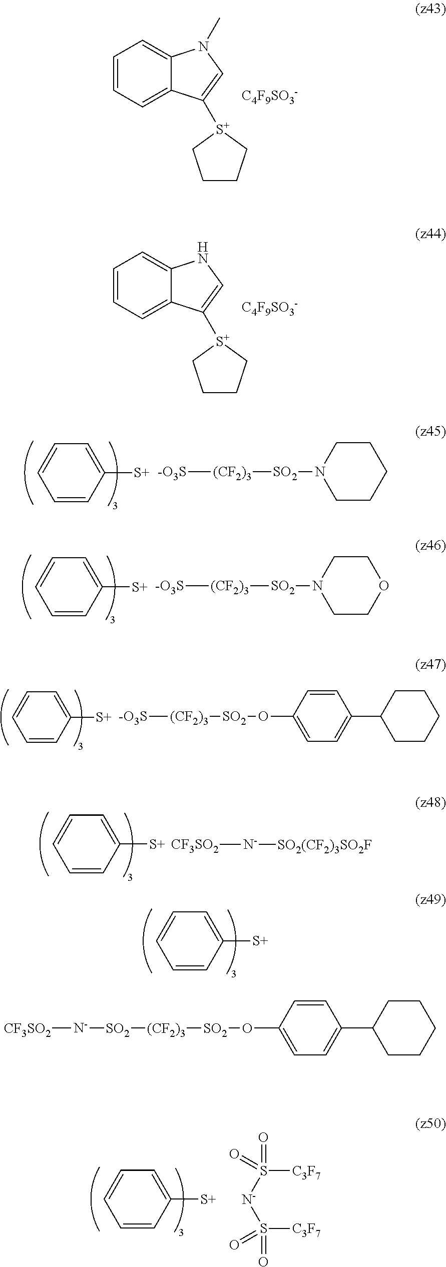

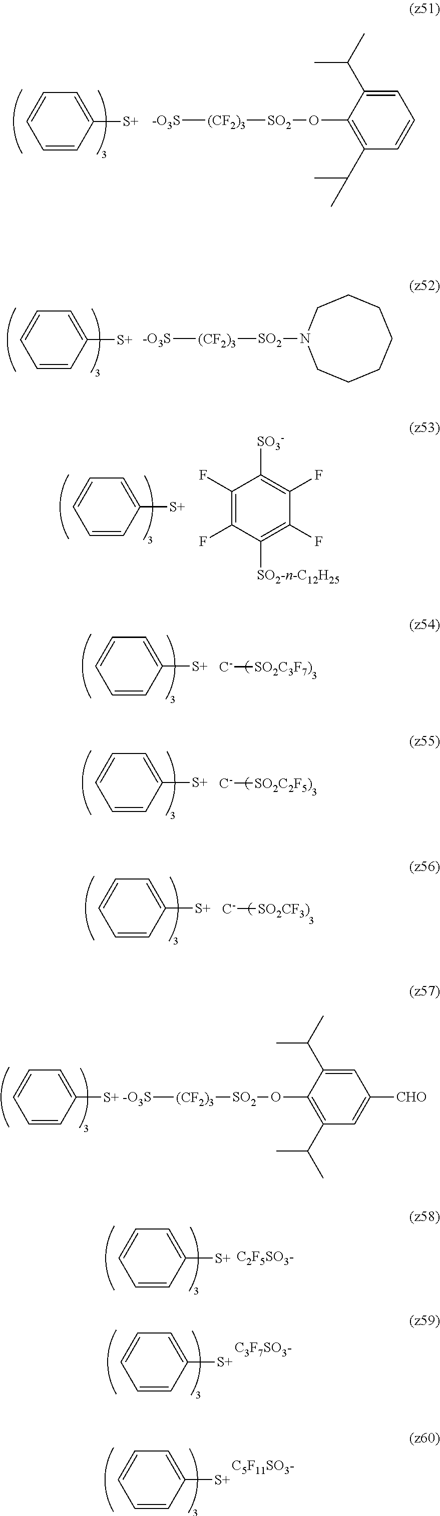

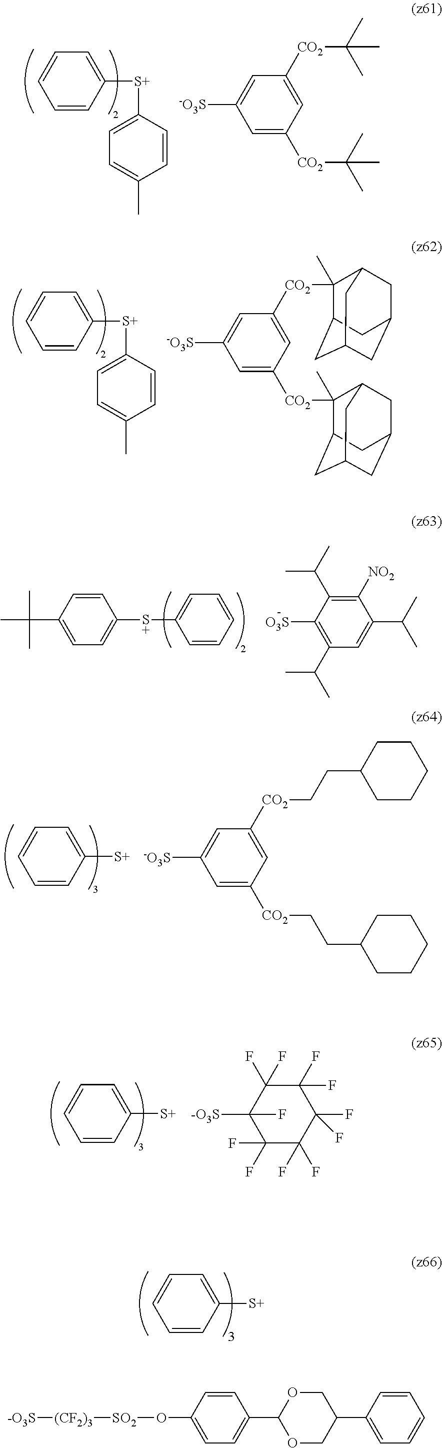

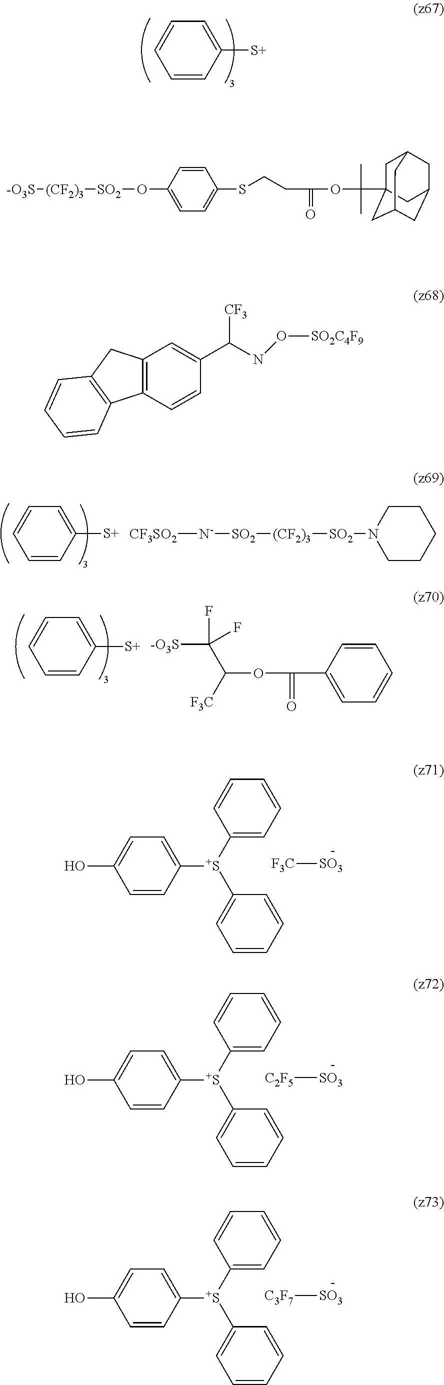

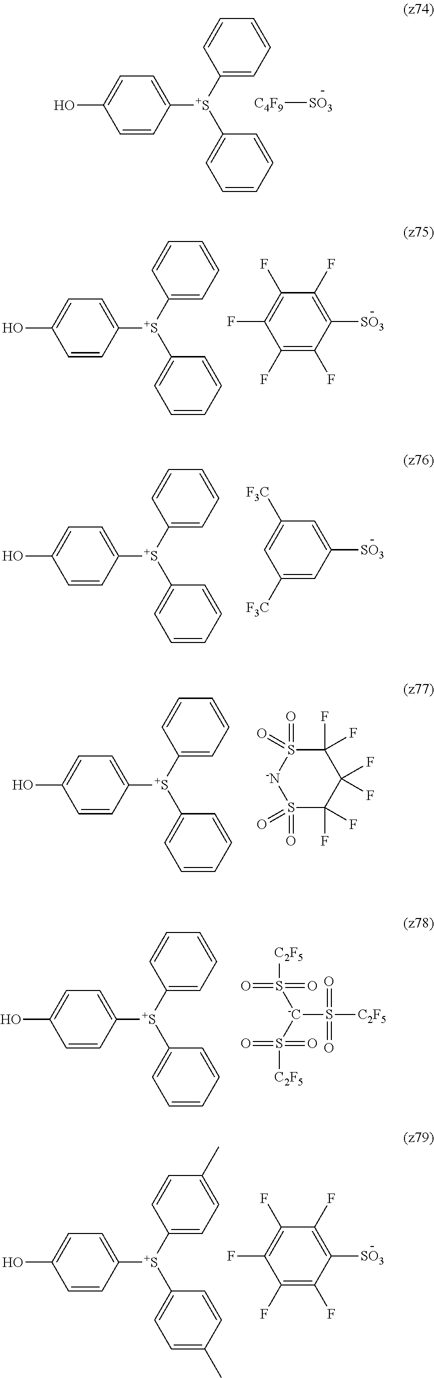

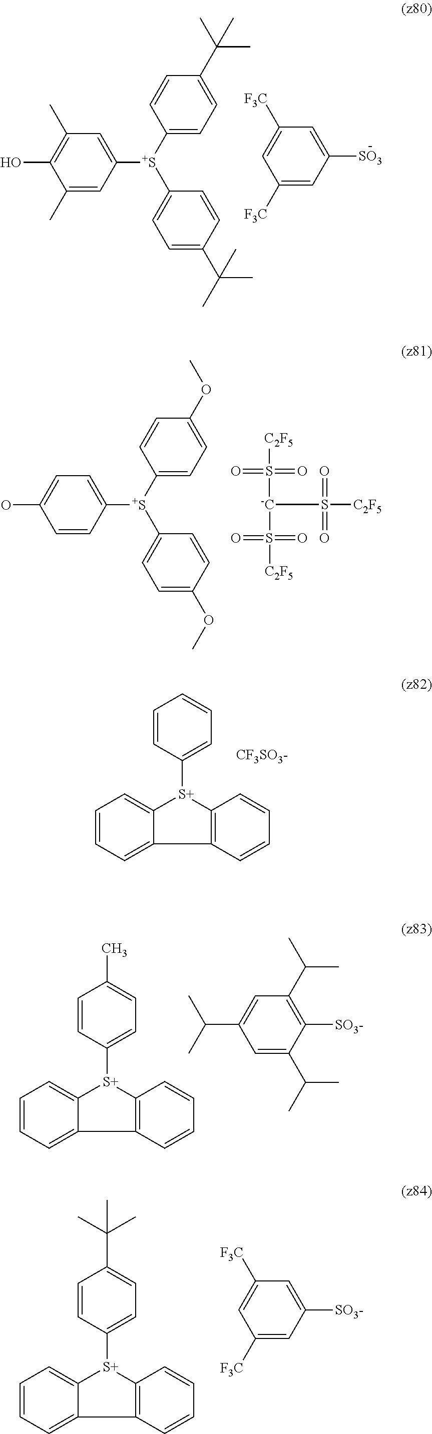

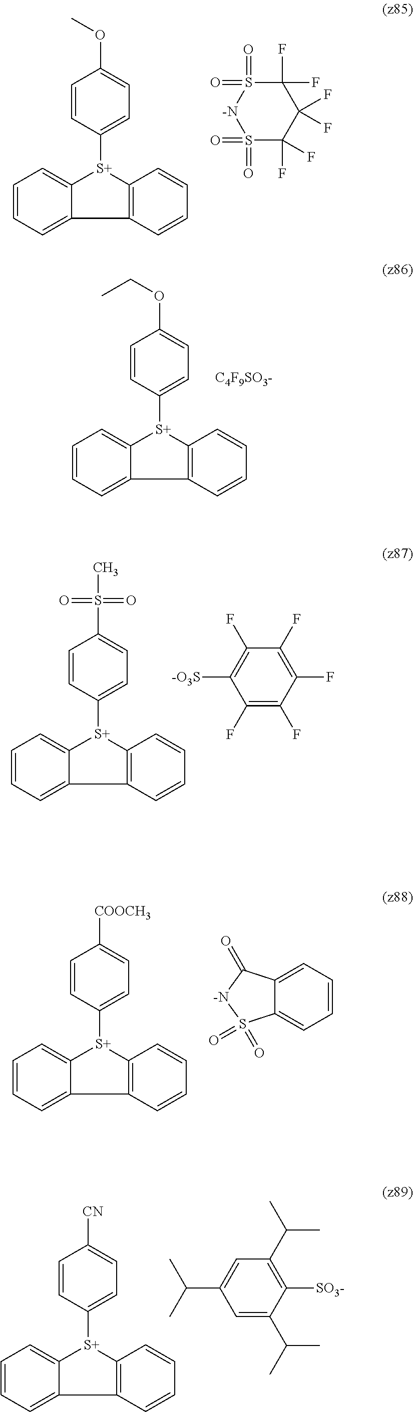

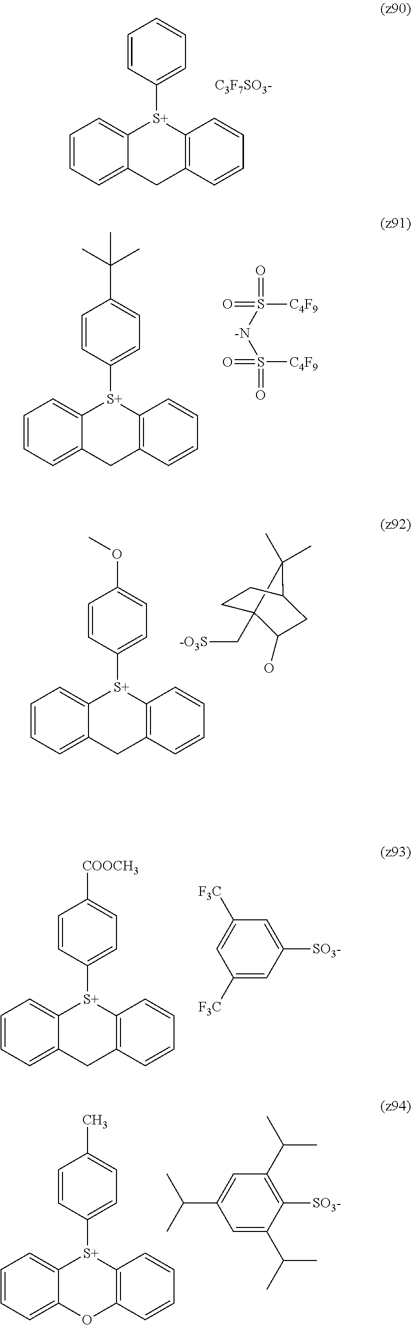

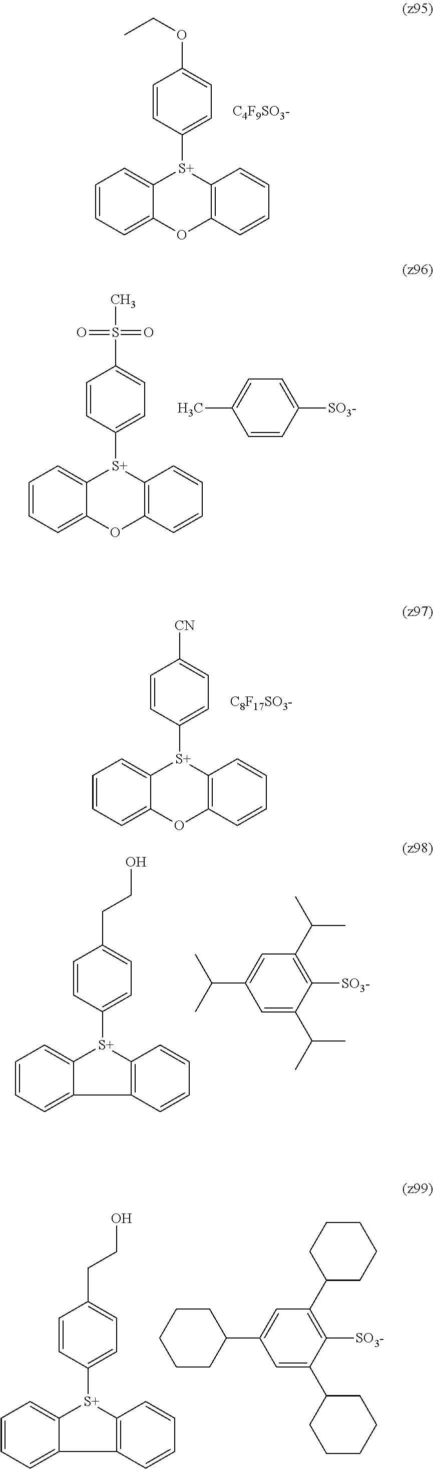

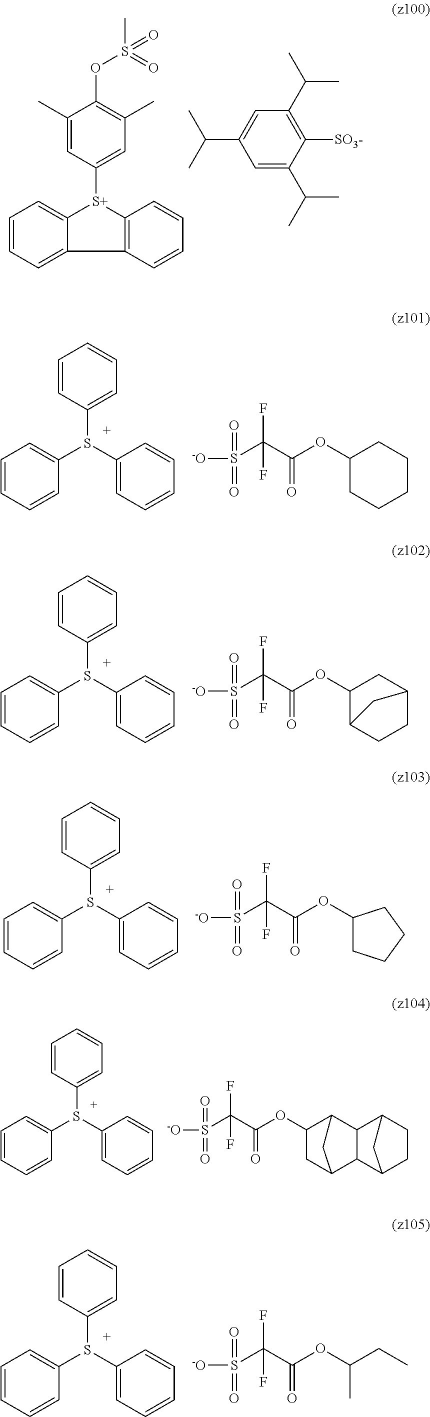

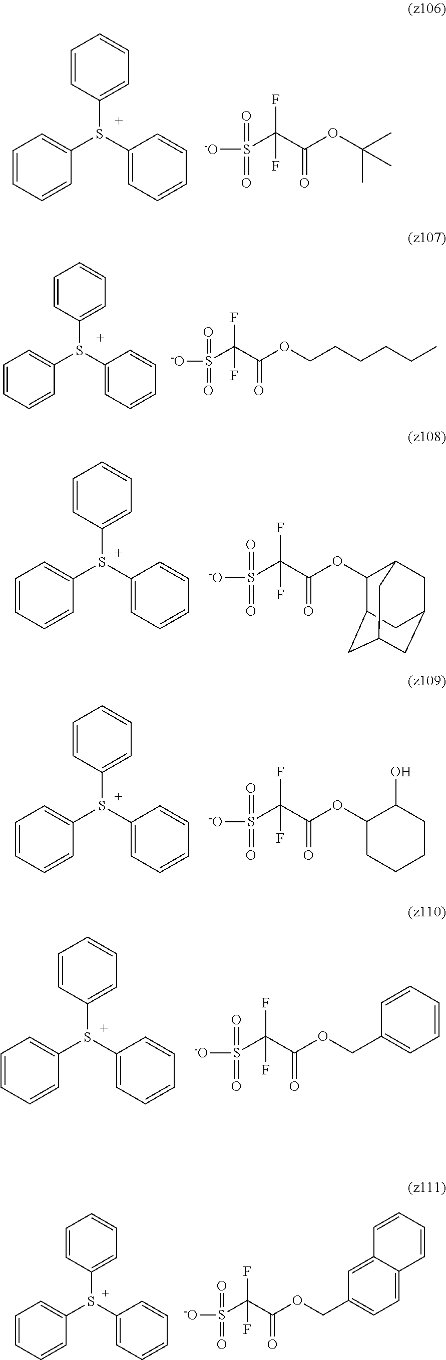

When the above low-molecular acid generator is used, the content thereof in the composition, based on the total solids of the composition, is preferably in the range of 0.1 to 70 mass %, more preferably 5 to 60 mass % and further more preferably 10 to 50 mass %.

When the acid generator is a polymer, it is preferred for the polymer to contain a repeating unit that when exposed to actinic rays or radiation, is decomposed to thereby generate an acid anion in a side chain of the resin. In particular, it is preferably contained in the resin as a component copolymerized with the acid-decomposable repeating unit of the resin (P) according to the present invention.

[3] Basic Compound

The composition of the present invention contains a compound (R) expressed by general formula (1) or (2) below as a basic compound.

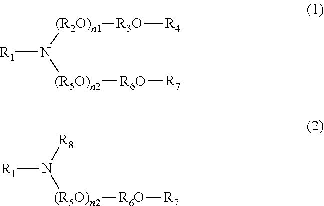

In the formulae,

each of R₁ and R₈ independently represents an organic group containing no heteroatom,

each of R₂, R₃, R₅ and R₆ independently represents an alkylene group having 1 to 3 carbon atoms,

each of R₄ and R₇ independently represents a hydrogen atom or an alkyl group, and

each of n₁ and n₂ independently is an integer of 1 to 6.

Preferably, each of R₁ and R₈ independently represents an alkyl group or an aryl group. An alkyl group is more preferred.

The alkyl group represented R₁ or R₈ preferably has at least 3 carbon atoms, more preferably at least 6 carbon atoms and further more preferably at least 7 carbon atoms. The number of carbon atoms is generally up to 30, for example, up to 20. This alkyl group includes a cycloalkyl group.

As the aryl group represented R₁ or R₈, there can be mentioned, for example, a phenyl group or a naphthyl group. It is preferred for the aryl group to be a phenyl group.

The alkylene group represented by R₂, R₃, R₅ or R₆ preferably has 2 or 3 carbon atoms. An arbitrary substituent may further be introduced in this alkylene group.

When the compound (R) is expressed by general formula (1), it is preferred for at least either R₄ or R₇ to be a hydrogen atom. More preferably, both of R₄ and R₇ are hydrogen atoms.

When the compound (R) is expressed by general formula (2), it is preferred for R₇ to be a hydrogen atom.

The alkyl group represented by R₄ or R₇ preferably has 1 to 4 carbon atoms. A methyl group and an ethyl group are more preferred. A methyl group is most preferred.

Each of n₁ and n₂ independently is preferably in the range of 1 to 4, more preferably 1 or 2.

Specific examples of the compounds (R) of general formulae (1) and (2) are shown below.

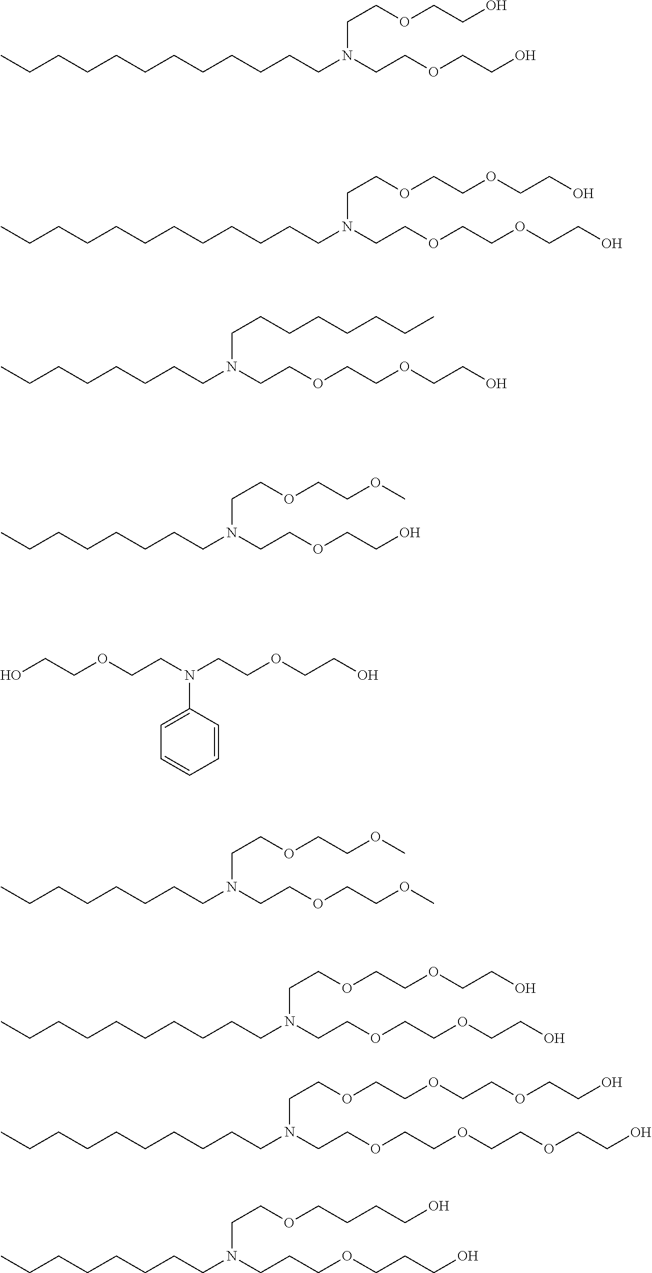

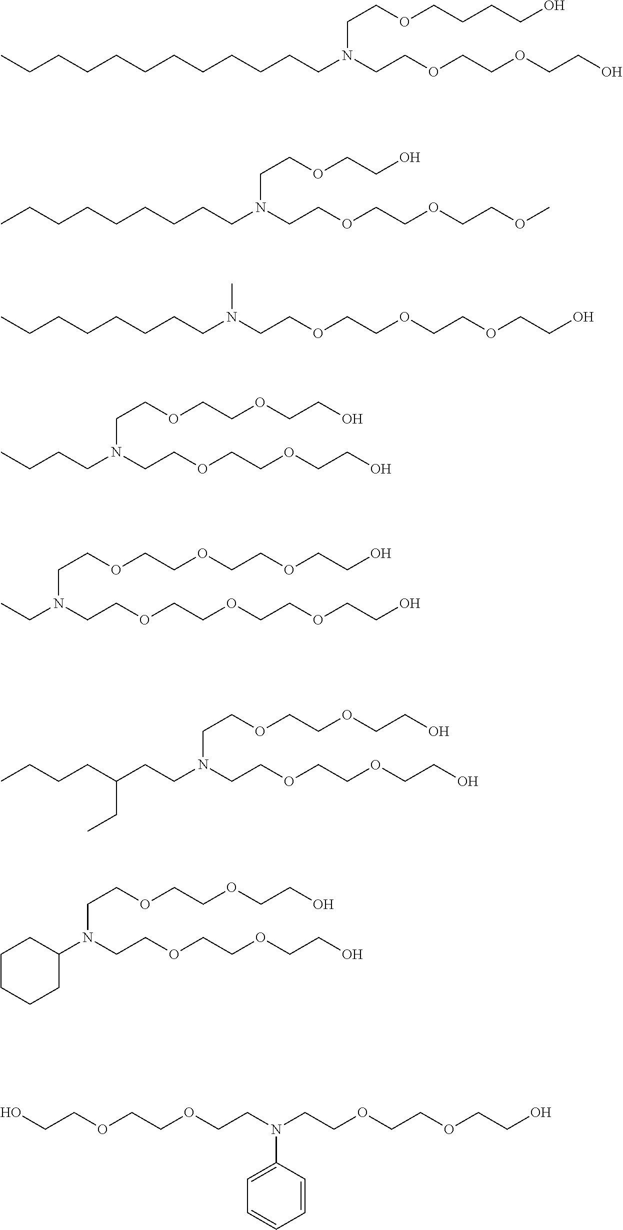

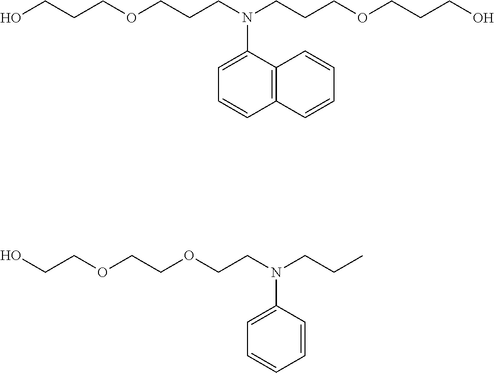

One of the compounds (R) of general formulae (1) and (2) may be used alone, or two or more thereof may be used in combination.

The content of compound (R) based on the total solids of the composition is preferably in the range of 0.01 to 20.0 mass %, more preferably 0.1 to 15.0 mass % and most preferably 0.5 to 10.0 mass %.

The actinic-ray- or radiation-sensitive resin composition of the present invention may further contain a basic compound other than the compounds (R). The basic compound is preferably a nitrogen-containing organic compound. As such a basic compound, there can be mentioned, for example, tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, 2,4,6-tri(t-butyl)aniline, triethanolamine, N,N-dihydroxyethylaniline, tris(methoxyethoxyethyl)amine, 2-phenylbenzimidazole, 2,4,5-triphenylimidazole, N-hydroxyethylpiperidine, bis(1,2,2,6,6-pentamethyl-4-piperidyl)sebacate, 4-dimethylaminopyridine, antipyrine, hydroxyantipyrine, tetrabutylammonium hydroxide or the like.

The basic compound used in combination with the compound (R) is preferably one containing no hydroxyl group. If so, an enhanced pattern shape can be obtained. Further, residue defects can be reduced. In addition, the most appropriate formulation for obtaining the most favorable pattern shape, most favorable roughness characteristic and least residue defects can be realized on various foundation substrates (acid substrate, substrate coated with an organic layer). Namely, the most appropriate formulation can be easily realized by regulating the ratio between compound (R) and basic compound other than the compounds (R) in which no hydroxyl group is incorporated.

The content of basic compounds [including compound (R)] based on the total solids of the composition is preferably in the range of 0.01 to 20.0 mass %, more preferably 0.1 to 15.0 mass % and most preferably 0.5 to 10.0 mass %.

[4] Other Component

The composition of the present invention may further comprise components other than the above resin (P) and compounds (Q) and (R).

For example, it is preferred for the composition of the present invention to further contain a surfactant. The surfactant is preferably a fluorinated and/or siliconized surfactant.

As such a surfactant, there can be mentioned Megafac F177 or Megafac R08 produced by Dainippon Ink & Chemicals, Inc., PF656 or PF6320 produced by OMNOVA SOLUTIONS, INC., Troy Sol S-366 produced by Troy Chemical Co., Ltd., Florad FC430 produced by Sumitomo 3M Ltd., polysiloxane polymer KP-341 produced by Shin-Etsu Chemical Co., Ltd., or the like.

Surfactants other than these fluorinated and/or siliconized surfactants can also be used. In particular, the other surfactants include polyoxyethylene alkyl ethers, polyoxyethylene alkyl aryl ethers and the like. As other useful surfactants, there can be mentioned, for example, those described in section [0273] et seq of US Patent Application Publication No. 2008/0248425 A1.

These surfactants may be used alone or in combination.

The amount of surfactant added is preferably in the range of 0.0001 to 2 mass %, more preferably 0.001 to 1 mass %, based on the total solids of the composition.

The composition of the present invention may contain a dissolution inhibiting compound of 3000 or less molecular weight that is decomposed by the action of an acid to thereby increase its rate of dissolution in an alkali developer (hereinafter also simply referred to as a “dissolution inhibiting compound”).

It is preferred for the dissolution inhibiting compound to be an alicyclic or aliphatic compound containing an acid-decomposable group, such as any of cholic acid derivatives containing an acid-decomposable group described in Proceeding of SPIE, 2724, 355 (1996), or a compound containing a structure resulting from substitution of the phenolic hydroxyl group of a phenol compound with an acid-decomposable group. The phenol compound preferably contains 1 to 9 phenol skeletons, more preferably 2 to 6 phenol skeletons.

The molecular weight of the dissolution inhibiting compound according to the present invention is 3000 or less, preferably 300 to 3000 and more preferably 500 to 2500.

The composition of the present invention may further contain a dye. As an appropriate dye, there can be mentioned, for example, an oil dye or a basic dye.

The composition of the present invention may further contain a compound capable of accelerating the dissolution in a developer (dissolution accelerating compound). The dissolution accelerating compound is, for example, a low-molecular compound of 1000 or less molecular weight having either two or more phenolic OH groups or one or more carboxyl groups. When a carboxyl group is contained, an alicyclic or aliphatic compound is preferred. As the phenolic compound of 1000 or less molecular weight, there can be mentioned, for example, those described in JP-A's H4-122938 and H2-28531, U.S. Pat. No. 4,916,210 and European Patent 219294.

Still further, compounds having a functional group with proton acceptor properties described in, for example, JP-A's 2006-208781 and 2007-286574 can be appropriately incorporated in the composition of the present invention.

It is preferred for the composition of the present invention to be in the form of a solution containing a solvent. As such a solvent, there can be mentioned an organic solvent, such as an alkylene glycol monoalkyl ether carboxylate, an alkylene glycol monoalkyl ether, an alkyl lactate, an alkyl alkoxypropionate, a cyclolactone, an optionally cyclized monoketone compound, an alkylene carbonate, an alkyl alkoxyacetate or an alkyl pyruvate. Solvents whose normal boiling point is 150° C. or below are especially preferred.

As preferred solvents, there can be mentioned 2-heptanone, cyclopentanone, γ-butyrolactone, cyclohexanone, butyl acetate, ethyl lactate, ethylene glycol monoethyl ether acetate, propylene glycol monomethyl ether acetate, propylene glycol monomethyl ether, ethyl 3-ethoxypropionate, ethyl pyruvate, 2-ethoxyethyl acetate, 2-(2-ethoxyethoxy)ethyl acetate and propylene carbonate. Most preferred solvents are propylene glycol monomethyl ether acetate and propylene glycol monomethyl ether.

In the present invention, any one of these solvents may be used alone, or any two or more thereof may be used in combination.

The amount of solvent used in the whole amount of the composition of the present invention can be appropriately regulated in accordance with the desired film thickness, etc. In general, the amount is so regulated that the total solid concentration of the composition falls in the range of 0.5 to 30 mass %, preferably 1.0 to 20 mass % and more preferably 1.5 to 10 mass %.

With respect to the particulars of the process for fabricating an imprint mold structure with the use of the composition of the present invention, reference can be made to, for example, “Fundamentals of nanoimprint and its technology development/application deployment-technology of nanoimprint substrate and its latest technology deployment” edited by Yoshihiko Hirai, published by Frontier Publishing (issued in June, 2006), Japanese Patent No. 4109085, JP-A-2008-162101, etc.

<Method of Forming Pattern>

The composition of the present invention is typically used in the following manner. In particular, the composition of the present invention is typically applied onto a support, such as a substrate, thereby forming a film. The thickness of the film is preferably in the range of 0.02 to 10.0 μm. The method of application onto a substrate is preferably spin coating. The spin coating is performed at a rotating speed of preferably 1000 to 3000 rpm.

For example, the composition is applied onto, for example, any of substrates (e.g., silicon/silicon dioxide coating, silicon nitride and chromium-vapor-deposited quartz substrate, etc.) for use in the production of precision integrated circuit devices, etc. by appropriate application means, such as a spinner or a coater. The thus applied composition is dried, thereby forming an actinic-ray- or radiation-sensitive film (hereinafter also referred to as a photosensitive film). The application of the composition to the substrate can be preceded by the application of a heretofore known antireflection film.

The resultant photosensitive film is exposed to actinic rays or radiation, preferably baked (heated), and developed. A pattern of enhanced quality can be obtained by baking. From the viewpoint of sensitivity and stability, the baking temperature is preferably in the range of 80 to 150° C., more preferably 90 to 130° C.

As the actinic rays or radiation, there can be mentioned, for example, infrared light, visible light, ultraviolet light, far-ultraviolet light, X-rays or electron beams. It is preferred for the actinic rays or radiation to have, for example, a wavelength of 250 nm or shorter, especially 220 nm or shorter. As such actinic rays or radiation, there can be mentioned, for example, a KrF excimer laser (248 nm), an ArF excimer laser (193 nm), an F₂ excimer laser (157 nm), X-rays or electron beams. As preferred actinic rays or radiation, there can be mentioned EUV-rays or electron beams. EUV-rays are especially appropriate.

The exposure in the condition that the interstice between the photosensitive film and a lens is filled with a liquid (for example, pure water) whose refractive index is higher than that of air, namely, liquid-immersion exposure may be carried out in the stage of the exposure to actinic rays or radiation. This liquid-immersion exposure can enhance the resolution.

In the development step, an alkali developer is generally used. As the alkali developer for the composition of the present invention, use can be made of any of alkaline aqueous solutions containing, for example, an inorganic alkali compound such as sodium hydroxide, potassium hydroxide, sodium carbonate, sodium silicate, sodium metasilicate or aqueous ammonia; a primary amine such as ethylamine or n-propylamine; a secondary amine such as diethylamine or di-n-butylamine; a tertiary amine such as triethylamine or methyldiethylamine; an alcoholamine such as dimethylethanolamine or triethanolamine; a quaternary ammonium salt such as tetramethylammonium hydroxide or tetraethylammonium hydroxide; or a cycloamine such as pyrrole or piperidine.

Appropriate amounts of an alcohol and a surfactant may be added to the alkali developer before use. The alkali concentration of the alkali developer is generally in the range of 0.1 to 20 mass %. The pH value of the alkali developer is generally in the range of 10.0 to 15.0.

### EXAMPLE

The present invention will be described in greater detail below by way of its examples. However, the gist of the present invention is in no way limited to these examples.

<Acid-Decomposable Resin>

The following resins (A-1) to (A-5) were provided as the resin (P).

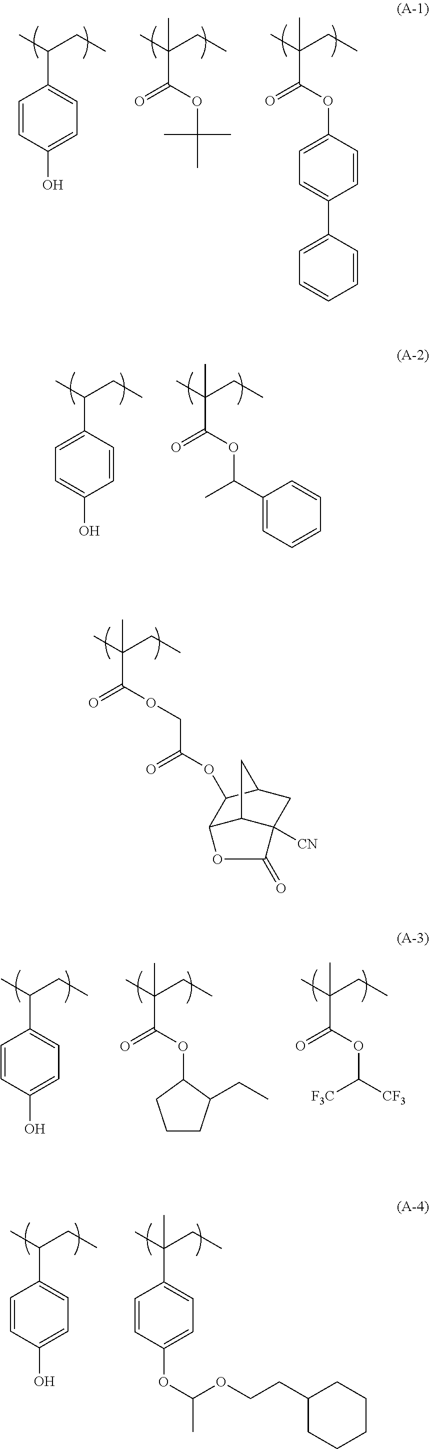

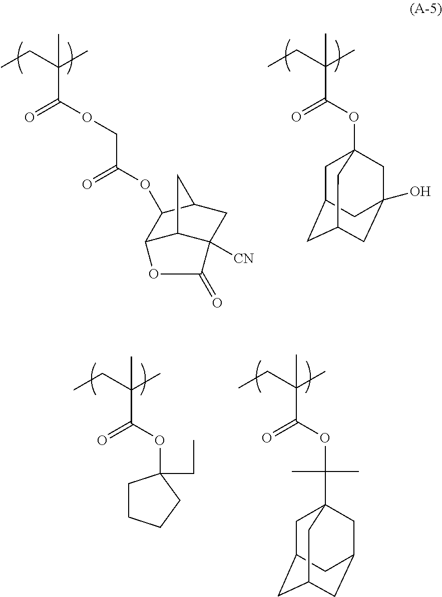

<Photoacid Generator>

The following compounds (B-1) to (B-3) were provided as the compound (Q).

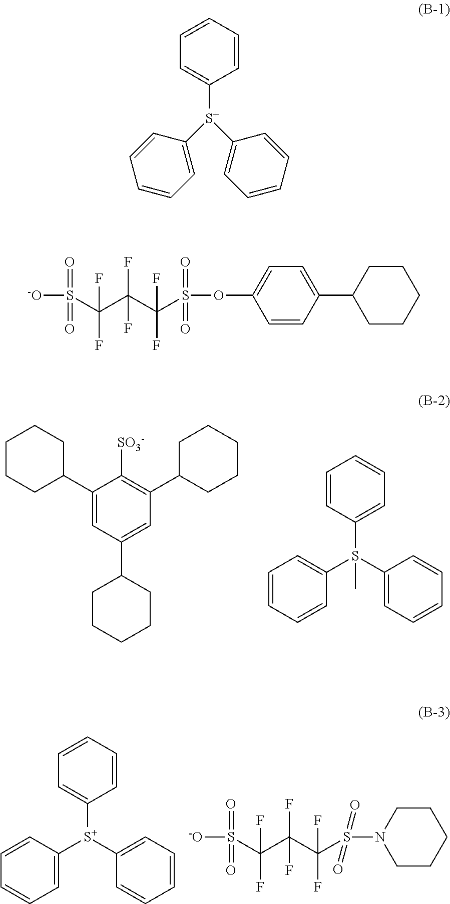

<Basic Compound>

The following compounds (C-1) to (C-6) were synthesized as the compound (R).

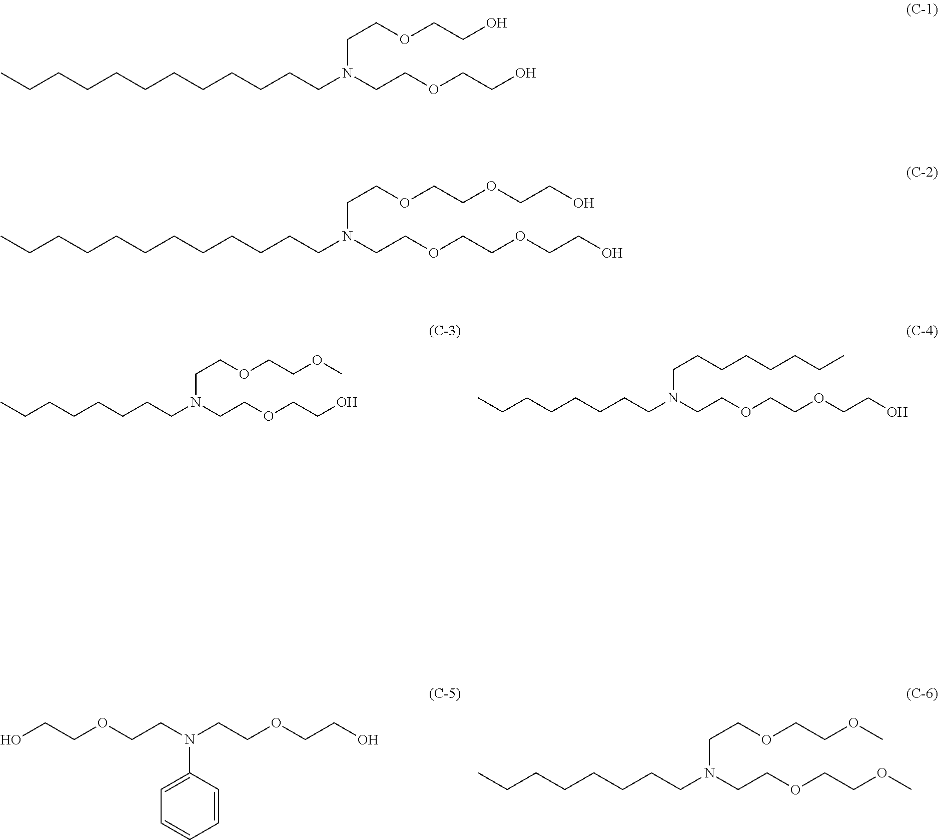 [SMILES: CCCCCCCCCCCCN(CCOCCO)CCOCCO ; CCCCCCCCCCCCN(CCOCCOCCO)CCOCCOCCO ; CCCCCCCCN(CCOCCO)CCOCCOC ; CCCCCCCCN(CCCCCCCC)CCOCCOCCO ; OCCOCCN(CCOCCO)c1ccccc1 ; CCCCCCCCN(CCOCCOC)CCOCCOC]

The above compounds (C-1) to (C-6) can be synthesized by heretofore known methods.

For example, the compound (C-1) can be easily synthesized by heating dodecylamine, 2 equivalent weight of chloroethoxyethanol and 2 or more equivalent weight of base, such as triethylamine or potassium carbonate, in the presence of a catalyst, such as potassium iodide, in an aprotic solvent, such as N,N-dimethylacetamide or N-methylpyrrolidone, at 50° C. or higher. A highly purified compound (C-1) can be obtained by adding ethyl acetate and water to the reaction liquid after the completion of the reaction, conducting a liquid-separating operation, concentrating the obtained organic phase and carrying out a separation by distillation or silica gel chromatography. Identification of the compound can be performed by nmR spectroscopy and MS spectroscopy. The compounds (C-2), (C-4), (C-5) and (C-6) can be synthesized in the similar manner. Any compound in which three substituents on nitrogen are different from each other, such as the compound (C-3), can be synthesized by sequentially introducing these substituents one by one. Relevant reagents, solvents, etc. are being marketed by, for example, Wako Pure Chemical Industries, Ltd., Tokyo Chemical Industry Co., Ltd. and Sigma-Aldrich Co. and thus can be easily procured.

The following compounds (C-7) and (C-8) were provided as basic compounds usable in combination with the compound (R).

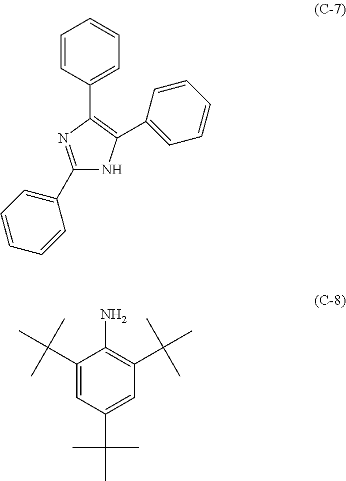 [SMILES: c1ccc(-c2nc(-c3ccccc3)c(-c3ccccc3)[nH]2)cc1 ; CC(C)(C)c1cc(C(C)(C)C)c(N)c(C(C)(C)C)c1]

The following compounds (C-A) to (C-D) were provided as comparative basic compounds.

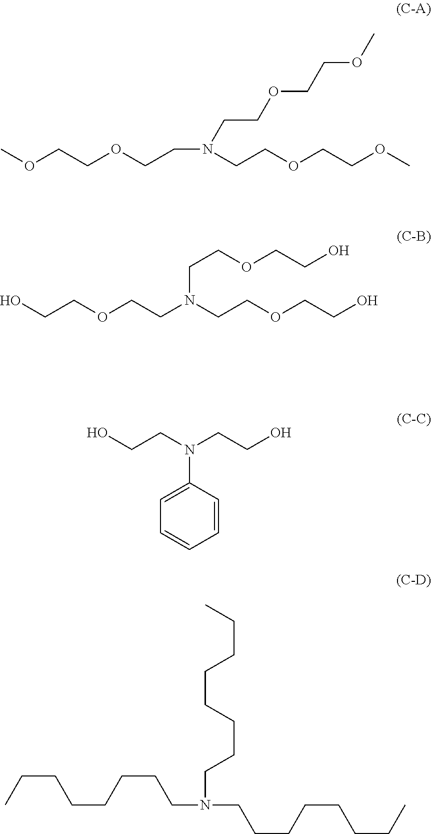

<Surfactant>

The following surfactant was used.

W-1: PF6320 (produced by OMNOVA SOLUTIONS, INC., fluorinated).

<Preparation of Resist Composition>

Components of Table 1 below were dissolved in a solvent consisting of a 40:60 mixture of propylene glycol monomethyl ether acetate and propylene glycol monomethyl ether, thereby obtaining solutions each of 3.5 mass % solid content. The solutions were each passed through a polytetrafluoroethylene filter of 0.03 μm pore size, thereby obtaining chemically amplified positive resist compositions (positive resist solutions). In Table 1, the amount of each of the components is expressed by the mass % based on the total solids.

TABLE 1

| | | | | Concom- | |
|---|---|---|---|---|---|
| | | Acid | | itant | |
| | Resin | generator | Compd. | basic | Surfac- |
| | (P) | (Q) | (R) | compd. | tant |
| | (mass %) | (mass %) | (mass %) | (mass %) | (mass %) |
| Ex. 1 | A-1 | B-1 | C-1 | — | W-1 |
| | (91.49) | (8.00) | (0.50) | | (0.01) |
| Ex. 2 | A-1 | B-1 | C-2 | — | W-1 |
| | (91.37) | (8.00) | (0.62) | | (0.01) |
| Ex. 3 | A-1 | B-1 | C-3 | — | W-1 |
| | (91.55) | (8.00) | (0.44) | | (0.01) |
| Ex. 4 | A-1 | B-1 | C-4 | — | W-1 |
| | (91.47) | (8.00) | (0.52) | | (0.01) |
| Ex. 5 | A-1 | B-1 | C-5 | — | W-1 |
| | (91.62) | (8.00) | (0.37) | | (0.01) |
| Ex. 6 | A-1 | B-1 | C-6 | — | W-1 |
| | (91.53) | (8.00) | (0.46) | | (0.01) |
| Ex. 7 | A-2 | B-1 | C-2 | — | W-1 |
| | (91.37) | (8.00) | (0.62) | | (0.01) |
| Ex. 8 | A-3 | B-1 | C-2 | — | W-1 |
| | (91.37) | (8.00) | (0.62) | | (0.01) |
| Ex. 9 | A-4 | B-2 | C-2 | — | W-1 |
| | (92.09) | (7.28) | (0.62) | | (0.01) |
| Ex. 10 | A-5 | B-3 | C-2 | — | W-1 |
| | (92.37) | (7.00) | (0.62) | | (0.01) |
| Ex. 11 | A-1 | B-1 | C-2 | C-7 | W-1 |
| | (91.47) | (8.00) | (0.31) | (0.21) | (0.01) |
| Ex. 12 | A-1 | B-1 | C-2 | C-8 | W-1 |
| | (91.50) | (8.00) | (0.31) | (0.18) | (0.01) |
| Comp. Ex. 1 | A-1 | B-1 | C-A | — | W-1 |
| | (91.54) | (8.00) | (0.45) | | (0.01) |
| Comp. Ex. 2 | A-1 | B-1 | C-B | — | W-1 |
| | (91.60) | (8.00) | (0.39) | | (0.01) |
| Comp. Ex. 3 | A-1 | B-1 | C-C | — | W-1 |
| | (91.74) | (8.00) | (0.25) | | (0.01) |
| Comp. Ex. 4 | A-1 | B-1 | C-D | — | W-1 |
| | (91.50) | (8.00) | (0.49) | | (0.01) |

<Evaluation of Resist (EB)>

Each of the above positive resist solutions was applied onto a silicon substrate having undergone a hexamethyldisilazane treatment by means of a spin coater, and dried by heating on a hot plate at 130° C. for 90 seconds. Thus, resist films of 100 nm average thickness were obtained.

Each of the resist films was irradiated with electron beams by means of an electron beam lithography system (HL750 manufactured by Hitachi, Ltd., acceleration voltage 50 KeV). Immediately after the irradiation, the film was baked on a hot plate at 110° C. for 90 seconds. The baked film was developed with a 2.38 mass % aqueous tetramethylammonium hydroxide solution at 23° C. for 60 seconds. After the development, the film was rinsed with pure water for 30 seconds and dried. Thus, a line and space pattern (line:space=1:1) and an isolated line pattern (line:space=1:>100) were formed.

(Sensitivity)

The obtained pattern was observed by means of a scanning electron microscope (model S-9260 manufactured by Hitachi, Ltd.). The sensitivity (Eopt) was defined as an exposure amount in which a line of 100 nm width (line:space=1:1) was resolved.

(Shape of Pattern)

With respect to the 100 nm line pattern (line:space=1:1) realized in the irradiation amount exhibiting the above sensitivity, the shape of cross section thereof was observed by means of a scanning electron microscope (model S-4800 manufactured by Hitachi, Ltd.). The observed shape was evaluated in the following five grades.

x(−)[Insufficient]: shape of taper, 0°<θ≦75°

Δ(−)[Fair]: shape of taper, 75°<θ≦85°

O [Good]: rectangle, 85°<θ<95°

Δ(+) [Fair]: shape of inverted taper, 95°≦θ<105°

x(+) [Insufficient]: shape of inverted taper, 105°≦θ<180°

FIGURE is a section view schematically showing the definition of the taper angle mentioned in Examples. FIGURE shows a substrate 10 and a line pattern 20 formed on the substrate. The taper angle θ refers to the angle on the side of the resist pattern among angles formed between a substrate surface and a straight line which passes through a substrate-pattern contact point and a point of greatest line width, in the shape of cross section of a 100 nm line pattern (line:space=1:1).

In the above evaluation criteria, the taper angle θ is determined in the following manner. First, with respect to each of five patterns, the right and left angles are measured. The thus obtained ten measurement values are averaged, and the average is denoted as the taper angle θ.

(Roughness Characteristic; LWR)

The above 100 nm line pattern (line:space=1:1) was observed by means of a scanning electron microscope (model S-9260, manufactured by Hitachi, Ltd.). The distance between actual edge and a reference line on which edges were to be present was measured at 50 points of equal intervals within 2 μm in the longitudinal direction of the pattern. The standard deviation of measured distances was determined, and 3σ was computed therefrom. This 3σ was denoted as “LWR (nm).”

(Residue)

The above 100 nm line pattern (line:space=1:1) was observed by means of a scanning electron microscope (model S-9260, manufactured by Hitachi, Ltd.). The evaluation marks o(good), Δ(fair) and x(insufficient) were given when no residue was found at all in the substrate surface of the space portion, when 20% or less of the surface area of the space portion was covered by residue and when 50% or more of the space portion was covered by residue, respectively.

(Resolution of Isolated Pattern; Resolving Power)

With respect to the isolated pattern (line:space=1: >100) realized in the irradiation amount exhibiting the above sensitivity, the limiting resolving power (minimum line width permitting the separation and resolution of a line and a space) was determined. The obtained value was denoted as “resolving power (nm).”

The obtained evaluation results are given in Table 2 below.

TABLE 2

| | | Shape | | | Resolution |
|---|---|---|---|---|---|
| | Sensitivity | of | LWR | | of isolated |
| | (μC/cm²) | pattern | (nm) | Residue | pattern (nm) |
| Ex. 1 | 30 | ∘ | 5.4 | ∘ | 37.5 |
| Ex. 2 | 29 | ∘ | 5.1 | ∘ | 37.5 |
| Ex. 3 | 32 | ∘ | 5.5 | ∘ | 50 |
| Ex. 4 | 31 | ∘ | 5.2 | ∘ | 50 |
| Ex. 5 | 27 | ∘ | 5.9 | ∘ | 37.5 |
| Ex. 6 | 32 | Δ(+) | 4.8 | ∘ | 50 |
| Ex. 7 | 32 | ∘ | 4.8 | ∘ | 37.5 |
| Ex. 8 | 22 | ∘ | 5.3 | ∘ | 37.5 |
| Ex. 9 | 24 | ∘ | 4.5 | ∘ | 50 |
| Ex. 10 | 35 | Δ(+) | 4.9 | ∘ | 62.5 |
| Ex. 11 | 27 | ∘ | 3.9 | ∘ | 37.5 |
| Ex. 12 | 25 | ∘ | 4.2 | ∘ | 37.5 |
| Comp. Ex. 1 | 37 | Δ(−) | 6.0 | x | 62.5 |
| Comp. Ex. 2 | 38 | x(−) | 7.2 | x | 87.5 |
| Comp. Ex. 3 | 35 | Δ(−) | 6.3 | Δ | 67.5 |
| Comp. Ex. 4 | 35 | x(+) | 8.6 | ∘ | 100 |

As apparent from Table 2, the compositions of Examples exhibited excellent performance as compared with that of the compositions of Comparative Examples.

<Preparation of Resist Composition>

Components of Table 3 below were dissolved in a solvent consisting of a 40:60 mixture of propylene glycol monomethyl ether acetate and propylene glycol monomethyl ether, thereby obtaining solutions each of 1.8 mass % solid content. The solutions were each passed through a polytetrafluoroethylene filter of 0.03 μm pore size, thereby obtaining chemically amplified positive resist compositions (positive resist solutions). In Table 3, the amount of each of the components is expressed by the mass % based on the total solids.

TABLE 3

| | | | | Concom- | |
|---|---|---|---|---|---|
| | | Acid | | itant | |
| | Resin | generator | Compd. | basic | Surfac- |
| | (P) | (Q) | (R) | compd. | tant |
| | (mass %) | (mass %) | (mass %) | (mass %) | (mass %) |
| Ex. 13 | A-1 | B-1 | C-1 | — | W-1 |
| | (91.4) | (8.0) | (0.5) | | (0.1) |
| Ex. 14 | A-1 | B-1 | C-2 | — | W-1 |
| | (91.4) | (8.0) | (0.62) | | (0.1) |
| Comp. Ex. 5 | A-1 | B-1 | C-A | — | W-1 |
| | (91.4) | (8.0) | (0.5) | | (0.1) |
| Comp. Ex. 6 | A-1 | B-1 | C-B | — | W-1 |
| | (91.4) | (8.0) | (0.5) | | (0.1) |

<Evaluation of Resist (EUV)>

Each of the above positive resist solutions was applied onto a silicon substrate having undergone a hexamethyldisilazane treatment by means of a spin coater, and dried by heating on a hot plate at 130° C. for 90 seconds. Thus, resist films of 50 nm average thickness were obtained.

Each of the resist films was exposed to EUV light by means of an EUV exposure apparatus (wavelength=13.5 nm, NA=0.3). Immediately after the exposure, the film was baked on a hot plate at 110° C. for 90 seconds. The baked film was developed with a 2.38 mass % aqueous tetramethylammonium hydroxide solution at 23° C. for 30 seconds. After the development, the film was rinsed with pure water for 30 seconds and dried. Thus, a line and space pattern (line:space=1:1) was formed.

(Sensitivity)

The shape of cross section of obtained line and space pattern was observed by means of a scanning electron microscope (model S-9380 manufactured by Hitachi, Ltd.). The sensitivity (Eopt) was defined as an exposure amount in which a line of 35 nm width (line:space=1:1) was resolved.

(Shape of Pattern)

With respect to the 35 nm line pattern (line:space=1:1) realized in the irradiation amount exhibiting the above sensitivity, the shape of cross section thereof was observed by means of a scanning electron microscope (model S-4800 manufactured by Hitachi, Ltd.). The observed shape was evaluated in the same manner as described above.

(Roughness Characteristic; LWR)

The above 35 nm line pattern (line:space=1:1) was observed by means of a scanning electron microscope (model S-9380, manufactured by Hitachi, Ltd.). The distance between actual edge and a reference line on which edges were to be present was measured at 50 points of equal intervals within 2 μm in the longitudinal direction of the pattern. The standard deviation of measured distances was determined, and 3σ was computed therefrom. This 3σ was denoted as “LWR (nm).”

(Residue)

The above 100 nm line pattern (line:space=1:1) was observed by means of a scanning electron microscope (model S-9260, manufactured by Hitachi, Ltd.). The evaluation marks o(good), Δ(fair) and x(insufficient) were given when no residue was found at all in the substrate surface of the space portion, when 20% or less of the surface area of the space portion was covered by residue and when 50% or more of the space portion was covered by residue, respectively.

The obtained evaluation results are given in Table 4 below.

TABLE 4

| | | Shape | | |
|---|---|---|---|---|
| | Sensitivity | of | LWR | |
| | (mJ/cm²) | pattern | (nm) | Residue |
| Ex. 13 | 13.6 | ∘ | 5.1 | ∘ |
| Ex. 14 | 12.2 | ∘ | 4.7 | ∘ |
| Comp. Ex. 5 | 15.8 | Δ(−) | 6.1 | x |
| Comp. Ex. 6 | 17.2 | x(−) | 8.5 | x |

As apparent from Table 4, the compositions of Examples also exhibited excellent performance upon exposure to EUV.

<Preparation of Resist Composition>

Components of Table 5 below were dissolved in a solvent consisting of a 40:60 mixture of propylene glycol monomethyl ether acetate and propylene glycol monomethyl ether, thereby obtaining solutions each of 1.8 mass % solid content. The solutions were each passed through a polytetrafluoroethylene filter of 0.03 μm pore size, thereby obtaining chemically amplified positive resist compositions (positive resist solutions). In Table 5, the amount of each of the components is expressed by the mass % based on the total solids.

TABLE 5

| | | | | Concom- | |
|---|---|---|---|---|---|
| | | Acid | | itant | |
| | Resin | generator | Compd. | basic | Surfac- |
| | (P) | (Q) | (R) | compd. | tant |
| | (mass %) | (mass %) | (mass %) | (mass %) | (mass %) |
| Ex. 15 | A-1 | B-1 | C-1 | — | W-1 |
| | (91.49) | (8.00) | (0.5) | | (0.01) |
| Ex. 16 | A-1 | B-1 | C-2 | — | W-1 |
| | (91.37) | (8.00) | (0.62) | | (0.01) |
| Comp. Ex. 7 | A-1 | B-1 | C-A | — | W-1 |
| | (91.54) | (8.00) | (0.45) | | (0.01) |
| Comp. Ex. 8 | A-1 | B-1 | C-B | — | W-1 |
| | (91.60) | (8.00) | (0.39) | | (0.01) |

<Evaluation of Resist (EB)>

A silicon substrate on its one surface was coated with a 50 nm thick silicon oxide film by a plasma CVD technique. Each of the above positive resist solutions was applied onto the silicon substrate by means of a spin coater, and dried by heating on a hot plate at 130° C. for 90 seconds. Thus, resist films of 100 nm average thickness were obtained.

Each of the resist films was irradiated with electron beams by means of an electron beam lithography system (HL750 manufactured by Hitachi, Ltd., acceleration voltage 50 KeV). Immediately after the irradiation, the film was baked on a hot plate at 110° C. for 90 seconds. The baked film was developed with a 2.38 mass % aqueous tetramethylammonium hydroxide solution at 23° C. for 60 seconds. After the development, the film was rinsed with pure water for 30 seconds and dried. Thus, a line and space pattern (line:space=1:1) and an isolated line pattern (line:space=1:>100) were formed.

(Sensitivity)

The obtained pattern was observed by means of a scanning electron microscope (model S-9260 manufactured by Hitachi, Ltd.). The sensitivity (Eopt) was defined as an exposure amount in which a line of 100 nm width (line:space=1:1) was resolved.

(Shape of Pattern)

With respect to the 100 nm line pattern (line:space=1:1) realized in the irradiation amount exhibiting the above sensitivity, the shape of cross section thereof was observed by means of a scanning electron microscope (model S-4800 manufactured by Hitachi, Ltd.). The observed shape was evaluated in the same manner as described above.

(Roughness Characteristic; LWR)

The above 100 nm line pattern (line:space=1:1) was observed by means of a scanning electron microscope (model S-9260, manufactured by Hitachi, Ltd.). The distance between actual edge and a reference line on which edges were to be present was measured at 50 points of equal intervals within 2 μm in the longitudinal direction of the pattern. The standard deviation of measured distances was determined, and 3σ was computed therefrom. This 3σ was denoted as “LWR (nm).”

(Residue)

The above 100 nm line pattern (line:space=1:1) was observed by means of a scanning electron microscope (model S-9260, manufactured by Hitachi, Ltd.). The evaluation marks o(good), Δ(fair) and x(insufficient) were given when no residue was found at all in the substrate surface of the space portion, when 20% or less of the surface area of the space portion was covered by residue and when 50% or more of the space portion was covered by residue, respectively.

(Resolution of Isolated Pattern; Resolving Power)

With respect to the isolated pattern (line:space=1: >100) realized in the irradiation amount exhibiting the above sensitivity, the limiting resolving power (minimum line width permitting the separation and resolution of a line and a space) was determined. The obtained value was denoted as “resolving power (nm).”

The obtained evaluation results are given in Table 6 below.

TABLE 6

| | | Shape | | | Resolution |
|---|---|---|---|---|---|
| | Sensitivity | of | LWR | | of isolated |
| | (μC/cm²) | pattern | (nm) | Residue | pattern(nm) |
| Ex. 15 | 27 | ∘ | 5.6 | ∘ | 37.5 |
| Ex. 16 | 27 | ∘ | 5.0 | ∘ | 37.5 |
| Comp. Ex. 7 | 35 | x(−) | 6.8 | x | 87.5 |
| Comp. Ex. 8 | 34 | x(−) | 8.4 | x | 100 |

As apparent from Table 6, the compositions of Examples exhibited excellent performance even when an acidic substrate was used.

The composition according to the present invention can find appropriate application as a lithography process in the manufacturing of a variety of electronic devices including semiconductor elements, recording media and the like.

### REFERENCE SIGNS LIST

10: substrate
20: line pattern

What is claimed is:

1. An actinic-ray- or radiation-sensitive resin composition comprising:
a resin (P) containing an acid-decomposable repeating unit (A), which resin when acted on by an acid, increases its solubility in an alkali developer,
a compound (Q) that when exposed to actinic rays or radiation, generates an acid, and
a compound (R) expressed by general formula (1) or (2) below, 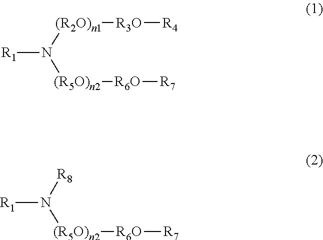
in the formulae,
each of R₁ and R₈ independently represents an organic group containing no heteroatom,
each of R₂, R₃, R₅ and R₆ independently represents an alkylene group having 1 to 3 carbon atoms,
each of R₄ and R₇ independently represents a hydrogen atom or an alkyl group, and
each of n₁ and n₂ independently is an integer of 1 to 6.

2. The composition according to claim 1, wherein the organic group is an alkyl group or an aryl group.

3. The composition according to claim 1, wherein the compound (R) is expressed by general formula (1), and wherein at least one of R₄ and R₇ is a hydrogen atom.

4. The composition according to claim 3, wherein both of R₄ and R₇ are hydrogen atoms.

5. The composition according to claim 1, wherein the compound (R) is expressed by general formula (2), and wherein R₇ is a hydrogen atom.

6. The composition according to claim 1, wherein the repeating unit (A) is expressed by general formula (V) or (VI) below, 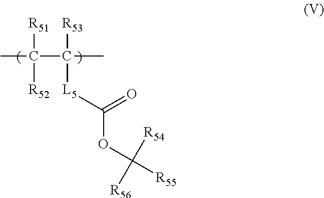
in which,
each of R₅₁, R₅₂ and R₅₃ independently represents a hydrogen atom, an alkyl group, a cycloalkyl group, a halogen atom, a cyano group or an alkoxycarbonyl group, provided that R₅₂ may be bonded to L₅ to thereby form a ring, which R₅₂ represents an alkylene group,
L₅ represents a single bond or a bivalent connecting group, provided that when a ring is formed in cooperation with R₅₂, L₅ represents a trivalent connecting group, and
R₅₄ represents an alkyl group, and each of R₅₅ and R₅₆ independently represents a hydrogen atom, an alkyl group, a cycloalkyl group or a monovalent aromatic ring group, provided that R₅₅ and R₅₆ may be bonded to each other to thereby form a ring, and provided that R₅₅ and R₅₆ are not simultaneously hydrogen atoms, 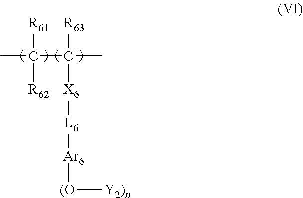
in which,
each of R₆₁, R₆₂ and R₆₃ independently represents a hydrogen atom, an alkyl group, a cycloalkyl group, a halogen atom, a cyano group or an alkoxycarbonyl group, provided that R₆₂ may be bonded to Ar₆ to thereby form a ring, which R₆₂ represents an alkylene group,
X₆ represents a single bond, —COO— or —CONR₆₄— in which R₆₄ represents a hydrogen atom or an alkyl group,
L₆ represents a single bond or an alkylene group,
Ar6 represents a bivalent aromatic ring group,
Y₂, when n≧2 each independently, represents a hydrogen atom or a group that when acted on by an acid, is cleaved, provided that at least one of Y₂s is a group that when acted on by an acid, is cleaved, and
n is an integer of 1 to 4.

7. The composition according to claim 1, wherein the resin (P) further contains any of repeating units (B) expressed by general formula (I) below, 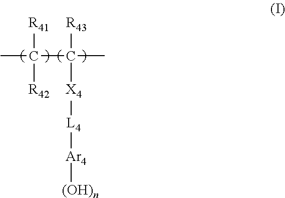
in which
each of R₄₁, R₄₂ and R₄₃ independently represents a hydrogen atom, an alkyl group, a halogen atom, a cyano group or an alkoxycarbonyl group,
X₄ represents a single bond, —COO— or —CONR₆₄— in which R₆₄ represents a hydrogen atom or an alkyl group,
L₄ represents a single bond or an alkylene group,
Ar₄ represents a (n+1)-valent aromatic ring group, and
n is an integer of 1 to 4.

8. The composition according to claim 7, wherein the repeating unit (B) has a hydroxystyrene structure.

9. The composition according to claim 1, further comprising a basic compound other than the compound (R).

10. The composition according to claim 9, wherein the basic compound contains no hydroxyl group.

11. The composition according to claim 1 for use in a pattern formation including exposure by EUV.

12. An actinic-ray- or radiation-sensitive resin film formed from the composition according to claim 1.

13. A method of forming a pattern, comprising:
exposing the film according to claim 12 to light, and
developing the exposed film.

14. The method according to claim 13, wherein the exposure is carried out by EUV light.

15. A process for manufacturing an electronic device, comprising the pattern forming method according to claim 13.

16. An electronic device manufactured by the process according to claim 15.
